(19) United States
(12) Patent Application Publication
(10) Pub. No.: US 2024/0334736 A1
(43) Pub. Date: Oct. 3, 2024

(54) DISPLAY APPARATUS

(71) Applicant: Semiconductor Energy Laboratory Co., Ltd., Atsugi-shi, Kanagawa-ken (JP)

(72) Inventors: Yukinori SHIMA, Tatebayashi (JP); Koji ONO, Tochigi (JP); Masataka NAKADA, Tochigi (JP); Rai SATO, Tochigi (JP); Hiroki ADACHI, Tochigi (JP)

(21) Appl. No.: 18/575,411

(22) PCT Filed: Jun. 27, 2022
(86) PCT No.: PCT/IB2022/055922

§ 371 Date: Dec. 29, 2023

(30) Foreign Application Priority Data
Jul. 8, 2021 (JP) 2021-113556

(51) Int. Cl. H10K 50/813; H10K 59/131

(52) U.S. Cl. CPC H10K 50/813; H10K 59/131

(57) ABSTRACT

A display apparatus with high detection sensitivity of an image capturing function and high display quality is provided. The display apparatus includes a light-receiving device; a first light-emitting device including a first lower electrode whose end portion has a first tapered shape and a first organic compound layer having a shape along the first tapered shape; a second light-emitting device including a second lower electrode whose end portion has a second tapered shape and a second organic compound layer having a shape along the second tapered shape; a common electrode included in the first light-emitting device and the second light-emitting device; an insulating layer positioned between the first light-emitting device and the second light-emitting device and between the second light-emitting device and the light-receiving device; and an auxiliary wiring electrically connected to the common electrode. The auxiliary wiring is positioned over the common electrode and includes a region overlapping with the insulating layer.

### TECHNICAL FIELD

One embodiment of the present invention relates to a display apparatus.

Note that one embodiment of the present invention is not limited to the above technical field. Examples of a technical field of one embodiment of the present invention disclosed in this specification and the like include a semiconductor device, a light-emitting apparatus, a power storage device, a memory device, an electronic device, a lighting device, an input device, or an input/output device, and a manufacturing method thereof.

### BACKGROUND ART

In recent years, an information terminal device such as a smartphone has an image capturing function for capturing a fingerprint image for authentication or the like in addition to a function of displaying an image. In order that the information terminal device can have an image capturing function, a structure in which a light-receiving element is provided on the same substrate as a light-emitting device has been proposed (see Patent Document 1).

Moreover, a display apparatus used in the information terminal device requires a high aperture ratio. For improving the aperture ratio, a display apparatus having a top-emission structure has been proposed (see Patent Document 2).

As a method for manufacturing an organic EL element which can be used in the display apparatus, a method for fabricating an organic optoelectronic device using a standard UV photolithography is disclosed (see Non-Patent Document 1).

### REFERENCE

### Patent Documents

[Patent Document 1] PCT International Publication No. 2021/038392
[Patent Document 2] Japanese Published Patent Application No. 2012-182127

### Non-Patent Document

[Non-Patent Document 1] B. Lamprecht et al., “Organic optoelectronic device fabrication using standard UV photolithography” phys. stat. sol. (RRL) 2, No. 1, pp. 16-18 (2008)

### SUMMARY OF THE INVENTION

### Problems to be Solved by the Invention

In Patent Document 1, a light-blocking layer provided on a counter substrate is used as a measure against stray light. However, it is not possible to sufficiently inhibit stray light with the light-blocking layer provided on the counter substrate in some cases; thus, an image capturing function with high detection sensitivity is difficult to be provided.

As disclosed in Patent Document 2, the display apparatus having a top-emission structure extracts light of a light-emitting device through a common electrode; thus, the common electrode needs to have a light-transmitting property. However, when a conductive material having a light-transmitting property is used, the resistance of the common electrode becomes high and voltage drop might occur. Voltage drop causes non-uniform potential distribution in a display surface, leading to a reduction in display quality.

In the above method of Non-Patent Document 1, it is difficult to achieve high resolution of the display apparatus.

In view of the above, an object of one embodiment of the present invention is to provide a display apparatus with high detection sensitivity of an image capturing function and a manufacturing method thereof. Another object of one embodiment of the present invention is to provide a display apparatus with high display quality and a manufacturing method thereof. Another object of one embodiment of the present invention is to provide a display apparatus with high resolution and a manufacturing method thereof.

Note that the description of these objects does not preclude the existence of other objects. These objects should be construed as being independent of one another, and one embodiment of the present invention only needs to achieve at least one of these objects and does not need to achieve all the objects. Furthermore, other objects can be derived from the description of the specification, the drawings, and the claims.

### Means for Solving the Problems

In view of the above objects, one embodiment of the present invention is a display apparatus including a first light-emitting device including a first lower electrode whose end portion has a first tapered shape and a first organic compound layer having a shape along the first tapered shape; a second light-emitting device including a second lower electrode whose end portion has a second tapered shape and a second organic compound layer having a shape along the second tapered shape; a common electrode included in the first light-emitting device and the second light-emitting device; an insulating layer positioned between the first light-emitting device and the second light-emitting device; and an auxiliary wiring electrically connected to the common electrode. The auxiliary wiring is positioned over the common electrode and includes a region overlapping with the insulating layer.

One embodiment of the present invention is a display apparatus including a light-receiving device; a first light-emitting device including a first lower electrode whose end portion has a first tapered shape and a first organic compound layer having a shape along the first tapered shape; a second light-emitting device including a second lower electrode whose end portion has a second tapered shape and a second organic compound layer having a shape along the second tapered shape; a common electrode included in the first light-emitting device and the second light-emitting device; an insulating layer positioned between the first light-emitting device and the second light-emitting device and between the second light-emitting device and the light-receiving device; and an auxiliary wiring electrically connected to the common electrode. The auxiliary wiring is positioned over the common electrode and includes a region overlapping with the insulating layer.

One embodiment of the present invention is a display apparatus including a light-receiving device; a first light-emitting device including a first lower electrode whose end portion has a first tapered shape and a first organic compound layer having a shape along the first tapered shape; a second light-emitting device including a second lower electrode whose end portion has a second tapered shape and a second organic compound layer having a shape along the second tapered shape; a common electrode included in the first light-emitting device and the second light-emitting device; an insulating layer positioned between the first light-emitting device and the second light-emitting device and between the second light-emitting device and the light-receiving device; and an auxiliary wiring electrically connected to the common electrode. The auxiliary wiring is positioned over the common electrode and includes a region provided to surround the light-receiving device.

One embodiment of the present invention is a display apparatus including a light-receiving device; a first light-emitting device including a first lower electrode whose end portion has a first tapered shape and a first organic compound layer having a shape along the first tapered shape; a second light-emitting device including a second lower electrode whose end portion has a second tapered shape and a second organic compound layer having a shape along the second tapered shape; a common electrode included in the first light-emitting device and the second light-emitting device; an insulating layer positioned between the first light-emitting device and the second light-emitting device and between the second light-emitting device and the light-receiving device; and an auxiliary wiring electrically connected to the common electrode. The auxiliary wiring is positioned over the common electrode and includes a region provided between the first light-emitting device and the light-receiving device.

In one embodiment of the present invention, the insulating layer preferably has a shape where the center portion thereof rises up more than the end portion.

In one embodiment of the present invention, the insulating layer preferably includes an upper portion with a flat shape.

### Effect of the Invention

With one embodiment of the present invention, a display apparatus with high detection sensitivity of an image capturing function can be provided. With one embodiment of the present invention, a display apparatus with high display quality can be provided. With one embodiment of the present invention, a display apparatus with high resolution can be provided. Furthermore, with one embodiment of the present invention, a method for manufacturing the above display apparatus or the like can be provided.

Note that the description of these effects does not preclude the existence of other effects. These effects should be construed as being independent of one another, and one embodiment of the present invention is only necessary to achieve at least one of the above-described effects and does not need to have all the effects. Furthermore, other effects can be derived from the description of the specification, the drawings, and the claims.

### BRIEF DESCRIPTION OF THE DRAWINGS

FIG. 1A to FIG. 1E are top views of a pixel portion.

FIG. 2A to FIG. 2C are cross-sectional views of a pixel portion.

FIG. 3A is a top view of a pixel portion and a connection portion, FIG. 3B is a cross-sectional view of the pixel portion, and FIG. 3C is a cross-sectional view of the connection portion.

FIG. 4A to FIG. 4C are cross-sectional views of a pixel portion.

FIG. 5A to FIG. 5C are cross-sectional views of a pixel portion.

FIG. 6A and FIG. 6B are cross-sectional views of a pixel portion.

FIG. 7A to FIG. 7C are top views of a pixel portion and FIG. 7D is a circuit diagram.

FIG. 8A to FIG. 8C are cross-sectional views illustrating a method for manufacturing a display apparatus.

FIG. 9A to FIG. 9C are cross-sectional views illustrating a method for manufacturing a display apparatus.

FIG. 10A to FIG. 10C are cross-sectional views illustrating a method for manufacturing a display apparatus.

FIG. 11A to FIG. 11C are cross-sectional views illustrating a method for manufacturing a display apparatus.

FIG. 12A to FIG. 12C are cross-sectional views illustrating a method for manufacturing a display apparatus.

FIG. 13A to FIG. 13C are cross-sectional views illustrating a method for manufacturing a display apparatus.

FIG. 14 is a cross-sectional view illustrating a method for manufacturing a display apparatus.

FIG. 15A to FIG. 15D are top views of a pixel circuit.

FIG. 16A is a top view of a pixel portion and a connection portion, FIG. 16B is a cross-sectional view of the pixel portion, and FIG. 16C is a cross-sectional view of the connection portion.

FIG. 17A to FIG. 17E are top views of a pixel portion.

FIG. 18A to FIG. 18E are top views of a pixel portion.

FIG. 19A to FIG. 19C are cross-sectional views illustrating a method for manufacturing a display apparatus.

FIG. 20A to FIG. 20C are cross-sectional views illustrating a method for manufacturing a display apparatus.

FIG. 21A and FIG. 21B are cross-sectional views illustrating a method for manufacturing a display apparatus.

FIG. 22A and FIG. 22B are cross-sectional views illustrating a method for manufacturing a display apparatus.

FIG. 23A is a top view of a display apparatus and FIG. 23B and FIG. 23C are perspective views of the display apparatus.

FIG. 24A and FIG. 24B are perspective views of a display apparatus.

FIG. 25A is a block diagram of a display apparatus, and FIG. 25B to FIG. 25D are circuit diagrams.

FIG. 26A to FIG. 26D are cross-sectional views of transistors.

FIG. 27A to FIG. 27D are diagrams of electronic devices.

FIG. 28A and FIG. 28B are diagrams of electronic devices.

FIG. 29A and FIG. 29B are diagrams of electronic devices.

FIG. 30A and FIG. 30B are diagrams of an electronic device.

### MODE FOR CARRYING OUT THE INVENTION

In this specification and the like, components are classified based on their functions and the components are described using independent blocks in a diagram in some cases; however, it is difficult to classify actual components based on their functions completely, and one component can have a plurality of functions.

In this specification and the like, the terms “source” and “drain” of a transistor interchange with each other depending on the polarity of the transistor or the levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification and the like, for the sake of convenience, the connection relationship of a transistor is sometimes described assuming that the source and the drain are fixed; in reality, the names of the source and the drain interchange with each other according to the above relationship of the potentials. In this specification and the like, a “source” of a transistor means a source region that is part of a semiconductor layer functioning as an active layer or means a source electrode connected to the source region. Similarly, a “drain” of a transistor means a drain region that is part of the semiconductor layer or a drain electrode connected to the drain region. Moreover, a “gate” of a transistor means a gate electrode.

In this specification and the like, a state in which transistors are connected in series means, for example, a state in which only one of a source and a drain of a first transistor is connected to only one of a source and a drain of a second transistor. In addition, a state in which transistors are connected in parallel means a state in which one of a source and a drain of a first transistor is connected to one of a source and a drain of a second transistor and the other of the source and the drain of the first transistor is connected to the other of the source and the drain of the second transistor.

In this specification and the like, connection is sometimes referred to as electrical connection and may refer to a state where current, voltage, or potential can be supplied or transmitted. Accordingly, connection may refer to connection via an element such as a wiring, a resistor, a diode, or a transistor. Electrical connection may refer to direct connection without via an element such as a wiring, a resistor, a diode, or a transistor.

In this specification and the like, a first electrode and a second electrode are used for description of a source and a drain of a transistor in some cases; when one of the first electrode and the second electrode refers to a source electrode, the other thereof refers to a drain electrode. In this specification and the like, a conductive layer sometimes has a plurality of functions such as those of a wiring and an electrode.

In this specification and the like, a light-emitting device is referred to as a light-emitting element in some cases. The light-emitting device has a structure in which an organic compound layer is interposed between a pair of electrodes. One of the pair of electrodes is an anode, the other of the pair of electrodes is a cathode, and at least one organic compound layer is a light-emitting layer.

In this specification and the like, a light-emitting device including an organic compound layer which is formed using a metal mask (an MM) is sometimes referred to as a light-emitting device having a metal mask structure.

In this specification and the like, a metal mask may be referred to as a fine metal mask (an FMM, a high-resolution metal mask) depending on the minuteness of its opening portions.

In this specification and the like, a light-emitting device including an organic compound layer formed without using a metal mask or a fine metal mask is sometimes referred to as a light-emitting device having a metal maskless (MML) structure.

In this specification and the like, light-emitting devices exhibiting for example, red, green, and blue are sometimes referred to as a red light-emitting device, a green light-emitting device, and a blue light-emitting device, respectively.

In this specification and the like, a structure in which light-emitting layers of light-emitting devices of different colors are separately formed is sometimes referred to as an SBS (Side By Side) structure. For example, formation of the red light-emitting device, the green light-emitting device, and the blue light-emitting device with an SBS structure enables providing a full-color display apparatus.

In this specification and the like, a light-emitting device emitting white light may be referred to as a white-light-emitting device. Note that a combination of such a white-light-emitting device with coloring layers (e.g., color filters or color conversion layers) enables providing a full-color display apparatus.

Structures of light-emitting devices can be classified roughly into a single structure and a tandem structure. In the single structure, one light-emitting unit is provided between a pair of electrodes. The light-emitting unit refers to a stack including one or more light-emitting layers.

To obtain a white-light-emitting device with a single structure, two or more light-emitting layers are included in a light-emitting unit, and the emission colors of the two or more light-emitting layers are recognized as white. The two or more light-emitting layers may be in contact with each other in the light-emitting unit. A white-light-emitting device can also be obtained in the light-emitting unit including three or more light-emitting layers when the emission colors are complementary colors. The three or more light-emitting layers may be in contact with each other in the light-emitting unit.

In the tandem structure, two or more light-emitting units are provided between a pair of electrodes. Each of the two or more light-emitting units refers to a stack including one or more light-emitting layers. In the tandem structure, an intermediate layer such as a charge-generation layer is suitably provided between the plurality of light-emitting units. The charge-generation layer has a function of injecting holes into one of the light-emitting units formed to be in contact with the charge-generation layer and injecting electrons into the other light-emitting unit, when voltage is applied between the cathode and the anode. For example, the tandem structure is preferably a structure in which a first light-emitting unit, a charge-generation layer, and a second light-emitting unit are provided between a pair of electrodes and, through the charge-generation layer, holes are injected into the first light-emitting unit and electrons are injected into the second light-emitting unit.

To obtain a white-light-emitting device with the tandem structure, a structure is employed in which light from light-emitting layers of two or more light-emitting units is combined to enable white light emission. In the combination of light-emitting layers capable of white light emission, light of complementary colors is emitted as in the single structure.

When the white-light-emitting device (having a single structure or a tandem structure) and the light-emitting device having an SBS structure are compared to each other, the light-emitting device having an SBS structure can have lower power consumption than the white-light-emitting device (having a single structure or a tandem structure). To reduce power consumption, the light-emitting device having an SBS structure is preferably used. Meanwhile, the white-light-emitting device (having a single structure or a tandem structure) is suitable in terms of lower manufacturing cost or higher manufacturing yield because the manufacturing process of the white-light-emitting device is simpler than that of the light-emitting device having an SBS structure. In this specification and the like, a structure in which a connector such as an FPC (Flexible Printed Circuit) or a TCP (Tape Carrier Package) is attached to a substrate of a display panel, or a structure in which an IC is mounted on a substrate by a COG (Chip On Glass) method or the like is referred to as a display module in some cases. Thus, the display panel is one embodiment of a display apparatus.

Next, embodiments are described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

In this embodiment, structure examples of a display apparatus of one embodiment of the present invention are described.

### <Auxiliary Wiring>

The display apparatus of one embodiment of the present invention preferably includes an auxiliary wiring in a pixel portion. In this specification and the like, the term “auxiliary wiring” means a layer having an auxiliary function of a main electrode. In addition, in this specification and the like, a function of inhibiting voltage drop that might be generated in the main electrode can be given as an example of an “auxiliary function”.

In this specification and the like, any one of a pair of electrodes of the light-emitting device provided in the pixel portion can be given as an example of a “main electrode”. Any one of the pair of electrodes of the light-emitting device has a function of one of a cathode and an anode of the light-emitting device; thus, a conductive material used in any one of the pair of electrodes of the light-emitting device has a work function suitable for the cathode or the anode. Therefore, the conductive material used in any one of the pair of electrodes of the light-emitting device has high resistivity in some cases.

Furthermore, an upper electrode is given as an example of one of the pair of electrodes of the light-emitting device; however, the upper electrode is not divided between a plurality of light-emitting devices and becomes continuous. Although the continuous electrode is referred to as a “common electrode” in this specification and the like, the area of the common electrode that needs to be formed is wider as the display apparatus becomes larger; thus, a difference between the voltage applied to the edge of the common electrode and the voltage applied to the center of the common electrode is easily caused. A specific example of the “voltage drop” in the above description of the auxiliary wiring is a difference between the voltages, and a specific example of the “main electrode” is a common electrode.

In order to inhibit the “voltage drop”, an auxiliary wiring is electrically connected to the common electrode in the display apparatus of one embodiment of the present invention. In the case where the auxiliary wiring is electrically connected to the common electrode, voltage drop is inhibited compared to a state where the auxiliary wiring is not electrically connected to the common electrode; thus, it can be said that the auxiliary wiring has an auxiliary function of inhibiting voltage drop that might be generated in the common electrode.

The auxiliary wiring is sometimes denoted as an auxiliary electrode according to its shape; however, in this specification and the like, any shape may be employed for the auxiliary wiring as long as the function of inhibiting voltage drop that might be generated in the common electrode is produced. Note that in this specification and the like, one embodiment of the present invention is described with use of an auxiliary wiring.

As a conductive material used for the auxiliary wiring, a metal such as aluminum, copper, silver, gold, platinum, chromium, or molybdenum can be used. An alloy of the metal can also be used as the conductive material. The metal and the alloy of the metal are preferable because of their low resistivity. Specifically, the conductivity of the metal and the alloy of the metal can be lower than that of a conductive material used for the common electrode. With the use of such a conductive material, the auxiliary wiring can have a single-layer structure or a stacked-layer structure. Note that in the case of the stacked-layer structure, any of the above-described conductive materials are used for at least one layer. Although the conductive material is the metal and the alloy of the metal, which is also a conductive material with a non-light-transmitting property, the performance of the display apparatus is unchanged even in the case where the conductive material is used for the auxiliary wiring. That is, unlike the common electrode, the auxiliary wiring has a high degree of freedom in arrangement or shape; thus, it is possible to employ the arrangement or shape which does not make the performance of the display apparatus decreased, for example. Note that there is no limitation on a method for forming the auxiliary wiring using the conductive material.

It is needless to say that a conductive material having a light-transmitting property may be used as the conductive material used for the auxiliary wiring. Specific examples of the conductive material having a light-transmitting property include an oxide containing indium and tin (also referred to as indium tin oxide, In—Sn oxide, or ITO), an oxide containing indium, silicon, and tin (also referred to as In—Si—Sn oxide or ITSO), an oxide containing indium and zinc (also referred to as indium zinc oxide or In—Zn oxide), an oxide containing indium, tungsten, and zinc (also referred to as In—W—Zn oxide), or the like. With the use of such a conductive material, the auxiliary wiring can have a single-layer structure or a stacked-layer structure. Note that in the case of the stacked-layer structure, any of the above-described conductive materials are used for at least one layer. The conductive material is the conductive material with a light-transmitting property; thus, the performance of the display apparatus is unchanged even in the case where the conductive material is used for the auxiliary wiring. As described above, unlike the common electrode, the auxiliary wiring has a high degree of freedom in arrangement or shape; thus, the auxiliary wiring may have an arrangement or shape which does not make the performance of the display apparatus decreased even in the case where the conductive material with a light-transmitting property is used. Note that there is no limitation on a method for forming the auxiliary wiring using the conductive material.

For the auxiliary wiring, an organic material such as a conductive polymer may be used or an inorganic material such as carbon black may be used. The conductive polymer and carbon black can exhibit conductivity. With the use of the organic material such as the conductive polymer, the height of the auxiliary wiring in a cross-sectional view can be increased. With such a material, the auxiliary wiring can have a single-layer structure or a stacked-layer structure. Note that in the case of the stacked-layer structure, any of the above-described materials may be used for at least one layer. Note that there is no limitation on a method for forming the auxiliary wiring using the material.

The following relation is preferably satisfied: the resistivity of the conductive material used for the auxiliary wiring is lower than the resistivity of the conductive material used for the common electrode. However, the degree of freedom in arrangement or shape of the auxiliary wiring is high; thus, voltage drop can be sufficiently inhibited by making the thickness, that is, the height, of the auxiliary wiring larger in the cross-sectional view. In addition, voltage drop can be sufficiently inhibited by increasing the area of the auxiliary wiring in a top view (this is also referred to as a plan view), for example. In these cases, the above-described relation of the resistivity is not necessarily satisfied.

### <Top-Emission Structure>

The display apparatus of one embodiment of the present invention preferably employs a top-emission structure. In the top-emission structure, an electrode positioned on the light emission side of the pair of electrodes of the light-emitting device needs to have a light-transmitting property. In this specification and the like, the term “light-transmitting property” means a state where at least visible light (light at wavelengths greater than or equal to 400 nm and less than 750 nm) passes through and desirably has a transmittance higher than or equal to 40%. Furthermore, using the electrode as a common electrode is preferable because the manufacturing method is simplified and the yield of the display apparatus is improved. When these are taken into consideration, Structure A in which a common electrode is formed using a conductive material having a light-transmitting property, Structure B in which a conductive material which does not have a light-transmitting property is thinned down is used for a common electrode, or the like can be given for obtaining a common electrode having a light-transmitting property. However, as in Structure A, a conductive material having a light-transmitting property has high resistivity in some cases; thus, voltage drop might be a concern. Also in the case of thinning the conductive material down as in Structure B, the resistivity of the common electrode is high and voltage drop might be a concern. When voltage drop of the common electrode is generated, the potential distribution in the pixel portion, that is, in a display surface of the display apparatus becomes non-uniform, leading to a variation in luminance of the light-emitting device. The variation in luminance might lead to a reduction in display quality. In the case where the display apparatus of one embodiment of the present invention has a top-emission structure as described above, the auxiliary wiring which is one embodiment of the present invention has a significant effect.

It is needless to say that even in the case where the display apparatus of one embodiment of the present invention has a bottom-emission structure, the effect of inhibiting voltage drop can be produced owing to the structure having the auxiliary wiring electrically connected to the common electrode.

### <Image Capturing Function>

An image capturing function can be added to the display apparatus of one embodiment of the present invention in the case where a light-receiving device (also referred to as a light-receiving element) is included in the pixel portion. The structure in which the light-receiving device is provided in the pixel portion is preferable because of reduction in the number of components and reduction in cost or size of the display apparatus compared to a structure where the light-receiving device is provided outside the display apparatus.

In order to improve the detection sensitivity in the image capturing function, a structure where light other than detection light is not received is preferable. As described above, when the light-receiving device is included in the pixel portion, the distance between the light-receiving device and the light-emitting device becomes shorter compared to the case where the light-receiving device is provided outside the display apparatus; thus, the light-receiving device may receive part of light emitted from the light-emitting device. Note that part of light refers to light reflected or scattered on an interface or the like between layers through which light emitted from the light-emitting device passes, and this light is referred to as “stray light” in this specification and the like.

The display apparatus of one embodiment of the present invention can inhibit the light-receiving device from receiving stray light by the auxiliary wiring. In this specification and the like, this may be referred to as “inhibition of stray light”. As a structure example in which the effect of inhibiting stray light is increased by the auxiliary wiring, Structure C in which the auxiliary wiring is positioned between the light-receiving device and the light-emitting device or Structure D in which the auxiliary wiring is positioned to surround the light-receiving device can be given. Furthermore, the auxiliary wiring with high height in the cross-sectional view is preferably used as a shape example of the auxiliary wiring for increasing the effect of inhibiting stray light. Moreover, a material having conductivity and capable of reflecting or absorbing stray light to improve the inhibition of stray light is preferably used for the auxiliary wiring. In order to reflect stray light, a metal material is preferably used for the auxiliary wiring. In order to absorb stray light, a material exhibiting black such as carbon black is preferably used for the auxiliary wiring.

Note that in this specification and the like, in the case where the display apparatus only needs to have the effect of inhibiting stray light and voltage drop does not need to be inhibited, the above-described auxiliary wiring can be referred to as a “light-blocking body” and an insulating material can also be used for the auxiliary wiring. The light-blocking body is preferably positioned between the light-receiving device and the light-emitting device as in Structure C or may be positioned to surround the light-receiving device as in Structure D. The height of the light-blocking body is preferably high in the cross-sectional view. Furthermore, a material which reflects or absorbs stray light is preferably used for the light-blocking body.

In view of the above description, specific examples of the display apparatus of one embodiment of the present invention are described.

### <Top Surface Structure Example of Auxiliary Wiring>

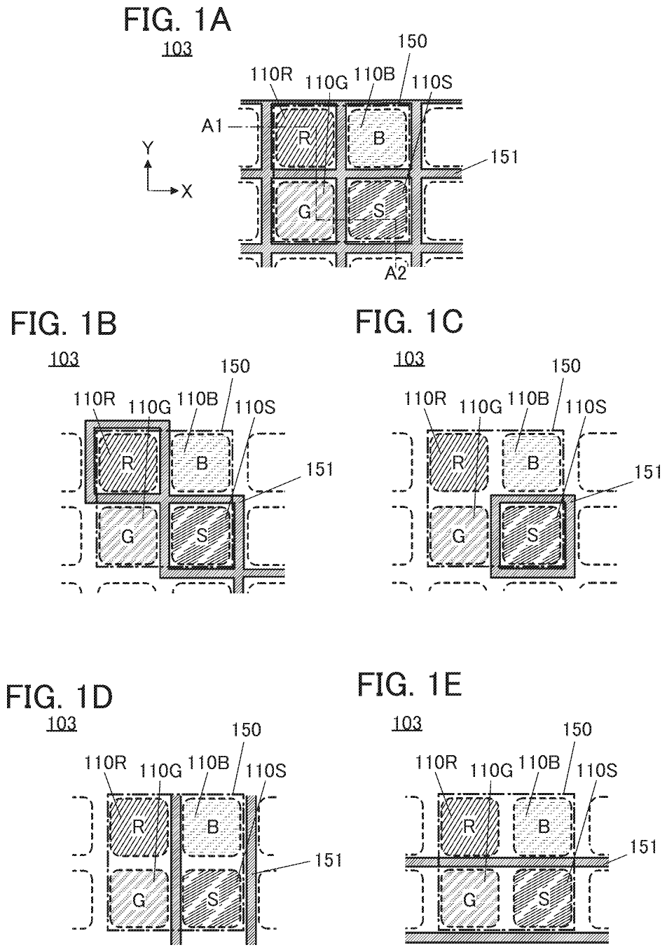

FIG. 1A to FIG. 1E illustrate top views of a pixel portion 103 included in the display apparatus. In FIG. 1A to FIG. 1E, the X direction and the Y direction intersecting the X direction are denoted and a structure of the pixel portion 103 and the like are described using the directions.

The pixel portion 103 is positioned in a display region and includes a plurality of pixels 150. The display apparatus includes a protection circuit and/or a driver circuit besides the pixel portion 103 in some cases. The pixel 150 includes at least a subpixel 110R, a subpixel 110G, and a subpixel 110B. The subpixel 110R, the subpixel 110G, and the subpixel 110B correspond to light-emitting regions of light-emitting devices, and for example, the subpixel 110R, the subpixel 110G, and the subpixel 110B correspond to a light-emitting region of the light-emitting device of red (sometimes referred to as R), a light-emitting region of the light-emitting device of green (sometimes referred to as G), and a light-emitting region of the light-emitting device of blue (sometimes referred to as B), respectively.

Note that the display apparatus of one embodiment of the present invention is not limited to the above emission colors, and a light-emitting region of white may be included in addition to the light-emitting regions of red, green, and blue, for example.

The subpixel 110R, the subpixel 110G, and the subpixel 110B are preferably arranged in a matrix (referred to as a matrix arrangement). The matrix arrangement is a regular arrangement, and a plurality of subpixels 110R, a plurality of subpixels 110G, and a plurality of subpixels 110B are arranged in the entire pixel portion 103 in accordance with the regular arrangement as shown in the pixel 150.

The structure at least including the subpixel 110R, the subpixel 110G, and the subpixel 110B enables full-color display of the display apparatus of one embodiment of the present invention. Moreover, the display apparatus of this embodiment includes a light-receiving portion 110S. Thus, in this specification and the like, a group in which the light-receiving portion 110S is added to the subpixel 110R, the subpixel 110G, and the subpixel 110B is referred to as the pixel 150. In other words, the pixel is used as “the minimum unit capable of full-color display” in this specification and the like; thus, in the pixel, not only the subpixel corresponding to at least each color but also at least a light-receiving portion may be included besides the subpixel. Note that the light-receiving portion 110S does not need to be positioned in all the pixels 150. For example, one light-receiving portion 110S is made to be provided for the plurality of pixels 150. Thus, the light-receiving portion 110S is not necessarily included in the pixel 150, and one light-receiving portion 110S is made to be provided for the plurality of pixels 150, whereby the display apparatus of one embodiment of the present invention can be provided with an image capturing function.

In this specification and the like, when a common part of the subpixel 110R, the subpixel 110G, and the subpixel 110B is described, the term “subpixel 110” is used. The subpixel 110 includes a switching element for controlling the light-emitting device in addition to the light-emitting device exhibiting one emission color. The display apparatus can perform full-color display by light emission from the light-emitting device which is controlled by the switching element. To perform full-color display, the subpixel 110R, the subpixel 110G, and the subpixel 110B may each include a coloring layer, and a color filter or a color conversion layer can be given as the coloring layer, for example. In the top views illustrated in FIG. 1A to FIG. 1E, for example, a coloring layer is regarded as overlapping with regions denoted by R, G, and B.

The light-receiving portion 110S includes a light-receiving device. The light-receiving portion 110S further includes a switching element for controlling the light-receiving device. The light-receiving device controlled by the switching element has a function of receiving light from a light source and can convert the received light into an electric signal. Thus, the light-receiving device is sometimes referred to as a photoelectric conversion device. As the light source of the light-receiving device, visible light or infrared light can be used. In the case of visible light, there is no particular limitation on a wavelength of light and for example, light with a wavelength of blue, violet, bluish violet, green, yellowish green, yellow, orange, red, or the like can be used. The light-receiving device preferably receives one piece or two or more pieces of light selected from the above-described light as visible light.

Furthermore, it is preferable that light emitted from the subpixels be used as a light source and that the light-receiving device can receive light emitted from the subpixels. This case is preferable because another light source does not need to be provided. Although green (a typical wavelength of greater than or equal to 480 nm and less than or equal to 560 nm) is an example of the light emitted from the subpixels, the green is preferable because of corresponding to a wavelength with high detection sensitivity of the light-receiving device.

The arrangement of an auxiliary wiring 151 and the like is described with reference to FIG. 1A. The pixel 150 in FIG. 1A includes the subpixel 110R, the subpixel 110B adjacent to the subpixel 110R in the X direction, the subpixel 110G adjacent to the subpixel 110R in the Y direction, and the light-receiving portion 110S adjacent to the subpixel 110B in the Y direction.

The auxiliary wiring 151 illustrated in FIG. 1A is provided in a region not overlapping with the subpixel 110R, the subpixel 110G, the subpixel 110B, and the light-receiving portion 110S, and has a lattice shape in a plan view. The lattice is one pattern in which a plurality of vertical lines arranged in parallel are combined with a plurality of horizontal lines arranged in parallel. The auxiliary wiring 151 in FIG. 1A includes regions extending along the X direction as horizontal lines and the regions are in parallel. The auxiliary wiring 151 in FIG. 1A also includes regions extending along the Y direction as vertical lines and the regions are in parallel.

The auxiliary wirings 151 illustrated in FIG. 1A are positioned between the subpixels 110R and the subpixels 110G as regions extending along the X direction, and the regions are in parallel with a gap of the subpixels therebetween. The auxiliary wirings 151 illustrated in FIG. 1A are positioned between the subpixels 110R and the subpixels 110B as regions extending along the Y direction, and the regions are in parallel with a gap of the subpixels therebetween.

The common electrode not illustrated in FIG. 1A is electrically connected to the auxiliary wiring 151 illustrated in FIG. 1A, whereby voltage drop due to the common electrode can be inhibited. Furthermore, the auxiliary wiring 151 illustrated in FIG. 1A has an arrangement provided such that the light-receiving portion 110S is surrounded; thus, the auxiliary wiring 151 has an effect of inhibiting stray light. In the case where only the effect of inhibiting stray light is produced, the light-blocking body may replace the auxiliary wiring and the arrangement of the light-blocking body can also be understood by referring to FIG. 1A.

Next, an auxiliary wiring having an arrangement different from that in FIG. 1A is described with reference to FIG. 1B. FIG. 1B illustrates the pixel 150 in the same arrangement as that in FIG. 1A. The auxiliary wiring 151 illustrated in FIG. 1B is provided so as to sequentially surround the subpixel 110R, the light-receiving portion 110S, and the like aligned in an oblique direction in the pixel portion 103. The auxiliary wirings 151 illustrated in FIG. 1B include regions extending along the X direction and regions extending along the Y direction, and the regions can be read on the basis of FIG. 1B in a manner similar to that in FIG. 1A. Note that the regions of the auxiliary wiring in FIG. 1B are smaller than the regions of the auxiliary wiring in FIG. 1A.

The common electrode not illustrated in FIG. 1B is electrically connected to the auxiliary wiring 151 illustrated in FIG. 1B, whereby voltage drop due to the common electrode can be inhibited. Furthermore, the auxiliary wiring 151 illustrated in FIG. 1B has an arrangement provided such that the light-receiving portion 110S is surrounded; thus, the auxiliary wiring 151 has an effect of inhibiting stray light. In the case where only the effect of inhibiting stray light is produced, the light-blocking body may replace the auxiliary wiring and the arrangement of the light-blocking body can also be understood by referring to FIG. 1B.

Next, an auxiliary wiring having an arrangement different from those in FIG. 1A and FIG. 1B is described with reference to FIG. 1C. FIG. 1C illustrates the pixel 150 in the same arrangement as that in FIG. 1A. The auxiliary wiring 151 illustrated in FIG. 1C is provided so as to surround at least the light-receiving portion 110S. The auxiliary wirings 151 illustrated in FIG. 1C include regions extending along the X direction and regions extending along the Y direction, and the regions can be read on the basis of FIG. 1C in a manner similar to that in FIG. 1A. Note that the regions of the auxiliary wiring in FIG. 1C are smaller than the regions of the auxiliary wiring in FIG. 1A.

The common electrode not illustrated in FIG. 1C is electrically connected to the auxiliary wiring 151 illustrated in FIG. 1C, whereby voltage drop due to the common electrode can be inhibited. Furthermore, the auxiliary wiring 151 illustrated in FIG. 1C has an arrangement provided such that the light-receiving portion 110S is surrounded; thus, the auxiliary wiring 151 has an effect of inhibiting stray light. In the case where only the effect of inhibiting stray light is produced, the light-blocking body may replace the auxiliary wiring and the arrangement of the light-blocking body can also be understood by referring to FIG. 1C.

Next, an auxiliary wiring having an arrangement different from those in FIG. 1A to FIG. 1C is described with reference to FIG. 1D. FIG. 1D illustrates the pixel 150 in the same arrangement as that in FIG. 1A. The auxiliary wiring 151 illustrated in FIG. 1D is provided at least between the light-receiving portion 110S and the subpixel 110G. The auxiliary wirings 151 illustrated in FIG. 1D include regions extending along the Y direction, and the regions can be read from a drawing in a manner similar to that in FIG. 1A. Note that the regions of the auxiliary wiring in FIG. 1D are smaller than the regions of the auxiliary wiring in FIG. 1A.

The common electrode not illustrated in FIG. 1D is electrically connected to the auxiliary wiring 151 illustrated in FIG. 1D, whereby voltage drop due to the common electrode can be inhibited. Furthermore, the auxiliary wiring 151 illustrated in FIG. 1D has an arrangement provided between the light-receiving portion 110S and the subpixel 110G; thus, the auxiliary wiring 151 has an effect of inhibiting stray light. In the case where only the effect of inhibiting stray light is produced, the light-blocking body may replace the auxiliary wiring and the arrangement of the light-blocking body can also be understood by referring to FIG. 1D.

Next, an auxiliary wiring having an arrangement different from those in FIG. 1A to FIG. 1D is described with reference to FIG. 1E. FIG. 1E illustrates the pixel 150 in the same arrangement as that in FIG. 1A. The auxiliary wiring 151 illustrated in FIG. 1E is provided at least between the light-receiving portion 110S and the subpixel 110B. The auxiliary wirings 151 illustrated in FIG. 1E include regions extending along the X direction, and the regions can be read from a drawing in a manner similar to that in FIG. 1A. Note that the regions of the auxiliary wiring in FIG. 1E are smaller than the regions of the auxiliary wiring in FIG. 1A.

The common electrode not illustrated in FIG. 1E is electrically connected to the auxiliary wiring 151 illustrated in FIG. 1E, whereby voltage drop due to the common electrode can be inhibited. Furthermore, the auxiliary wiring 151 illustrated in FIG. 1E has an arrangement provided between the light-receiving portion 110S and the subpixel 110B; thus, the auxiliary wiring 151 has an effect of inhibiting stray light. In the case where only the effect of inhibiting stray light is produced, the light-blocking body may replace the auxiliary wiring and the arrangement of the light-blocking body can also be understood by referring to FIG. 1E.

The arrangements of the auxiliary wiring 151 illustrated in FIG. 1A to FIG. 1E have a common arrangement in terms of not decreasing the aperture ratio or the like and positioning at least in the vicinity of the light-receiving portion 110S. The auxiliary wirings 151 illustrated in FIG. 1A to FIG. 1E enable both the inhibition of voltage drop and the inhibition of stray light.

In the case where the conductive material having a light-transmitting property is used for the auxiliary wiring 151, the aperture ratio or the like does not decrease even when the auxiliary wiring 151 overlaps with the subpixel and the light-receiving portion 110S; thus, the arrangement of the auxiliary wiring 151 is not limited to those illustrated in FIG. 1A to FIG. 1E. The inhibition of stray light becomes difficult when the conductive material having a light-transmitting property is used for the auxiliary wiring 151; thus, the auxiliary wiring having a stacked-layer structure by combining the conductive material having a light-transmitting property and the auxiliary wirings 151 illustrated in FIG. 1A to FIG. 1E may be used to achieve both the inhibition of voltage drop and the inhibition of stray light.

### <Cross-Sectional Structure Example of Auxiliary Wiring>

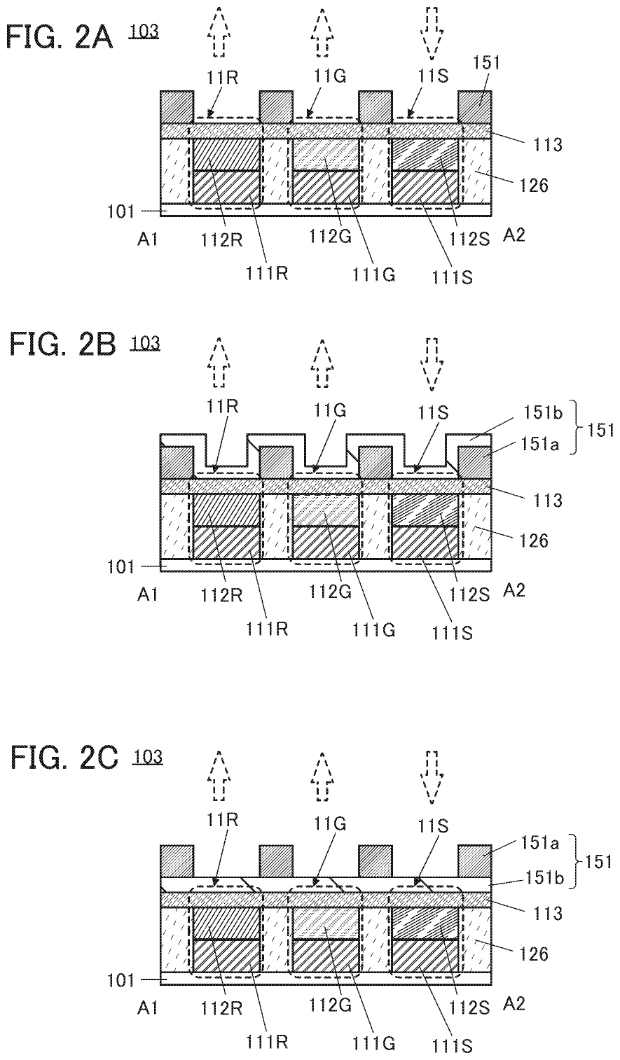

Next, cross-sectional structures of the auxiliary wiring 151 and the like are described. FIG. 2A to FIG. 2C each illustrate a cross-sectional view taken along the dashed-dotted line A1-A2 illustrated in FIG. 1A. Note that the cross-sectional structures of the auxiliary wiring 151 illustrated in FIG. 2A to FIG. 2C can also be applied to cross-sectional structures of the auxiliary wiring 151 and the like illustrated in FIG. 1B to FIG. 1E.

As illustrated in FIG. 2A, a light-emitting device is positioned over a substrate 101. For example, a light-emitting device 11R corresponding to the subpixel 110R is positioned over the substrate 101. Specifically, a lower electrode 111R of the light-emitting device 11R is positioned over the substrate 101, an organic compound layer 112R of the light-emitting device 11R is positioned over the lower electrode 111R, and a common electrode 113 is positioned over the organic compound layer 112R. The light-emitting device 11R can emit light on the common electrode 113 side, that is, in the direction indicated by an arrow in FIG. 2A.

Similarly, a light-emitting device 11G corresponding to the subpixel 110G is positioned. Specifically, a lower electrode 111G of the light-emitting device 11G is positioned over the substrate 101, an organic compound layer 112G of the light-emitting device 11G is positioned over the lower electrode 111G, and the common electrode 113 is positioned over the organic compound layer 112G. The light-emitting device 11G can emit light on the common electrode 113 side, that is, in the direction indicated by an arrow in FIG. 2A.

Although not illustrated in FIG. 2A, a light-emitting device 11B corresponding to the subpixel 110B is positioned. Specifically, a lower electrode 111B of the light-emitting device 11B is positioned over the substrate 101, an organic compound layer 112B of the light-emitting device 11B is positioned over the lower electrode 111B, and the common electrode 113 is positioned over the organic compound layer 112B. The light-emitting device 11B can emit light on the common electrode 113 side.

When a common part of the light-emitting device 11R, the light-emitting device 11G, and the light-emitting device 11B is described, the term “light-emitting device 11” is used in some cases.

When a common part of the organic compound layer 112R, the organic compound layer 112G, and the organic compound layer 112B is described, the term “organic compound layer 112” is used in some cases.

As illustrated in FIG. 2A, a light-receiving device 11S corresponding to the light-receiving portion 110S is positioned. Specifically, a lower electrode 111S of the light-receiving device 11S is positioned over the substrate 101, an active layer 112S of the light-receiving device 11S is positioned over the lower electrode 111S, and the common electrode 113 is positioned over the active layer 112S. The light-receiving device 11S can receive light as indicated by an arrow in FIG. 2A.

The common electrode 113 is a common layer included in each light-emitting device. In FIG. 2A, the light-receiving device 11S also includes the common electrode 113.

In order to describe the lower electrode 111R, the lower electrode 111G, the lower electrode 111B, and the lower electrode 111S not to distinguish from one another, the term “lower electrode 111” is sometimes used.

In the case where a top-emission structure is employed for the display apparatus of one embodiment of the present invention, a visible-light-transmittance of the common electrode 113 is desirably high. Specifically, the visible-light-transmittance of the common electrode 113 only needs to be higher than or equal to 40%.

Note that the lower electrode 111 may have a visible-light-transmittance of higher than or equal to 40%. In this case, the display apparatus of one embodiment of the present invention has a bottom-emission structure. Also in the bottom-emission display apparatus, voltage drop can be inhibited by providing the auxiliary wiring.

Furthermore, a material having a visible-light-transmittance of higher than or equal to 40% is used for the common electrode 113 and the lower electrode 111, the display apparatus of one embodiment of the present invention is a dual-emission display apparatus emitting light in the perpendicular direction, that is, in both directions, of the substrate 101. A dual-emission display apparatus can be referred to as a transparent display. Also in a dual-emission display apparatus, voltage drop can be inhibited by providing the auxiliary wiring.

In a top-emission structure, stray light of light from the light-emitting device is caused by scattering or reflection of the light in upper layers positioned above the common electrode 113 in many cases. Therefore, the auxiliary wiring 151 is preferably provided over the common electrode 113 as illustrated in FIG. 2A to inhibit stray light. As illustrated in FIG. 1A and the like, in order to obtain an effect of not decreasing the aperture ratio of the display apparatus, for example, the auxiliary wiring 151 is positioned in a region over the common electrode 113 and to overlap with neither the light-emitting device nor the light-receiving device.

### <Insulating Layer 126>

An insulating layer 126 is preferably positioned between the light-emitting devices and between the light-emitting device and the light-receiving device as illustrated in FIG. 2A. In this case, the auxiliary wiring 151 is positioned so as to overlap with the insulating layer 126. With the insulating layer 126, the organic compound layers of the light-emitting devices can be separated, in which case a crosstalk between the light-emitting devices can be inhibited.

In FIG. 2A illustrates such that the top surface of the insulating layer 126 is substantially the same as or the same as the top surface of the organic compound layer 112. Such a positional relation is preferably satisfied because the common electrode 113 is not be disconnected.

Although not illustrated in FIG. 2A, the top surface of the insulating layer 126 may be positioned above the top surface of the organic compound layer 112 to prevent the disconnection of the common electrode 113. In that case, the end portion of the insulating layer 126 is preferably made gradually thinner toward the center of the organic compound layer 112. The shape where the thickness is made gradually smaller is sometimes referred to as a tapered shape.

Although not illustrated in FIG. 2A, it is further preferable that the center portion of the insulating layer 126 be positioned above the end portion of the insulating layer 126 and that a region which rises up more than the end portion be included in the center portion. When the common electrode 113 is provided over the insulating layer 126, the disconnection of the common electrode 113 is inhibited.

Although the auxiliary wiring 151 includes a region in contact with the top surface of the common electrode 113 in FIG. 2A, voltage drop can be inhibited as long as electrical connection between the auxiliary wiring 151 and the common electrode 113 is ensured.

### <Light-Receiving Device>

In the light-receiving device 11S illustrated in FIG. 2A, light emitted from the light-emitting devices 11 can be detection light. In that case, the detection light is to be visible light. Green (a typical wavelength of greater than or equal to 480 nm and less than or equal to 560 nm) out of visible light is preferably used because the sensitivity of the light-receiving device 11S is high. For this reason, the light-receiving device 11S is preferably provided adjacent to the light-emitting device 11G. Meanwhile, when light from the light-emitting device 11G is stray light and the light-receiving device 11S receives the stray light, the detection sensitivity decreases. Thus, the auxiliary wiring 151 is preferably positioned at least in a region between the light-receiving device 11S and the light-emitting device 11G which is a light-emitting device emitting detection light. The auxiliary wiring 151 can inhibit voltage drop caused by the common electrode 113 and can have an effect of inhibiting stray light.

Next, an auxiliary wiring having a cross-sectional structure different from that in FIG. 2A is described with reference to FIG. 2B. In FIG. 2B, the auxiliary wiring 151 having a stacked-layer structure is illustrated. A first auxiliary wiring 151a corresponding to a lower layer of the stacked-layer structure can be provided in a manner similar to the auxiliary wiring 151 in FIG. 2A. A conductive material having a light-transmitting property is preferably used for a second auxiliary wiring 151b positioned over the first auxiliary wiring 151a. The second auxiliary wiring 151b can be provided so as to include regions overlapping with the light-emitting devices. A conductive material having a light-transmitting property sometimes has high resistivity; thus, the thickness of the second auxiliary wiring 151b may be larger than that of the first auxiliary wiring 151a. The auxiliary wiring 151 having a stacked-layer structure can inhibit voltage drop caused by the common electrode 113 and can have an effect of inhibiting stray light.

FIG. 2B is similar to FIG. 2A except for the structure of the auxiliary wiring having a stacked-layer structure.

Then, an auxiliary wiring having a cross-sectional structure different from those in FIG. 2A and FIG. 2B is described with reference to FIG. 2C. FIG. 2C illustrates a case where the auxiliary wiring 151 has a stacked-layer structure and the stacking order is different from the auxiliary wiring 151 in FIG. 2B. Specifically, in FIG. 2C, the first auxiliary wiring 151a is positioned over the second auxiliary wiring 151b. Materials and the like of the first auxiliary wiring 151a and the second auxiliary wiring 151b are similar to those in FIG. 2B. The auxiliary wiring 151 having a stacked-layer structure can inhibit voltage drop caused by the common electrode 113 and can inhibit stray light from being received.

FIG. 2C is similar to FIG. 2A except for the structure of the auxiliary wiring having a stacked-layer structure.

By including the auxiliary wiring 151 having the cross-sectional structure as illustrated in each of FIG. 2A to FIG. 2C, voltage drop caused by the common electrode 113 can be inhibited and display quality can be improved. In addition, since the auxiliary wiring 151 includes a region positioned over the common electrode 113, an effect of inhibiting stray light can be produced and the detection sensitivity of the light-receiving device can be improved. Moreover, since the organic compound layer can be cut by the insulating layer 126, a crosstalk or the like can be inhibited. Furthermore, the organic compound layer can be subjected to microfabrication; thus, a high-resolution display apparatus can be provided.

### SPECIFIC EXAMPLES

The display apparatus of one embodiment of the present invention is described with an SBS structure where the light-emitting devices emitting light of different colors are separately formed.

### Specific Example 1

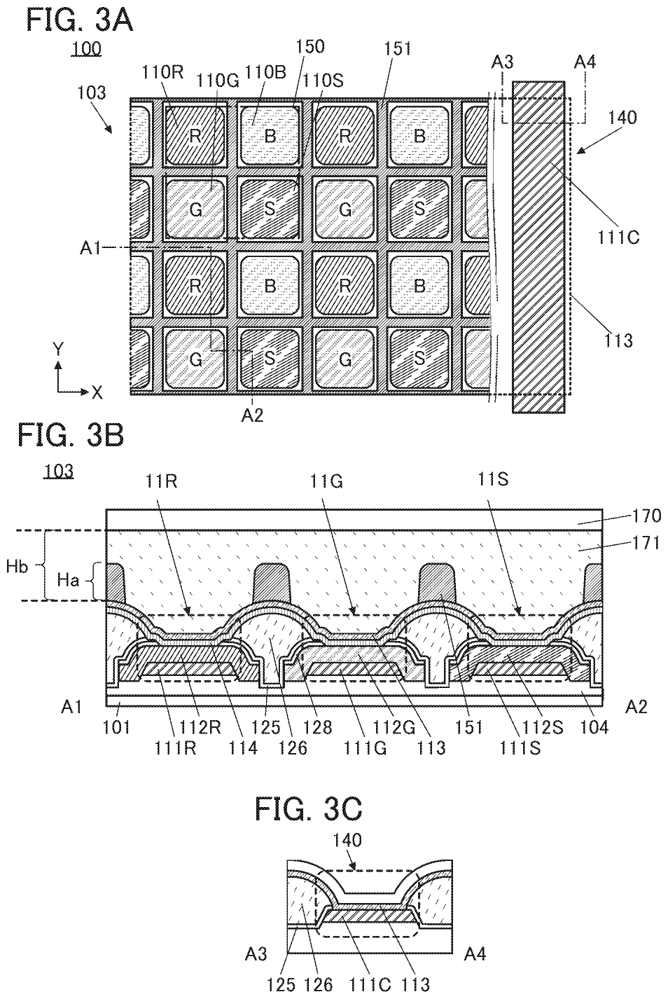

Specific Example 1 of the display apparatus of one embodiment of the present invention is described with reference to FIG. 3A to FIG. 3C. A display apparatus 100 includes the pixel portion 103 and a connection portion 140. The pixel portion 103 includes the plurality of pixels 150. The pixel 150 includes the plurality of subpixels 110, and for example, the subpixel 110R, the subpixel 110G, and the subpixel 110B includes the light-emitting device 11R exhibiting red, the light-emitting device 11G exhibiting green, and the light-emitting device 11B exhibiting blue, respectively. Furthermore, the pixel 150 includes the light-receiving portion 110S, and the light-receiving portion 110S includes the light-receiving device 11S.

In FIG. 3A, a region corresponding to the light-emitting device 11R, the light-emitting device 11G, the light-emitting device 11B, and the light-receiving device 11S are denoted by R, G, B, and S, respectively. The arrangement in FIG. 3A is similar to the arrangements illustrated in FIG. 1A and the like and is a regular arrangement.

As each of the light-emitting device 11R, the light-emitting device 11G, and the light-emitting device 11B, an element such as an OLED (Organic Light Emitting Diode) or a QLED (Quantum-dot Light Emitting Diode) is preferably used. Examples of a light-emitting substance contained in the light-emitting device include a substance that emits fluorescent light (a fluorescent material), a substance that emits phosphorescent light (a phosphorescent material), an inorganic compound (e.g., a quantum dot material), and a substance that exhibits thermally activated delayed fluorescence (a thermally activated delayed fluorescent (TADF) material).

The connection portion 140 illustrated in FIG. 3A is a region including a connection electrode 111C electrically connected to the common electrode 113. The common electrode 113 preferably extends to the connection portion 140 beyond the edge of the pixel portion 103. In FIG. 3A, the common electrode 113 extending to the connection portion 140 is indicated by a dotted line. The connection electrode 111C is supplied with a potential that is to be supplied to the common electrode 113. When voltage drop caused by the common electrode 113 occurs, the value of the potential varies. The display apparatus of this embodiment including at least the auxiliary wiring 151 in the pixel 150 is preferable because the value of the potential does not vary. The auxiliary wiring 151 can be provided in the connection portion 140 as well as in the pixel portion 103.

The connection electrode 111C can be provided along the outer periphery of the pixel portion 103. For example, the connection electrode 111C may be provided along one side of the outer periphery of the pixel portion 103, or the connection electrode 111C may be provided along two or more sides of the outer periphery of the pixel portion 103. In other words, in the case where the top surface shape of the pixel portion 103 is a rectangle, the top surface shape of the connection electrode 111C can be a band shape along one side of the outer periphery of the pixel portion 103, an L shape along two or more sides of the outer periphery of the pixel portion 103, a U shape along three or more sides of the outer periphery of the pixel portion 103, a quadrangle along four or more sides of the outer periphery of the pixel portion 103, or the like.

FIG. 3B and FIG. 3C are each a cross-sectional view taken along the dashed-dotted line A1-A2 and the dashed-dotted line A3-A4 in FIG. 3A. FIG. 3B illustrates a cross-sectional view of the light-emitting device 11R, the light-emitting device 11G, and the light-receiving device 11S, and FIG. 3C illustrates a cross-sectional view of the connection electrode 111C.

The light-emitting device 11R includes the lower electrode 111R, the organic compound layer 112R, a common layer 114, and the common electrode 113. The light-emitting device 11G includes the lower electrode 111G, the organic compound layer 112G, the common layer 114, and the common electrode 113. The light-emitting device 11B includes the lower electrode 111B, the organic compound layer 112B, the common layer 114, and the common electrode 113. A functional layer that can be used as the common layer 114, is an electron-injection layer, for example. Note that a lower electrode is an electrode electrically connected to a transistor, and is sometimes referred to as a pixel electrode. In some cases, a lower electrode functions as one of an anode and a cathode of a light-emitting device and is referred to as an anode or a cathode.

The organic compound layer 112R contains at least a light-emitting organic compound that emits light with intensity in a red wavelength range. The organic compound layer 112G contains at least a light-emitting organic compound that emits light with intensity in a green wavelength range. The organic compound layer 112B contains at least a light-emitting organic compound that emits light with intensity in a blue wavelength range. The layer containing a light-emitting organic compound can be referred to as a light-emitting layer.

The organic compound layer 112 and the common layer 114 can each independently include one or two or more selected from an electron-injection layer, an electron-transport layer, a light-emitting layer, a hole-injection layer, and a hole-transport layer. The electron-injection layer, the electron-transport layer, the light-emitting layer, the hole-injection layer, and the hole-transport layer are sometimes referred to as functional layers. The expression “the layers include two or more layers” refers to the case where two or more layers combining different functional layers and the case where two or more layers combining different materials in the same functional layer are included. Specific materials that can be used for the functional layer are described later.

In this embodiment, the organic compound layer 112 has a stacked-layer structure of a hole-injection layer, a hole-transport layer, a light-emitting layer, and an electron-transport layer sequentially from the lower electrode 111 side, and the common layer 114 has a structure including an electron-injection layer.

Note that the functional layer only needs to exhibit each function and does not necessarily contain the organic compound. For example, a film containing only an inorganic compound or an inorganic substance can be used as an electron-injection layer or the like.

The lower electrode 111R, the lower electrode 111G, and the lower electrode 111B are provided for the respective light-emitting devices. Each of the common electrode 113 and the common layer 114 is provided as a continuous layer shared by the light-emitting devices. A top-emission display apparatus can be obtained with the use of a conductive film having a reflective property for the lower electrodes and a conductive film having a visible-light-transmitting property for the common electrode 113.

The end portion of the lower electrode 111 preferably has a tapered shape. In this specification and the like, a “tapered shape” refers to a shape in which at least part of a side surface of a structure is inclined to a substrate surface or a formation surface. For example, it can be said that the structure has a tapered shape as long as a region having an angle of less than 90° between the inclined side surface and the substrate surface (such an angle is also referred to as a taper angle) can be confirmed. Note that even when the inclined side surface of the structure has a substantially planar surface having a fine curvature or a substantially planar surface having a fine unevenness, these shapes can be referred to as tapered shapes.

The end portion of the organic compound layer 112 is preferably positioned in a region beyond the end portion of the lower electrode 111, and in the case where the end portion of the lower electrode 111 has a tapered shape, the organic compound layer 112 has a shape along the tapered shape. When the side surface of the lower electrode 111 has a tapered shape, the coverage of the organic compound layer or the like is increased. Furthermore, when the side surface of the lower electrode 111 has a tapered shape, a material (e.g., also referred to as dust or particles) in the manufacturing step is easily removed by treatment such as cleaning, which is preferable.

The organic compound layer 112 is processed by a photolithography method. Therefore, an angle formed between the end portion of the organic compound layer 112 and the substrate surface or the formation surface becomes a shape close to 90°, and the end portion of the organic compound layer 112 does not have a tapered shape in some cases. The end portion of the organic compound layer 112 is preferably positioned in the region beyond the end portion of the lower electrode 111.

The insulating layer 126 is preferably provided between the organic compound layers whose end portions do not have tapered shapes, specifically, between two adjacent light-emitting devices. The insulating layer 126 is provided so as to at least fill a gap between two adjacent organic compound layers 112. Further preferably, the insulating layer 126 includes a region overlapping with the end portion of the organic compound layer 112. When part of the insulating layer 126 is positioned so as to overlap with the organic compound layer 112, it is possible to reduce a difference of the heights between the upper portion of the insulating layer 126 and the light-emitting device after the insulating layer 126 is formed. Since the insulating layer 126 is likely to come off in some cases, the difference is preferably small.

In the cross-sectional view, the upper portion of the insulating layer 126 preferably has a convex shape, further preferably has a smooth convex shape. The upper portion having a convex shape can be referred to as a shape where the center portion of the insulating layer 126 rises up more than the end portion thereof.

By providing the common layer 114 and the common electrode 113 while the insulating layer 126 having a shape where the center portion rises up more than the end portion is covered, so that the disconnection of the common layer 114 and the common electrode 113 can be at least inhibited.

Furthermore, an insulating layer 125 is preferably provided in contact with the side surface of the organic compound layer 112 before the step where the insulating layer 126 is formed. The insulating layer 125 is positioned between the insulating layer 126 and the organic compound layer 112 to function as a protective film for preventing contact between the insulating layer 126 and the organic compound layer 112. In the case where the organic compound layer 112 is in contact with the insulating layer 126, the organic compound layer 112 might be dissolved by an organic solvent or the like used in formation or processing of the insulating layer 126. In view of this, the insulating layer 125 is provided between the organic compound layer 112 and the insulating layer 126 as described in this embodiment, so that the organic compound layer 112 can be protected.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film, or an inorganic insulating film such as a silicon oxide film, each of which is formed by an ALD method, is used as the insulating layer 125, the insulating layer 125 having few pinholes and an excellent function of protecting the organic compound layer can be formed.

Note that in this specification and the like, oxynitride refers to a material that contains more oxygen than nitrogen, and nitride oxide refers to a material that contains more nitrogen than oxygen. For example, in the case where silicon oxynitride is described, it refers to a material that contains more oxygen than nitrogen in its composition. In the case where silicon nitride oxide is described, it refers to a material that contains more nitrogen than oxygen in its composition. The insulating layer 125 can be formed by a sputtering method, a chemical vapor deposition (CVD) method, a pulsed laser deposition (PLD) method, an atomic layer deposition (ALD) method, or the like. The insulating layer 125 is preferably formed by an ALD method achieving good coverage.

An insulating layer containing an organic material can be suitably used as the insulating layer 126. For the insulating layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the insulating layer 126, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used.

Moreover, for the insulating layer 126, a photosensitive resin can be used. A photoresist may be used for the photosensitive resin. As the photosensitive resin, a positive photosensitive material or a negative photosensitive material can be used.

For the insulating layer 126, a starting material of the photosensitive material is preferably used by being diluted with a dilute solution to be greater than or equal to 2 times and less than or equal to 10 times, further preferably greater than or equal to 2 times and less than or equal to 4 times. Using an undiluted solution of the above starting material, the thickness of the insulating layer 126 is greater than or equal to 0.8 μm and less than or equal to 1.2 μm. Using the starting material diluted to be 2 times with a dilute solution, the thickness of the insulating layer 126 is greater than or equal to 0.4 μm and less than or equal to 0.6 μm. Using the starting material diluted to be 3 times with a dilute solution, the thickness of the insulating layer 126 is greater than or equal to 0.5 μm and less than or equal to 0.7 μm. Using the diluted starting material enables the thickness of the insulating layer 126 to be small and the released amount of degassing to be reduced. When the viscosity of the starting material is greater than or equal to 3 cP and less than or equal to 10 cP, preferably greater than or equal to 5 cP and less than or equal to 7 cP, the thickness of the insulating layer 126 can be reduced.

In the case where the photosensitive material is used for the insulating layer 126, the processed insulating layer 126 can be formed by performing light exposure and development. The surface of the processed insulating layer 126 sometimes has a rounded shape or an uneven shape. Note that etching may be performed so that the height of the surface of the processed insulating layer 126 is adjusted. The height of the surface of the insulating layer 126 can be adjusted by being processed by ashing using oxygen plasma.

The insulating layer 126 preferably contains a material absorbing visible light. Using the material absorbing visible light makes the insulating layer 126 exhibit an effect of inhibiting stray light in combination with the auxiliary electrode. For example, the insulating layer 126 itself may be formed of the material absorbing visible light, or the insulating layer 126 may contain a pigment absorbing visible light. For example, a resin that can be used as a color filter transmitting red, blue, or green light and absorbing light of the other colors; a resin that contains carbon black as a pigment and functions as a black matrix; or the like can be used for the insulating layer 126.

The upper portion of the insulating layer 126 preferably has a portion higher than the height of the top surface of the organic compound layer 112. Accordingly, the insulating layer 126 can absorb light emitted from the light-emitting devices 11 to an obliquely upward direction and can exhibit an effect of inhibiting stray light in combination with the auxiliary electrode.

For example, the insulating layer 126 can be formed by a wet film formation method such as spin coating, dipping, spray coating, ink-jetting, dispensing, screen printing, offset printing, a doctor knife method, slit coating, roll coating, curtain coating, or knife coating. Specifically, it is preferable to form an organic insulating film to be the insulating layer 126 by spin coating.

After the insulating layer 126 is formed, heat treatment is preferably performed at higher than or equal to 85° C. and lower than or equal to 120° C. for longer than or equal to 45 minutes and shorter than or equal to 100 minutes in the air. Thus, dehydration or degassing from the insulating layer 126 can be performed.

Between the insulating layer 125 and the insulating layer 126, a reflective film (e.g., a metal film containing one or more selected from silver, palladium, copper, titanium, aluminum, and the like) may be provided. For example, the above-described reflective film can be formed after the insulating layer 125 is formed. By the reflective film, light emitted from the light-emitting layer can be reflected. This can improve light extraction efficiency.

As illustrated in FIG. 3B, an insulating layer 128 may be provided between the insulating layer 125 and the top surface of the organic compound layer 112. The insulating layer 128 is a layer in which part of a protective layer (also referred to as a sacrificial layer) for protecting the organic compound layer 112 is left at the etching of the organic compound layer 112. For the insulating layer 128, the material that can be used for the insulating layer 125 is preferably used. It is particularly preferable to use the same material for the insulating layer 128 and the insulating layer 125 because processing is facilitated. For example, both the insulating layer 128 and the insulating layer 125 preferably include an aluminum oxide film, a hafnium oxide film, or a silicon oxide film.

All of the insulating layer 125, the insulating layer 126, and the insulating layer 128 are insulating layers positioned between the light-emitting devices and these are collectively referred to as an “insulating stack” in some cases in this specification and the like. Since the common layer 114 and the common electrode 113 are provided over the insulating stack, the end portion of the insulating stack preferably has a tapered shape so that the common layer 114 and the common electrode 113 are not disconnected. In order that the end portion of the insulating stack can have a tapered shape, the end portion of the insulating layer 125 may have a tapered shape, the end portion of the insulating layer 126 may have a tapered shape, the end portion of the insulating layer 128 may have a tapered shape, or all of the end portions of the insulating layer 125, the insulating layer 126, and the insulating layer 128 may have tapered shapes. In the case where the tapered shape is formed by a plurality of insulating layers, the tapered shapes of the end portions of the insulating layers are preferably formed continuously.

Furthermore, the center portion of the insulating stack preferably has a rounded top surface. In other words, the center portion of the insulating stack has a shape where the center portion rises up more than the end portion thereof. To be the above shape, the insulating layer 126 positioned on the uppermost layer of the insulating stack is preferably formed using an organic material.

Furthermore, the end portion of the insulating stack can have various shapes. For example, the insulating layer 125 positioned below the insulating stack may protrude from the insulating layer 126. In that case, part of the upper portion of the insulating layer 125 may be removed in the processing of the insulating layer 126. When part of the upper portion of the insulating layer 125 protruding from the insulating layer 126 is removed, an effect in which the common layer 114 and the common electrode 113 are not disconnected can be produced.

The insulating layer 128 may protrude from the insulating layer 126. In that case, part of the upper portion of the insulating layer 128 is sometimes removed in the processing of the insulating layer 126. When part of the upper portion of the insulating layer 128 protruding from the insulating layer 126 is removed, an effect in which the common layer 114 and the common electrode 113 are not disconnected can be produced.

When the insulating layer 128 protrudes from the insulating layer 126, the end portion of the insulating layer 125 positioned below the insulating layer 128 is preferably aligned or substantially aligned with the end portion of the insulating layer 128

The auxiliary wiring 151 is provided over the common electrode 113. The thickness of the auxiliary wiring 151 (the distance denoted by Ha in FIG. 3B) is described. The thickness of the auxiliary wiring 151 (Ha) is preferably less than or equal to ½ of the distance from the bottom surface of the auxiliary wiring 151 to a substrate 170 (the distance denoted by Hb in FIG. 3B). In this case, both an effect of inhibiting stray light and an effect of inhibiting voltage drop can be sufficiently exhibited.

The common electrode 113 and the auxiliary wiring 151 are bonded to the substrate 170 with an adhesive layer 171. For the adhesive layer 171, a variety of curable adhesives such as a photocurable adhesive such as an ultraviolet curable adhesive, a reactive curable adhesive, a thermosetting adhesive, and an anaerobic adhesive can be used. An adhesive sheet or the like may be used for the adhesive layer 171.

In the connection portion 140 illustrated in FIG. 3C, opening portions are provided in the insulating layer 125 and the insulating layer 126 over the connection electrode 111C. Through the opening portions, the connection electrode 111C and the common electrode 113 are electrically connected to each other. The opening portions for electrically connecting the connection electrode 111C to the common electrode 113 may be provided in any of the insulating layers.

Although FIG. 3C illustrates the connection portion 140 including a region where the connection electrode 111C is in contact with the common electrode 113, the common layer 114 may be provided over the connection electrode 111C and the common electrode 113 may be provided over the common layer 114. In the case where a carrier-injection layer such as an electron-injection layer is used for the common layer 114, for example, the resistivity of the material used for the common layer 114 is sufficiently low; thus, the connection electrode 111C can be electrically connected to the common electrode 113 with the common layer 114 therebetween. Therefore, the common electrode 113 and the common layer 114 can be formed using the same mask (also referred to as an area mask, a rough metal mask, or the like to distinguish from a fine metal mask), leading to reduction in the manufacturing cost.

A structure example of the display apparatus whose structure is partly different from that of the above-described structure example is described below. Hereinafter, portions overlapping with those in Specific Example 1 are denoted by the same reference numeral as those in Specific Example 1, and the description thereof is not repeated in some cases.

### Specific Example 2

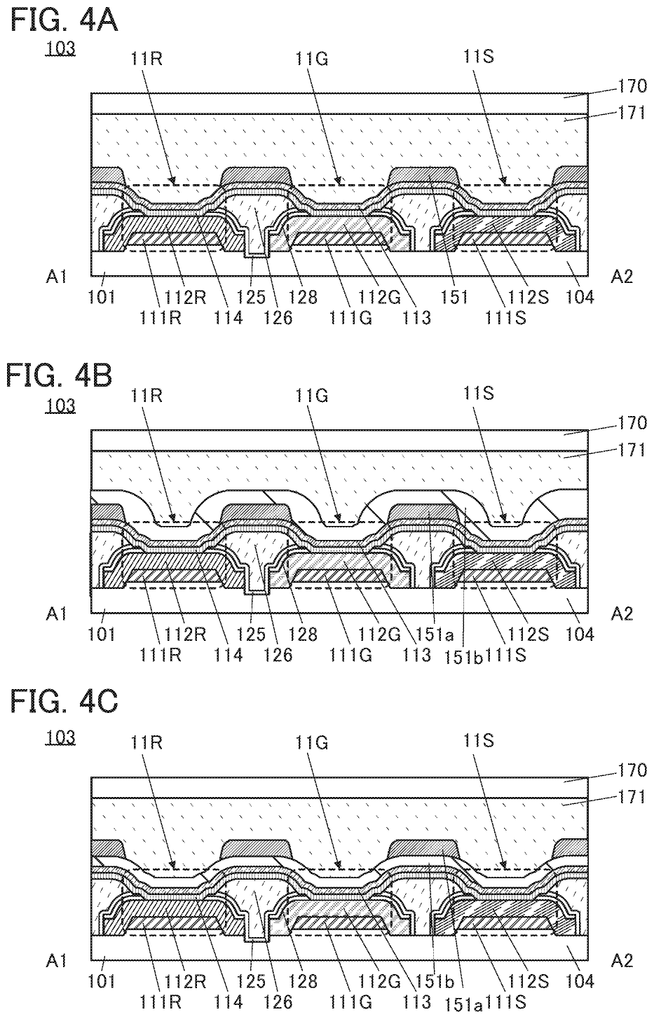

Specific Example 2 of the display apparatus of one embodiment of the present invention is described with reference to FIG. 4A.

FIG. 4A is different from FIG. 3B and the like in that the shape of the upper portion of the insulating layer 126 has a flat region. The structure of the end portion of the insulating layer 126 is similar to that in FIG. 3B. Depending on the material or the formation condition used for the insulating layer 126, the shape of the insulating layer 126 can be made different. The common layer 114 and the common electrode 113 are provided to cover the top surface of the insulating layer 126 whose upper portion shape is flat.

The auxiliary wiring 151 is provided over the insulating layer 126 with the common electrode 113 and the like therebetween. The top surface of the common electrode 113 which is the formation surface of the auxiliary wiring 151 is to have a shape along the top surface of the insulating layer 126. In FIG. 4A, the shape of the upper portion of the insulating layer 126 has a flat region; thus, the planarity of the formation surface of the auxiliary wiring 151 is increased, whereby the auxiliary wiring 151 can be easily formed. The auxiliary wiring 151 whose formation surface has the planarity can have a shape whose width is wider than the height; thus, voltage drop can be sufficiently inhibited. The other structures are similar to those in FIG. 3B and the like. The auxiliary wiring 151 can inhibit voltage drop and can have an effect of inhibiting stray light.

### Specific Example 3

Specific Example 3 of the display apparatus of one embodiment of the present invention is described with reference to FIG. 4B.

In FIG. 4B, the auxiliary wiring 151 having a stacked-layer structure is provided. Specifically, the second auxiliary wiring 151b is provided over the first auxiliary wiring 151a. The first auxiliary wiring 151a can be provided in a manner similar to the auxiliary wiring 151 in FIG. 4A. The second auxiliary wiring 151b has a conductive material having a light-transmitting property and can be provided so as to include a region overlapping with the light-emitting device. The thickness of the second auxiliary wiring 151b may be larger than the thickness of the first auxiliary wiring 151a. The other structures are similar to those in FIG. 4A and the like. The auxiliary wiring 151 having a stacked-layer structure can inhibit voltage drop and can have an effect of inhibiting stray light.

### Specific Example 4

Specific Example 4 of the display apparatus of one embodiment of the present invention is described with reference to FIG. 4C.

In FIG. 4C, the auxiliary wiring 151 having a stacked-layer structure is provided. Specifically, the stacking order is different from the auxiliary wiring 151 in FIG. 4B and the first auxiliary wiring 151a is provided over the second auxiliary wiring 151b. The second auxiliary wiring 151b has a conductive material having a light-transmitting property and can be provided so as to include a region overlapping with the light-emitting device. The first auxiliary wiring 151a can be provided in a manner similar to the auxiliary wiring 151 in FIG. 4A. The thickness of the second auxiliary wiring 151b may be larger than the thickness of the first auxiliary wiring 151a. The other structures are similar to those in FIG. 4A and the like. The auxiliary wiring 151 having a stacked-layer structure can inhibit voltage drop and can have an effect of inhibiting stray light.

### Specific Example 5

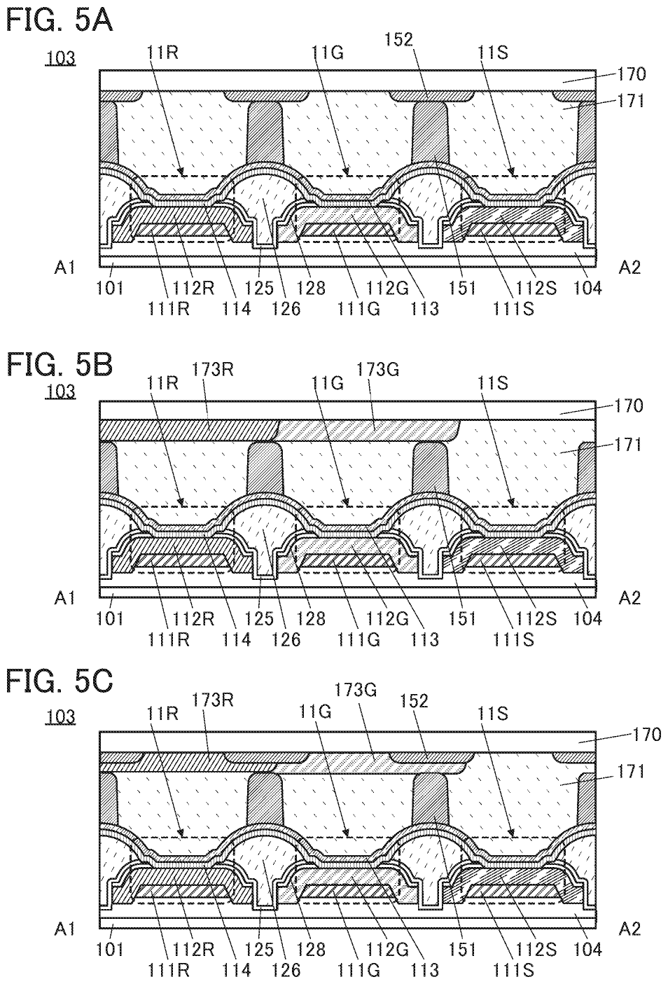

Specific Example 5 of the display apparatus of one embodiment of the present invention is described with reference to FIG. 5A.

In FIG. 5A, a light-blocking layer 152 is provided on the substrate 170. The auxiliary wiring 151 preferably includes a region in contact with the light-blocking layer 152. The other structures are similar to those in FIG. 3B and the like. The auxiliary wiring 151 can inhibit voltage drop and can have an effect of inhibiting stray light.

### Specific Example 6

Specific Example 6 of the display apparatus of one embodiment of the present invention is described with reference to FIG. 5B.

In FIG. 5B, a coloring layer 173R which transmits red light and a coloring layer 173G which transmits green light are provided on the substrate 170. Although the light-emitting device 11B is omitted in FIG. 5B, a coloring layer 173B which transmits blue light is provided in a position overlapping with the light-emitting device 11B. Note that a coloring layer is preferably not provided in a region overlapping with the light-receiving device 11S.

The end portion of the coloring layer 173R may include a region overlapping with the end portion of the coloring layer 173G. The end portion of the coloring layer 173G may include a region overlapping with the end portion of the coloring layer 173B. These overlapping regions can function as light-blocking regions.

When a common part of the coloring layer 173R, the coloring layer 173G, and the coloring layer 173B is described, the term “coloring layer 173” is used in some cases.

The auxiliary wiring 151 preferably includes a region in contact with the coloring layer 173. The other structures are similar to those in FIG. 3B and the like. The auxiliary wiring 151 can inhibit voltage drop and can have an effect of inhibiting stray light.

### Specific Example 7

Specific Example 7 of the display apparatus of one embodiment of the present invention is described with reference to FIG. 5C.

In FIG. 5C, the coloring layer 173R and the coloring layer 173G are provided on the substrate 170, and the light-blocking layer 152 is provided in a region where the coloring layer 173R and the coloring layer 173G overlap with each other. The auxiliary wiring 151 preferably includes a region in contact with the coloring layer 173. The other structures are similar to those in FIG. 3B and the like. The auxiliary wiring 151 can inhibit voltage drop and can have an effect of inhibiting of stray light.

### Variation Examples

In Specific Examples, the display apparatus of one embodiment of the present invention has been described using an SBS structure where the light-emitting devices emitting light of different colors are separately formed. In Variation Examples, an example of a display apparatus which can perform full-color display by combining a plurality of light-emitting devices emitting white light and a coloring layer is described. A color filter or a color conversion layer can be used as the coloring layer. Although the light-emitting device emitting white light preferably has a tandem structure, a single structure may also be employed.

### Variation Example 1

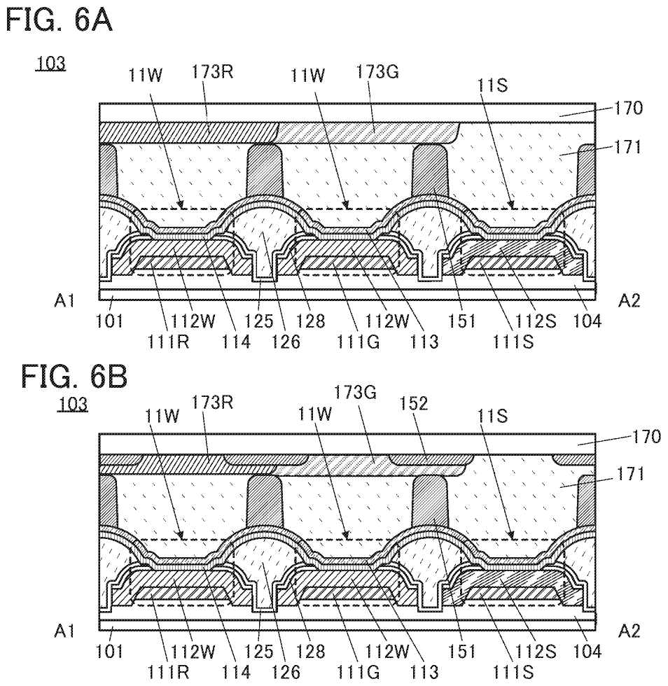

A display apparatus illustrated in FIG. 6A differs from the display apparatus in FIG. 5B in mainly including the light-emitting device emitting white light.

The display apparatus illustrated in FIG. 6A includes a plurality of light-emitting devices 11W. The light-emitting device 11W includes an organic compound layer 112W exhibiting white light emission. The coloring layer 173R and the coloring layer 173G are provided on the substrate 170. Although not illustrated in FIG. 6A, the coloring layer 173B is included. White light emitted from the light-emitting device 11W is colored when light in a predetermined wavelength range is absorbed by the coloring layer 173R, the coloring layer 173G, or the coloring layer 173B, then, the colored light is emitted to the outside through the substrate 170, whereby full-color display can be achieved.

### Variation Example 2

FIG. 6B is an example in which the light-blocking layer 152 is used for the structure illustrated in FIG. 6A. The light-blocking layer 152 is provided on the substrate 170 side like the coloring layer 173. The coloring layer 173 preferably includes a region overlapping with the light-blocking layer 152. FIG. 6B illustrates an example of a case where the coloring layer 173 has a portion positioned between the light-blocking layers 152.

The above is the description of Variation Examples.

The display apparatuses described in Specific Examples and Variation Examples have a common structure in that at least an organic compound layer is cut. With the structure, a crosstalk due to leakage current is inhibited; thus, an image with extremely high display quality can be displayed. Moreover, both a high aperture ratio and a high resolution can be achieved. Thus, the display apparatus can be used for an extremely small display for a head-mounted display (a microdisplay). Note that without limitation to this, the display apparatus of one embodiment of the present invention can be used for an extremely small display that is less than one inch in size to an ultra-large display that is more than 100 inches in size.

### [Light-Emitting Device]

Next, materials and the like that can be used for the light-emitting device is described.

In the light-emitting device, it is preferable that a conductive film having a light-transmitting property be used for an electrode through which light is extracted and a conductive film reflecting visible light be used for an electrode through which no light is extracted. For the electrode through which no light is extracted, a conductive film transmitting visible light may be used concurrently with the conductive film reflecting visible light. In that case, the electrode is preferably positioned between the conductive film reflecting visible light and the organic compound layer. That is, light emitted from the light-emitting device only needs to be reflected by the conductive film reflecting visible light so that extracted from the display apparatus.

As a material that forms the electrode of the light-emitting device, a metal, an alloy, an electrically conductive compound, a mixture thereof, and the like can be used as appropriate. Specific examples include indium tin oxide, In—Si—Sn oxide, indium zinc oxide, In—W—Zn oxide, an alloy containing aluminum (also referred to as an aluminum alloy) such as an alloy containing aluminum, nickel, and lanthanum (also referred to as an Al—Ni—La alloy), an alloy containing silver and magnesium (also referred to as MgAg), and an alloy containing silver, palladium, and copper (also referred to as Ag—Pd—Cu or APC). Alternatively, it is possible to use a metal such as aluminum, titanium, chromium, manganese, iron, cobalt, nickel, copper, gallium, zinc, indium, tin, molybdenum, tantalum, tungsten, palladium, gold, platinum, silver, yttrium, or neodymium, or an alloy containing an appropriate combination of any of these metals. It is also possible to use an element belonging to Group 1 or Group 2 of the periodic table, which is not described above as an example (e.g., lithium, cesium, calcium, or strontium), a rare earth metal such as europium or ytterbium, an alloy containing an appropriate combination of any of these, graphene, or the like.

Among the above materials, it is possible to use a material which can release holes for an anode and a material which can release electrons for a cathode.

The light-emitting device preferably employs a micro optical resonator (microcavity) structure. Therefore, one of the pair of electrodes of the light-emitting device preferably includes an electrode having properties of transmitting and reflecting visible light (a transflective electrode), and the other preferably includes an electrode having a property of reflecting visible light (a reflective electrode). When the light-emitting device has a microcavity structure, light can be resonated between the pair of electrodes and the light emitted from the light-emitting device can be narrowed, whereby the light can be further intensified.

When the micro optical resonator (microcavity) structure is employed, the distance between the pair of electrodes is different in the light-emitting devices of red, green, and blue.

For the transflective electrode, a reflective electrode formed thin enough to transmit part of visible light or a stacked-layer structure of a reflective electrode and an electrode having a visible-light-transmitting property (also referred to as a transparent electrode) can be used.

The transparent electrode has a light transmittance higher than or equal to 40%. For example, an electrode having a visible light (light at wavelengths greater than or equal to 400 nm and less than 750 nm) transmittance higher than or equal to 40% is preferably used in the light-emitting device. The visible light reflectance of the reflective electrode is higher than or equal to 40% and lower than or equal to 100%, preferably higher than or equal to 70% and lower than or equal to 100%.

The organic compound layer of the light-emitting device includes at least a light-emitting layer. The light-emitting layer is a layer that contains a light-emitting material (also referred to as a light-emitting substance). The light-emitting layer can contain one or more kinds of light-emitting substances. As the light-emitting substance, a substance that exhibits an emission color of blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a hole-transport material and an electron-transport material can be used. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

Each of the organic compound layers 112 may further include, as a layer other than the light-emitting layer, a layer containing a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), or the like.

Either a low molecular compound or a high molecular compound can be used in the light-emitting device, and an inorganic compound may also be included. Each layer included in the light-emitting device can be formed by a method such as an evaporation method (including a vacuum evaporation method), a transfer method, a printing method, an inkjet method, or a coating method.

For example, the organic compound layers 112 may each include one or more of a hole-injection layer, a hole-transport layer, a hole-blocking layer, an electron-blocking layer, an electron-transport layer, and an electron-injection layer.

As the common layer 114, one or more of a hole-injection layer, a hole-transport layer, a hole-blocking layer, an electron-blocking layer, an electron-transport layer, and an electron-injection layer can be used. For example, a carrier-injection layer (a hole-injection layer or an electron-injection layer) may be formed as the common layer 114. Note that the light-emitting device does not necessarily include the common layer 114.

The hole-injection layer is a layer injecting holes from the anode to the hole-transport layer, and a layer containing a material with a high hole-injection property. Examples of the material with a high hole-injection property include an aromatic amine compound, a composite material containing a hole-transport material and an acceptor material (an electron-accepting material), and the like.

The hole-transport layer is a layer transporting holes injected from the anode by the hole-injection layer, to the light-emitting layer. The hole-transport layer is a layer containing a hole-transport material. As the hole-transport material, a substance having a hole mobility of 10-6 cm²/Vs or higher is preferable. Note that other substances can also be used as long as the substances have a hole-transport property higher than an electron-transport property. As the hole-transport material, materials with a high hole-transport property, such as a T-electron rich heteroaromatic compound (e.g., a carbazole derivative, a thiophene derivative, and a furan derivative) and an aromatic amine (a compound having an aromatic amine skeleton), are preferred.

The electron-transport layer is a layer transporting electrons injected from the cathode by the electron-injection layer, to the light-emitting layer. The electron-transport layer is a layer containing an electron-transport material. As the electron-transport material, a substance having an electron mobility of 1×10⁻⁶ cm²/Vs or higher is preferable. Note that other substances can also be used as long as the substances have an electron-transport property higher than a hole-transport property. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a T-electron deficient heteroaromatic compound such as a nitrogen-containing heteroaromatic compound.

Other examples of the electron-transport material include, for example, a compound having an unshared electron pair and an electron deficient heteroaromatic ring. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of an organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a: 2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

The electron-injection layer is a layer injecting electrons from the cathode to the electron-transport layer, and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For example, lithium, cesium, and magnesium can be given as an example of the alkali metal or the alkaline earth metal, and lithium fluoride (LiF), cesium fluoride (CsF), calcium fluoride (CaFₓ, X is a given number), lithium oxide (LiOₓ, X is a given number), and cesium carbonate can be given as an example of the compound.

An organic compound can also be used as the material that can be used for the electron-injection layer. Examples of the organic compound include 8-quinolinolato lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), 4,7-diphenyl-1,10-phenanthroline (abbreviation: BPhen), and 2,9-di(naphthalen-2-yl)-4,7-diphenyl-1,10-phenanthroline (abbreviation: NBPhen).

The above organic compound may contain a dopant. A metal may be used as the dopant, and silver (Ag) or ytterbium (Yb) can be used, for example.

As the material that can be used for the electron-injection layer, a composite material containing the organic compound and the alkali metal or the alkaline earth metal can also be used.

The electron-injection layer may have a stacked-layer structure of two or more layers. As the stacked-layer structure, an appropriate combination of materials described above can be used. For example, it is possible to employ a structure where lithium fluoride is used for a first layer and ytterbium is used for a second layer.

For the electron-injection layer, the above-described electron-transport material may be used.

In the case of manufacturing a light-emitting device having a tandem structure, a charge-generation layer (also referred to as an intermediate layer) is provided between two light-emitting units. The intermediate layer has a function of injecting electrons into one of the two light-emitting units and injecting holes to the other when voltage is applied between the pair of electrodes.

For the charge-generation layer, for example, a material that can be used for the electron-injection layer, such as lithium, can be suitably used. For the charge-generation layer, for example, a material that can be used for the hole-injection layer can be suitably used. As the charge-generation layer, a layer containing a hole-transport material and an acceptor material can be used. As the charge-generation layer, a layer containing an electron-transport material and a donor material can be used. Forming such a charge-generation layer can inhibit an increase in the driving voltage in the case of stacking light-emitting units.

### [Light-Receiving Device]

Next, materials that can be used for the light-receiving device is described.

As the active layer 112S, a pn photodiode or a pin photodiode can be used, for example. An n-type semiconductor material and a p-type semiconductor material that can be used for the active layer 112S are described below. The n-type semiconductor material and the p-type semiconductor material may each be formed as a layered shape to be stacked or may be mixed to form one layer.

Examples of the n-type semiconductor material contained in the active layer 112S include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (an acceptor property). When π-electron conjugation (resonance) spreads in a plane as in benzene, an electron-donating property (a donor property) usually increases; however, having a spherical shape, fullerene has a high electron-accepting property even when π-electron conjugation widely spreads therein. The high electron-accepting property efficiently causes rapid charge separation and is useful for a light-receiving element. Both C₆₀ and C₇₀ have a wide absorption band in a visible light region, and C₇₀ is especially preferable because of having a larger π-electron conjugation system and a wider absorption band in the long wavelength region than C₆₀. Other examples of the fullerene derivative include [6,6]-Phenyl-C71-butyric acid methyl ester (abbreviation: PC70BM), [6,6]-Phenyl-C61-butyric acid methyl ester (abbreviation: PC60BM), 1′,1″,4′,4″-Tetrahydro-di [1,4]methanonaphthaleno[1,2:2′,3′,56,60:2″,3″] [5,6]fullerene-C60 (abbreviation: ICBA), and the like.

Another example of the n-type semiconductor material includes a perylenetetracarboxylic derivative such as N,N′-dimethyl-3,4,9,10-perylenetetracarboxylic diimide (abbreviation: Me-PTCDI).

Another example of the n-type semiconductor material includes 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of the p-type semiconductor material contained in the active layer 112S include electron-donating organic semiconductor materials such as copper (II) phthalocyanine (CuPc), tetraphenyldibenzoperiflanthene (DBP), zinc phthalocyanine (ZnPc), tin phthalocyanine (SnPc), quinacridone, and rubrene.

Other examples of the p-type semiconductor material include a carbazole derivative, a thiophene derivative, a furan derivative, and a compound having an aromatic amine skeleton. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, a polythiophene derivative, and the like.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can improve a carrier-transport property.

For example, the active layer 112S is preferably formed by co-evaporation of an n-type semiconductor and a p-type semiconductor. Alternatively, the active layer 112S may be formed by stacking an n-type semiconductor and a p-type semiconductor.

Either a low molecular compound or a high molecular compound can be used in the light-receiving device, and an inorganic compound may also be included. Each layer included in the light-receiving device can be formed by a method such as an evaporation method (including a vacuum evaporation method), a transfer method, a printing method, an inkjet method, or a coating method.

For example, an inorganic compound such as zinc oxide (ZnO) and an organic compound such as polyethylenimine ethoxylated (PEIE) can be used for the light-receiving device, and a mixed film of PEIE and ZnO may be included.

For the active layer 112S, a high molecular compound such as Poly[[4,8-bis[5-(2-ethylhexyl)-2-thienyl]benzo[1,2-b: 4,5-b′]dithiophene-2,6-diyl]-2,5-thiophenediyl[5,7-bis(2-ethylhexyl)-4,8-dioxo-4H,8H-benzo[1,2-c: 4,5-c′]dithiophene-1,3-diyl]] polymer (abbreviation: PBDB-T) or a PBDB-T derivative, which functions as a donor, can be used. For example, a method of dispersing an acceptor material in PBDB-T or a PBDB-T derivative can be used.

The active layer 112S may contain a mixture of three or more kinds of materials. For example, a third material may be mixed with the n-type semiconductor material and the p-type semiconductor material in order to expand the wavelength range. In that case, the third material may be a low molecular compound or a high molecular compound.

### <Layout>

There is no particular limitation on the arrangement of the subpixels, and a stripe arrangement, an S-stripe arrangement, a matrix arrangement, a delta arrangement, a Bayer arrangement, a PenTile arrangement, or the like can be employed.

Examples of the top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

In the display apparatus including the light-emitting device and the light-receiving device in the pixel, the pixel has a light-receiving function, which enables detection of contact or approach of an object while an image is displayed. For example, all the subpixels included in the display apparatus can display an image; alternatively, some of the subpixels can emit light as a light source and the other subpixels can display an image.

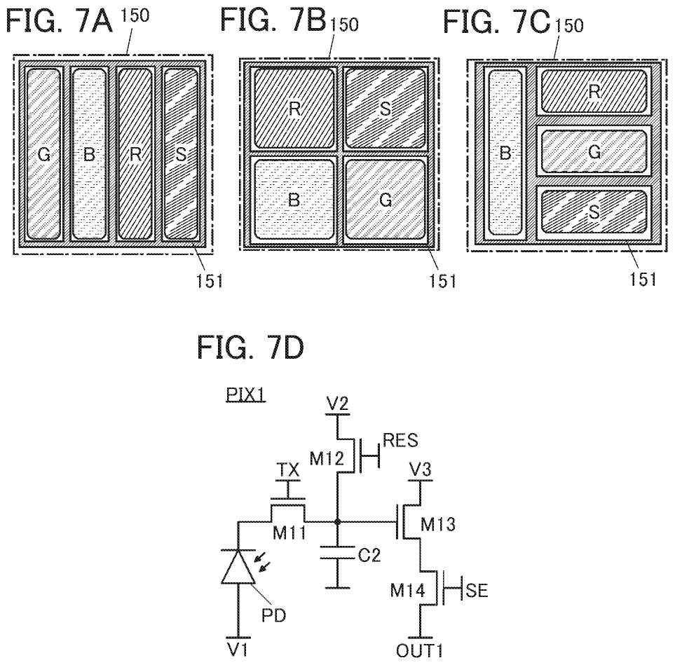

The pixel 150 illustrated in each of FIG. 7A, FIG. 7B, and FIG. 7C includes the subpixel 110G, the subpixel 110B, the subpixel 110R, and the light-receiving portion 110S, and further includes the auxiliary wiring 151. In FIG. 7A, FIG. 7B, and FIG. 7C, R, G, B, and S are denoted in regions corresponding to the subpixel 110G, the subpixel 110B, the subpixel 110R, and the light-receiving portion 110S.

The pixel 150 illustrated in FIG. 7A employs a stripe arrangement. The pixel illustrated in FIG. 7B employs a matrix arrangement. The auxiliary wiring 151 is positioned between the subpixels and between the subpixel and the light-receiving portion. The position of the auxiliary wiring 151 is not limited to those illustrated in FIG. 7A and FIG. 7B.

The pixel 150 illustrated in FIG. 7C employs an arrangement where two subpixels (the subpixel 110R and the subpixel 110G) and the light-receiving portion (110S) are vertically arranged next to one subpixel (the subpixel 110B). The auxiliary wiring 151 is positioned between the subpixels and between the subpixel and the light-receiving portion. The position of the auxiliary wiring 151 is not limited to that illustrated in FIG. 7C.

Note that the layout of the subpixels is not limited to the structures in FIG. 7A to FIG. 7C.

The subpixel 110R includes a light-emitting device that emits red light. The subpixel 110G includes a light-emitting device that emits green light. The subpixel 110B includes a light-emitting device that emits blue light. The light-receiving portion 110S includes the light-receiving device.

When the light-receiving area of the light-receiving portion 110S is smaller than the light-emitting area of the other subpixels, an image capturing range is narrowed and it is possible to inhibit blur in an image capturing result and to improve the definition. Therefore, the display apparatus of one embodiment of the present invention can perform image capturing with high resolution or high definition. For example, image capturing for personal authentication with the use of a fingerprint, a palm print, the iris, the shape of a blood vessel (including the shape of a vein and the shape of an artery), a face, or the like is possible by using the light-receiving portion 110S.

Moreover, the light-receiving portion 110S can be used in a touch sensor (also referred to as a direct touch sensor), a near touch sensor (also referred to as a hover sensor, a hover touch sensor, a contactless sensor, or a touchless sensor), or the like.

The touch sensor or the near touch sensor can detect an approach or contact of an object (a finger, a hand, a pen, or the like). The touch sensor can detect the object when the display apparatus and the object come in direct contact with each other. Furthermore, even when an object is not in contact with the display apparatus, the near touch sensor can detect the object. For example, the display apparatus is preferably capable of detecting an object when the distance between the display apparatus and the object is more than or equal to 0.1 mm and less than or equal to 300 mm, preferably more than or equal to 3 mm and less than or equal to 50 mm. This structure enables the display apparatus to be operated without direct contact of an object, that is, enables the display apparatus to be operated in a contactless (touchless) manner. With the above-described structure, the display apparatus can have a reduced risk of being dirty or damaged, or can be operated without the object directly touching a dirt (e.g., dust or a virus) attached to the display apparatus.

In the case where high-resolution image capturing is performed, the light-receiving portion 110S is preferably provided in all of the pixels included in the display apparatus. Meanwhile, in the case where the light-receiving portion 110S is used in the touch sensor or the near touch sensor, high accuracy is not required as compared to the case of capturing an image of a fingerprint or the like; accordingly, the light-receiving portion 110S only needs to be provided in some of the pixels included in the display apparatus. When the number of light-receiving portions 110S included in the display apparatus is smaller than the number of subpixels 110R or the like, higher detection speed can be achieved.

FIG. 7D illustrates an example of a pixel circuit of a subpixel including a light-receiving device (PIX1).

The pixel circuit illustrated in FIG. 7D includes a light-receiving device PD, a transistor M11, a transistor M12, a transistor M13, a transistor M14, and a capacitor C2. Here, an example in which a photodiode is used as the light-receiving device PD is illustrated.

An anode of the light-receiving device PD is electrically connected to a wiring V1 and a cathode of the light-receiving device PD is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. A gate of the transistor M12 is electrically connected to a wiring RES, and the other of the source and the drain of the transistor M12 is electrically connected to a wiring V2. One of a source and a drain of the transistor M13 is electrically connected to a wiring V3, and the other of the source and the drain of the transistor M13 is electrically connected to one of a source and a drain of the transistor M14. A gate of the transistor M14 is electrically connected to a wiring SE, and the other of the source and the drain of the transistor M14 is electrically connected to a wiring OUT1.

A constant potential is supplied to the wiring V1, the wiring V2, and the wiring V3. When the light-receiving device PD is driven, the wiring V2 is supplied with a potential higher than the potential of the wiring V1. The transistor M12 is controlled by a signal supplied to the wiring RES and has a function of resetting the potential of a node connected to the gate of the transistor M13 to the potential supplied to the wiring V2. The transistor M11 is controlled by a signal supplied to the wiring TX and has a function of controlling the timing at which the potential of the node changes, in accordance with current flowing through the light-receiving device PD. The transistor M13 functions as an amplifier transistor for performing an output corresponding to the potential of the node. The transistor M14 is controlled by a signal supplied to the wiring SE and functions as a selection transistor for reading an output corresponding to the potential of the node by an external circuit electrically connected to the wiring OUT1.

As each of the transistor M11, the transistor M12, the transistor M13, and the transistor M14, a transistor using a metal oxide (an oxide semiconductor) in a semiconductor layer where a channel is formed (such a transistor is also referred to as an OS transistor) is preferably used.

An OS transistor having a wider band gap and a lower carrier density than silicon can achieve extremely low off-state current. Thus, such low off-state current enables long-term retention of charge accumulated in a capacitor that is connected in series with the transistor. Therefore, it is particularly preferable to use an OS transistor including an oxide semiconductor as the transistor M11 and the transistor M12 each of which is connected to the capacitor C2 in series. Moreover, the use of the OS transistors as the other transistors can reduce the manufacturing cost.

For example, the off-state current value per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than the off-state current of a Si transistor by approximately ten orders of magnitude.

Alternatively, transistors using silicon as a semiconductor in which a channel is formed can be used as the transistor M11 to the transistor M14. In particular, the use of silicon with high crystallinity, such as single crystal silicon or polycrystalline silicon, is preferable because high field-effect mobility can be achieved and higher-speed operation is possible.

Alternatively, a transistor containing an oxide semiconductor may be used as one or more of the transistor M11 to the transistor M14, and transistors containing silicon may be used as the other transistors.

Although n-channel transistors are illustrated as the transistors in FIG. 7D, p-channel transistors can also be used.

The refresh rate of the display apparatus of one embodiment of the present invention can be variable. For example, the refresh rate is adjusted (adjusted in the range from 0.01 Hz to 240 Hz, for example) in accordance with contents displayed on the display apparatus, whereby power consumption can be reduced. Moreover, driving with a lowered refresh rate that reduces the power consumption of the display apparatus may be referred to as idling stop (IDS) driving.

The driving frequency of the touch sensor or the near touch sensor may be changed in accordance with the refresh rate. For example, when the refresh rate of the display apparatus is 120 Hz, the driving frequency of the touch sensor or the near touch sensor can be a frequency higher than 120 Hz (can typically be 240 Hz). With this structure, low power consumption can be achieved, and the response speed of the touch sensor or the near touch sensor can be increased.

### Manufacturing Method Example 1

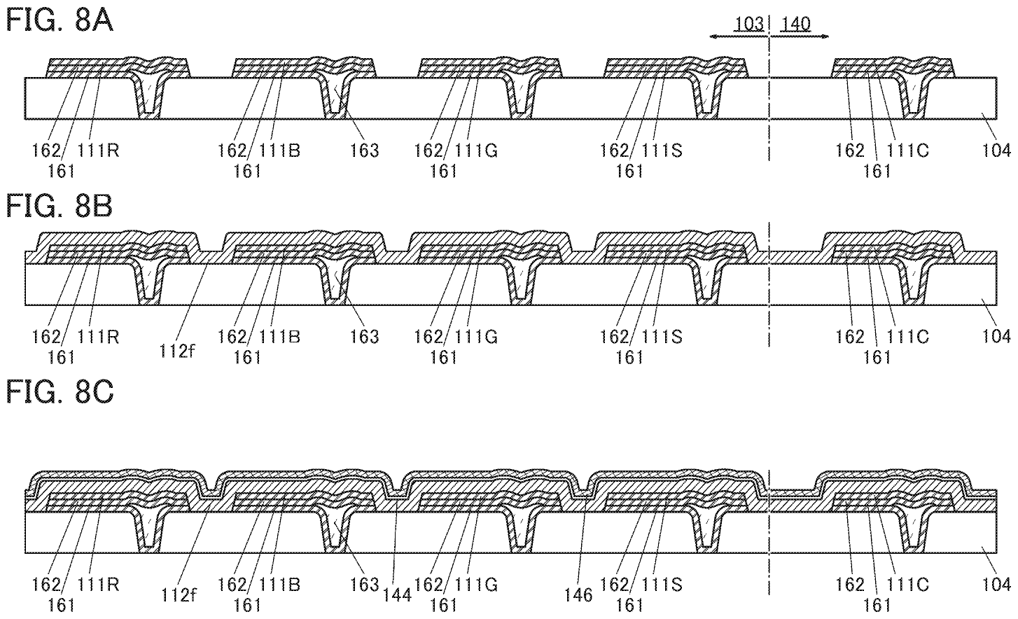

An example of the method for manufacturing the display apparatus in the above-described Variation Example 1 is described with reference to FIG. 8A to FIG. 14. In the drawings, the pixel portion 103 is illustrated on the left side and the connection portion 140 is illustrated on the right side.

Note that thin films that form the display apparatus (insulating films, semiconductor films, conductive films, and the like) can be formed by a sputtering method, a CVD method, a vacuum evaporation method, a PLD method, an ALD method, or the like. Examples of the CVD method include a plasma-enhanced chemical vapor deposition (PECVD: Plasma Enhanced CVD) method, a thermal CVD method, and the like. An example of the thermal CVD method is a metal organic chemical vapor deposition (MOCVD: Metal Organic CVD) method.

The thin films that form the display apparatus can be formed by a method such as spin coating, dipping, spray coating, ink-jetting, dispensing, screen printing, offset printing, a doctor knife method, a slit coater, a roll coater, a curtain coater, or a knife coater. These are wet film formation methods.

The thin films that form the display apparatus can be processed by a photolithography method or the like. Besides, the thin films may be processed by a nanoimprinting method, a sandblasting method, a lift-off method, or the like. The thin films may be directly formed by a film formation method using a metal mask or the like.

There are the following two typical examples of a photolithography method. In one of the methods, a resist mask is formed over a thin film that is to be processed, the thin film is processed by etching or the like, and the resist mask is removed. In the other method, a photosensitive thin film is formed and then processed into a desired shape by light exposure and development.

For light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet light, KrF laser light, ArF laser light, or the like can be used. Alternatively, for the light used for the light exposure, extreme ultraviolet (EUV) light, X-rays, or the like may be used. Furthermore, instead of the light used for the light exposure, an electron beam can also be used. Extreme ultraviolet light, X-rays, or an electron beam is preferably used, in which case extremely minute processing can be performed. Note that when light exposure is performed by scanning of a beam such as an electron beam, a resist mask is not needed.

For etching of the thin films, a dry etching method, a wet etching method, a sandblasting method, or the like can be used.

### Preparation for Substrate

Although not illustrated, a substrate is prepared. As the substrate, a substrate having at least heat resistance high enough to withstand heat treatment performed later can be used. In the case where an insulating substrate is used as the substrate, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate including silicon, silicon carbide, or the like as a material; a compound semiconductor substrate of silicon germanium or the like; or an SOI substrate.

As the substrate, it is preferable to use the semiconductor substrate or the insulating substrate where a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

An insulating layer 104 is formed over the substrate. The insulating layer 104 is the uppermost layer of the insulating layer stacked over the substrate. The insulating layer 104 may have an opening portion. The opening portion formed to reach a transistor, a wiring, an electrode, or the like provided over the substrate so that a conductive layer 161 and the like can be electrically connected to them. Such an opening portion may be referred to as a contact hole. The opening portion can be formed by a photolithography method or the like.

For the insulating layer 104, an inorganic material or an organic material can be used. The organic material is preferable because the planarity of the top surface of the insulating layer 104 can be ensured. As the organic material, one or two or more selected from an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, and the like can be used. When two or more of the above-described materials are used, the selected organic materials may be stacked.

### [Formation of Conductive Layer 161, Resin Layer 163, Conductive Layer 162, and Lower Electrode 111]

Described in this manufacturing method is a case where the conductive layer 161, a resin layer 163, and a conductive layer 162 are formed, and then the lower electrode 111 described in Variation Example 1 is formed.

A conductive film to be the conductive layer 161 is formed over the insulating layer 104. It is preferable that the top surface of the insulating layer 104, which is the formation surface of the conductive film, have a planarity because the conductive film is less likely to be disconnected. For the conductive layer 161, one or two or more of metal materials selected from aluminum, titanium, chromium, manganese, iron, cobalt, nickel, copper, gallium, zinc, indium, tin, molybdenum, tantalum, tungsten, palladium, gold, platinum, silver, yttrium, and neodymium; an alloy combining these as appropriate; and the like can be used.

In the case where the surface of the conductive film has a depressed portion after the conductive film is formed, the layer 163 containing a resin as an organic material (referred to as the resin layer) is preferably formed in the depressed portion. Unevenness caused by the insulating layer 104 and the conductive layer 161 can be reduced by the resin layer 163.

It is preferable to use a photosensitive resin for the resin layer 163. At this time, the resin layer 163 can be formed in the following manner: a resin film is formed first, the resin film is exposed to light through a resist mask, and then the resin film is subjected to development treatment. After that, in order to adjust the height of the top surface of the resin layer 163, the upper portion of the resin layer 163 may be etched by ashing or the like.

In the case where a non-photosensitive resin is used for the resin layer 163, the resin layer 163 can be formed in the following manner: the resin film is formed, and then the upper portion of the resin film is etched to have an optimum thickness until the surface of the conductive film to be the conductive layer 161 is exposed by ashing or the like.

Next, a conductive film to be the conductive layer 162 over the resin layer 163 and the conductive film to be the conductive layer 161 are formed. The conductive layer 162 preferably contains one or two or more selected from a metal and the like described for the conductive layer 161.

Then, a conductive film to be the lower electrode 111 and the connection electrode 111C is formed to cover the conductive film to be the conductive layer 161 and the conductive film to be the conductive layer 162. The lower electrode 111 has a function of an anode or a cathode included in the light-emitting device. For the lower electrode 111, a metal, an alloy, an electrically conductive compound, a mixture of these, and the like can be appropriately used. Specifically, the material described as the electrode of the light-emitting device can be used.

After that, a resist mask is formed over the three conductive films by a photolithography method, and unnecessary portions of the conductive films are removed by etching. Then, by removing the resist mask, the conductive layer 161, the conductive layer 162, the lower electrodes 111, and the connection electrode 111C can be formed in the same etching step using the same resist mask (FIG. 8A).

Note that although the conductive layer 161 and the conductive layer 162 are formed using the same resist mask in the same etching step, the conductive layer 161 and the conductive layer 162 may be separately processed using different resist masks. In this case, it is preferable that the conductive layer 161 and the conductive layer 162 be processed so that the conductive layer 162 is positioned inward from the outline of the conductive layer 161 in a plan view.

Although the conductive layer 162, the lower electrodes 111, and the like are formed in the same etching step using the same resist mask, the conductive layer 162, the lower electrodes 111, and the like may be separately processed using different resist masks. In this case, it is preferable that the conductive layer 162, the lower electrodes 111, and the like be processed so that the lower electrodes 111 are positioned inward from the outline of the conductive layer 162 and the like in a plan view.

### [Formation of Organic Compound Film]

Next, an organic compound film 112f which can emit white light is formed to cover the lower electrodes 111 and the connection electrode 111C (FIG. 8B). The organic compound film 112f may have either a single structure or a tandem structure. The organic compound film 112f is a stack of functional layers.

In the case where the organic compound film 112f has a tandem structure, a first light-emitting unit preferably includes at least a light-emitting layer which can emit blue light. A charge-generation layer is preferably included between the first light-emitting unit and a second light-emitting unit. The second light-emitting unit preferably includes at least a light-emitting layer which can emit green light and a light-emitting layer which can emit red light. In the second light-emitting unit, the light-emitting layer which can emit green light and the light-emitting layer which can emit red light may be in contact with each other and each of the layers preferably contains a phosphorescent material.

For the charge-generation layer, a layer containing a hole-transport material and an acceptor material can be used. For the charge-generation layer, a layer containing an electron-transport material and a donor material can be used.

The above-described material used for the electron-injection layer may be used as the electron-transport material. The charge-generation layer is processed by etching or the like later; thus, among the materials used for the electron-injection layer, a material not containing an alkali metal and an alkaline earth metal is preferable; for example, the organic compound containing the dopant is preferably used. Note that NBPhen can be used for the organic compound, and Ag can be used for the dopant.

The functional layer included in the organic compound film 112f can be formed by a vacuum evaporation method. Note that without limitation to this, the functional layer included in the organic compound film 112f can also be formed by a sputtering method, an inkjet method, or the like.

Note that although the organic compound film 112f is formed to cover the connection electrode 111C in FIG. 8B, the present invention is not limited thereto. For example, by using an area mask for specifying a film formation area, the film formation area of the organic compound film 112f may be inward from the connection portion 140 so that the organic compound film 112f does not overlap with the connection electrode 111C. Accordingly, the connection electrode 111C can be prevented from being in contact with the organic compound film 112f, which is preferable because a remover for removing the organic compound film 112f is not in contact with the surface of the connection electrode 111C.

The organic compound film 112f may be separately formed using a fine metal mask. In that case, the organic compound film 112f is preferably formed to cover only the lower electrode 111R, the lower electrode 111G, and the lower electrode 111B. Accordingly, the lower electrode 111S and the connection electrode 111C can be prevented from being in contact with the organic compound film 112f, which is preferable because the remover for removing the organic compound film 112f is not in contact with the surfaces of the lower electrode 111S and the connection electrode 111C.

It is preferable that the organic compound film 112f include the functional layers and be a stack including at least a hole-injection layer, a hole-transport layer, a light-emitting layer, and an electron-transport layer sequentially from the lower electrode 111, for example.

Note that an electron-injection layer positioned over an electron-transport layer is an example of the functional layer. In this embodiment, the electron-injection layer is a common layer and thus formed later. Any of functional layers may be employed as long as the common layer is positioned between the light-emitting layer and the common electrode. Needless to say, all the functional layers may be divided for each subpixel without providing the common layer.

The electron-transport layer positioned on the uppermost layer of the organic compound film 112f is exposed to a processing process using a photolithography method for obtaining the processed organic compound layer 112. Thus, a material having high heat resistance is preferably used for the electron-transport layer. As the material having high heat resistance, a material having the glass transition point higher than or equal to 110° C. and lower than or equal to 165° C., preferably higher than or equal to 120° C. and lower than or equal to 135° C. is used, for example.

Moreover, the electron-transport layer exposed to processing may have a stacked-layer structure. Examples of the stacked-layer structure include a structure where a second electron-transport layer is stacked over a first electron-transport layer. In the processing, a period when the first electron-transport layer is covered with the second electron-transport layer is included; thus, the heat resistance of the first electron-transport layer may be lower than that of the second electron-transport layer. For example, a material having the glass transition point higher than or equal to 110° C. and lower than or equal to 165° C., preferably higher than or equal to 120° C. and lower than or equal to 135° C. can be used for the second electron-transport layer, and a material having the glass transition point lower than the glass transition point of the second electron-transport layer, for example, higher than or equal to 100° C. and lower than or equal to 155° C., preferably higher than or equal to 110° C. and lower than or equal to 125° C. can be used for the first electron-transport layer.

Although the uppermost layer of the organic compound film 112f is also considered to be the light-emitting layer, damage to the light-emitting layer by the processing might significantly degrade the reliability. In view of the above, in manufacturing the display apparatus of one embodiment of the present invention, the processing is preferably performed after the functional layer (e.g., an electron-transport layer) is formed above the light-emitting layer. A mask layer or the like can be further formed over the organic compound film so that the light-emitting layer can be inhibited from being damaged by the processing. Such a method can provide a highly reliable display panel. Note that in this specification and the like, a mask layer is positioned on the upper portion of the organic compound film and has a function of protecting the organic compound film in the manufacturing process.

### [Formation of Mask Film 144]

Next, a mask film 144 is formed to cover the organic compound film 112f (FIG. 8C). The mask film 144 has a function of protecting the organic compound film 112f at the time of the etching treatment of the organic compound film 112f.

As the mask film 144, a film with high etching selectivity with respect to the organic compound film 112f at the time of the etching treatment of the organic compound film 112f is preferably used. In the case where the mask film is stacked, as the mask film 144, a film with high etching selectivity with respect to the other mask films such as a mask film of the upper layer which is described later (specifically, a mask film 146) is preferably used. Furthermore, when the mask film 144 is removed, a film that can be removed by a wet etching method, which is less likely to give damage to the organic compound film 112f, is preferably used.

As the mask film 144, an inorganic film such as a metal film, an alloy film, a metal oxide film, a semiconductor film, or an inorganic insulating film can be suitably used, for example. The mask film 144 can be formed by any of a variety of deposition methods such as a sputtering method, an evaporation method, a CVD method, and an ALD method.

In particular, the mask film 144, which is formed directly on the organic compound film 112f, is preferably formed by an ALD method that gives less film formation damage on a formation layer.

For the mask film 144, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

Alternatively, for the mask film 144, a metal oxide such as indium gallium zinc oxide (also referred to as In—Ga—Zn oxide or IGZO) can be used. Furthermore, it is possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, for example, indium tin oxide containing silicon can also be used.

Note that, in indium gallium zinc oxide or indium gallium tin zinc oxide, in place of gallium, one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, tin, cobalt, and magnesium may be used. Specifically, one or more kinds selected from aluminum and yttrium are preferable to obtain the same effect as gallium.

The mask film 144 may contain an inorganic material. As the inorganic material, oxide such as aluminum oxide, hafnium oxide, or silicon oxide, nitride such as silicon nitride or aluminum nitride, or oxynitride such as silicon oxynitride can be used. Such an inorganic material can be formed by a deposition method such as a sputtering method, a CVD method, or an ALD method.

The mask film 144 may contain an organic material. For example, as the organic material, a material that can be dissolved in a solvent chemically stable with respect to the organic compound film 112f may be used. In particular, a material that is dissolved in water or alcohol can be suitably used for the mask film 144. In formation of the mask film 144, it is preferable that application of such a material that has been dissolved in a solvent such as water or alcohol be performed by a wet film formation method and followed by heat treatment for evaporating the solvent. At this time, the heat treatment is preferably performed in a reduced-pressure atmosphere, in which case the solvent can be removed at a low temperature in a short time and thermal damage to an EL layer can be reduced accordingly.

A wet film formation method can be used for the formation of the mask film 144.

For the mask film 144, an organic resin such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used. Alternatively, a fluorine resin such as perfluoro polymer may be used for the mask film 144.

### [Formation of Mask Film 146]

Next, the mask film 146 is formed over the mask film 144 (FIG. 8C). Although the mask film is stacked in this embodiment, it is also possible to use only the mask film 144 or only the mask film 146 as a mask film of a single layer to protect the organic compound film 112f.

The mask film 146 is preferably used as a hard mask when the mask film 144 is etched later. After the mask film 146 is processed, the mask film 144 is exposed. Thus, in the case where the mask film 146 is used as the hard mask, a combination of films with high etching selectivity therebetween is preferably selected for the mask film 144 and the mask film 146.

A material of the mask film 146 can be selected from a variety of materials depending on the etching condition of the mask film 144 and the etching condition of the mask film 146. For example, the mask film 146 can be selected from the films that can be used as the mask film 144, and a material different from that of the mask film 144 can be selected.

For example, as the mask film 146, an oxide film or an oxynitride film can be used. A typical oxide film or a typical oxynitride film is a film containing silicon oxide, silicon oxynitride, aluminum oxide, aluminum oxynitride, hafnium oxide, hafnium oxynitride, or the like.

As the mask film 146, a nitride film can be used, for example. A typical nitride film is a film containing silicon nitride, aluminum nitride, hafnium nitride, titanium nitride, tantalum nitride, tungsten nitride, gallium nitride, germanium nitride, or the like.

For the combination of the mask film 144 and the mask film 146, for example, it is possible to use an inorganic material such as aluminum oxide, hafnium oxide, or silicon oxide formed by an ALD method for the mask film 144 and a metal oxide containing indium such as indium gallium zinc oxide (also referred to as In—Ga—Zn oxide or IGZO) formed by a sputtering method for the mask film 146.

For the mask film 146 combined with the mask film 144, one or two or more metals selected from tungsten, molybdenum, copper, aluminum, titanium, tantalum, and the like and an alloy containing the metals can also be used. In the case where the mask film 146 is formed as the hard mask, the metal or the alloy is preferably used. In the case where the mask film 146 is formed as the hard mask, the thickness of the mask film 146 is preferably larger than the thickness of the mask film 144.

### [Formation of Resist Mask 143]

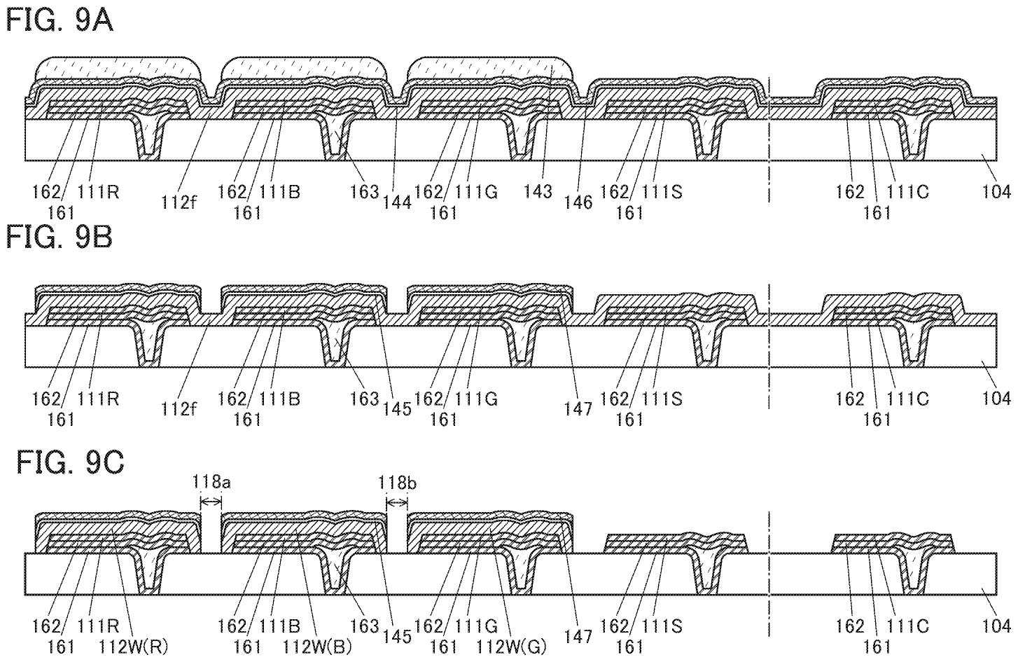

Then, over the mask film 146, a resist mask 143 is formed in positions overlapping with the lower electrode 111R, the lower electrode 111G, and the lower electrode 111B (FIG. 9A). At this time, the resist mask is not formed in positions overlapping with the lower electrode 111S and the connection electrode 111C.

For the resist mask 143, a resist material containing a photosensitive resin, such as a positive type resist material or a negative type resist material can be used.

In the case where a material that dissolves the organic compound film 112f is used for a solvent of the resist material and a defect such as a pinhole exists in the mask film 144 without providing the mask film 146, the organic compound film 112f and the like might be dissolved. In this case, the mask film 146 positioned over the mask film 144 at the time of forming the resist mask 143 can prevent such a problem.

In the case where a material that does not dissolve the organic compound film 112f is used for the solvent of the resist material, the resist mask 143 may be directly formed on the mask film 144 without providing the mask film 146 in some cases.

### [Etching of Mask Film 146]

Next, part of the mask film 146 that is not covered with the resist mask 143 is removed by etching, so that a mask layer 147 is formed (FIG. 9B).

In the etching of the mask film 146, the etching condition with high selectivity is preferably employed so that the mask film 144 is not removed by the etching. The etching of the mask film 146 can be performed by wet etching or dry etching.

### [Removal of Resist Mask 143]

Then, the resist mask 143 is removed. The removal of the resist mask 143 is performed in a state where the organic compound film 112f is covered with the mask film 144. The resist mask 143 can be removed by wet etching or dry etching. It is particularly preferable to perform dry etching (also referred to as plasma ashing) using an oxygen gas as an etching gas to remove the resist mask 143.

Although described again, the resist mask 143 is removed in the state where the organic compound film 112f is covered with the mask film 144; thus, the organic compound film 112f can be inhibited from being damaged by processing. In particular, when the organic compound film 112f is exposed to oxygen, the characteristics thereof might be adversely affected; thus, the etching using the oxygen gas is preferably performed in the state where the organic compound film 112f is covered with the mask film 144. Even in the case where the resist mask 143 is removed by wet etching, the organic compound film 112f can be prevented from being dissolved because the organic compound film 112f is not exposed to a chemical solution.

### [Etching of Mask Film 144]

Next, part of the mask film 144 is removed by etching with use of the mask layer 147 as a hard mask, so that a mask layer 145 is formed (FIG. 9B).

The etching of the mask film 144 can be performed by wet etching or dry etching.

[Etching of Organic Compound Film 112f]

Then, part of the organic compound film 112f which is not covered with the mask layer 145 is removed by etching, so that an organic compound layer 112W (R), an organic compound layer 112W (G), and an organic compound layer 112W (B), which are separated from each other, are formed (FIG. 9C). The organic compound layer 112W (R) is to be an organic compound layer of the light-emitting device which emits red light later, the organic compound layer 112W (G) is to be an organic compound layer of the light-emitting device which emits green light later, and the organic compound layer 112W (B) is to be an organic compound layer of the light-emitting device which emits blue light later.

When a common part of the organic compound layer 112W (R), the organic compound layer 112W (G), and the organic compound layer 112W (B) is described, the term “organic compound layer 112W” is used in some cases. On the outermost surfaces of the organic compound layers 112W, at least a functional layer having high heat resistance, for example, an electron-transport layer, is preferably positioned.

At that time, the organic compound film 112f over the lower electrode 111S and the connection electrode 111C is removed, so that the lower electrode 111S and the connection electrode 111C are exposed.

For the etching of the organic compound film 112f, it is preferable to use dry etching using an etching gas that does not contain oxygen as its main component. This is because, as described above, when the organic compound film 112f is exposed to oxygen, the characteristics thereof might be adversely affected: specifically, the quality of the organic compound film 112f might be changed. However, the use of the etching gas that does not contain oxygen as its main component can inhibit the change in the quality of the organic compound film 112f and can achieve the display apparatus with high reliability. Examples of the etching gas that does not contain oxygen as its main component include CF₄, C₄F₈, SF₆, CHF₃, Cl₂, H₂O, BCl₃, H₂, or a rare gas such as He. Alternatively, a mixed gas of the above gas and a dilution gas that does not contain oxygen may be used as the etching gas.

Note that the etching of the organic compound film 112f is not limited to the above and may be performed by dry etching using another gas or wet etching.

According to the above-described step, the organic compound layer 112W (R), the organic compound layer 112W (G), and the organic compound layer 112W (B) can be formed by processing at a time. This reduces the number of processing to one third compared to the case where the organic compound layers are separately formed for the light-emitting device 11R, the light-emitting device 11G, and the light-emitting device 11B. With use of the above-described method in this manner, the manufacturing process can be simplified and the productivity of the display apparatus of one embodiment of the present invention can be improved.

Note that the insulating layer 104 is exposed when the organic compound film 112f is etched. Thus, a depressed portion of the insulating layer 104 may be formed in a region which overlaps with a slit 118a or a slit 118b. In the case where the depressed portion is not desired to be formed, a film highly resistant to the etching treatment of the organic compound film 112f is preferably used as the insulating layer 104. For example, an insulating film containing an inorganic material is preferably used as the insulating layer 104.

In addition, the slit 118a and the slit 118b are formed between the organic compound layers 112W. That is, in the organic compound layers 112W obtained through the processing step using a photolithography method, the widths of the slit 118a and the slit 118b indicated by arrows in FIG. 9C can be less than or equal to 8 μm, less than or equal to 3 μm, less than or equal to 2 μm, or less than or equal to 1 μm. The widths of the slit 118a and the slit 118b correspond to the distance between the subpixels. When the distance between the subpixels is shortened, the display apparatus with high resolution and a high aperture ratio can be provided. Note that the widths of the slit 118a and the slit 118b are not necessarily constant. For example, the width of the slit 118a may be larger than the width of the slit 118b. The width of the slit 118b may be larger than the width of the slit 118a.

As illustrated by the slit 118a and the slit 118b, the organic compound layers 112W adjacent to each other are separated and a current leakage path (a leakage path) is divided; thus, leakage current (also referred to as side leakage and side leakage current) can be inhibited. In this manner, in the light-emitting device, it is possible to increase luminance, contrast, display quality, and power efficiency or to reduce power consumption, for example.

[Formation of Semiconductor Film 155f]

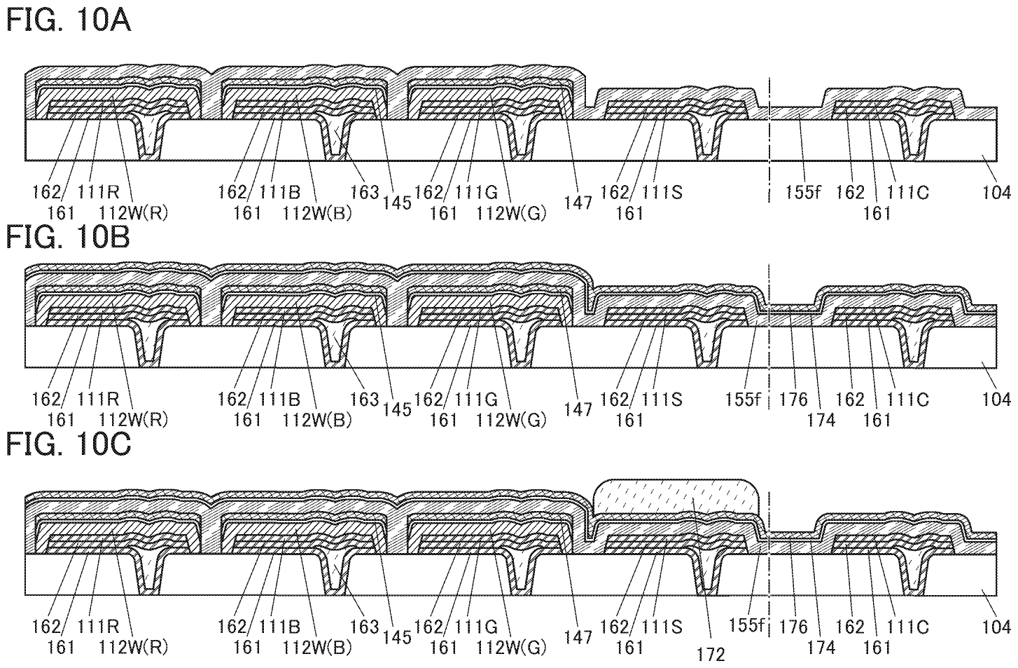

Next, a semiconductor film 155f is formed to cover the lower electrodes 111 and the connection electrode 111C (FIG. 10A). The semiconductor film 155f is a film to be processed into the active layer 112S in a later step and the materials that can be used for the active layer 112S may be used for the semiconductor film 155f. The semiconductor film 155f can be preferably formed by a vacuum evaporation method. Note that without limitation to this, the semiconductor film 155f can also be deposited by a sputtering method, an inkjet method, or the like. The above-described deposition method can be used as appropriate.

Here, the mask layer 145 and the mask layer 147 are provided over the organic compound layers 112W, so that the organic compound layers 112W can be prevented from being in contact with the semiconductor film 155f.

Also in the formation of the semiconductor film 155f, by using an area mask, the film formation area of the semiconductor film 155f may be limited to the inner side of the connection portion 140 so that the semiconductor film 155f does not overlap with the connection electrode 111C. Accordingly, the connection electrode 111C can be prevented from being in contact with the semiconductor film 155f, for example.

### [Formation of Mask Film 174]

Then, a mask film 174 is formed to cover the semiconductor film 155f (FIG. 10B).

As the mask film 174, it is possible to use a film highly resistant to the etching treatment performed on the active layer 112S, i.e., a film with high etching selectivity. Moreover, as the mask film 174, it is possible to use a film with high etching selectivity with respect to a mask film such as a mask film 176 described later. Furthermore, as the mask film 174, it is particularly preferable to use a film that can be removed by a wet etching method that is less likely to cause damage to the active layer 112S.

For the mask film 174, the material that can be used for the mask film 144 can be suitably used. The mask film 174 can be formed by any of a variety of deposition methods such as a sputtering method, an evaporation method, a CVD method, and an ALD method. In particular, the mask film 174 that is formed directly on the semiconductor film 155f is preferably formed by an ALD method, which gives less film formation damage on a formation layer.

### [Formation of Mask Film 176]

Next, the mask film 176 is formed over the mask film 174 (FIG. 10B).

The mask film 176 is preferably used as a hard mask when the mask film 174 is etched later. In a later step of processing the mask film 176, the mask film 174 is exposed. Thus, a combination of films with high etching selectivity therebetween is selected for the mask film 174 and the mask film 176. It is thus possible to select a film that can be used for the mask film 176 depending on the etching condition of the mask film 174 and the etching condition of the mask film 176.

A material of the mask film 176 can be selected from a variety of materials depending on the etching condition of the mask film 174 and the etching condition of the mask film 176. For example, the mask film 176 can be selected from any of the films that can be used as the mask film 144.

For example, it is preferable that an inorganic material such as aluminum oxide, hafnium oxide, or silicon oxide formed by an ALD method be used for the mask film 174, and a metal oxide containing indium such as indium gallium zinc oxide (also referred to as In—Ga—Zn oxide or IGZO) formed by a sputtering method be used for the mask film 176. Alternatively, it is preferable to use a metal such as tungsten, molybdenum, copper, aluminum, titanium, or tantalum or an alloy containing the metal for the mask film 176.

### [Formation of Resist Mask 172]

Then, a resist mask 172 is formed in a position that is over the mask film 176 and overlaps with the lower electrode 111S (FIG. 10C). In that case, the resist mask is not formed in positions overlapping with the lower electrodes 111R, 111G, and 111B and the connection electrode 111C.

For the resist mask 172, the materials that can be used for the resist mask 143 may be used.

### [Etching of Mask Film 176]

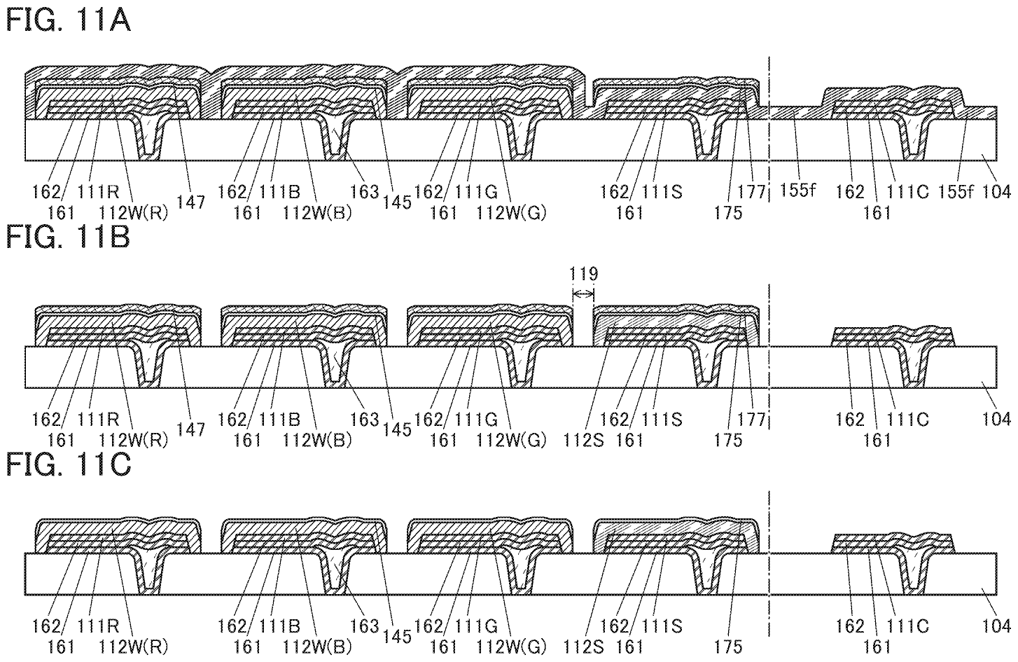

Next, part of the mask film 176 that is not covered with the resist mask 172 is removed by etching, so that a mask layer 177 is formed (FIG. 11A).

In the etching of the mask film 176, the etching condition with high selectivity is preferably employed so that the mask film 174 is not removed by the etching. The etching of the mask film 176 can be performed by wet etching or dry etching.

### [Removal of Resist Mask 172]

Then, the resist mask 172 is removed. The removal of the resist mask 172 can be performed in a manner similar to the removal of the resist mask 143.

### [Etching of Mask Film 174]

Next, part of the mask film 174 is removed by etching with use of the mask layer 177 as a hard mask, so that a mask layer 175 is formed (FIG. 11A).

The etching of the mask film 174 can be performed by wet etching or dry etching.

[Etching of Semiconductor Film 155f]

Then, part of the semiconductor film 155f which is not covered with the mask layer 175 is removed by etching, so that the active layer 112S is formed (FIG. 11B). At this time, the top surfaces of the mask layer 147 and the connection electrode 111C are exposed.

Etching of the semiconductor film 155f can be performed in a manner similar to the etching of the organic compound film 112f.

A slit 119 is formed between the active layer 112S and the organic compound layer 112W. In a gap between the active layer 112S and the organic compound layer 112W obtained through the processing step using a photolithography method, the width of the slit 119 indicated by an arrow in FIG. 11B can be less than or equal to 8 μm, less than or equal to 3 μm, less than or equal to 2 μm, or less than or equal to 1 μm. Although the slit 119 preferably has the same width as that of the slit 118a or the slit 118b between the subpixels, the slit 119 may have larger width than that of the slit 118a or the slit 118b.

As illustrated by the slit 119, the organic compound layer 112W and the active layer 112S are separated from each other, in which case a current leakage path (a leakage path) can be divided. Therefore, leakage current (also referred to as side leakage or side leakage current) between the organic compound layer 112W and the active layer 112S is inhibited; thus, high-resolution image capturing with a high signal-noise ratio (S/N ratio) can be performed. Hence, a clear image can be captured even with weak light. Accordingly, the luminance of the light-emitting device used for a light source in image capturing can be lowered, whereby power consumption can be reduced.

In the above-described step, the processing of the organic compound layer, that is, the patterning thereof can be performed only twice in the display apparatus provided with the light-emitting device and the light-receiving device. With use of the above-described method in this manner, the manufacturing process can be simplified and the productivity of the display apparatus of one embodiment of the present invention can be improved.

Note that the insulating layer 104 is exposed when the semiconductor film 155f is etched. Therefore, a depressed portion of the insulating layer 104 may be formed in a region which overlaps with the slit 119. In the case where the depressed portion is not desired to be formed, a film highly resistant to the etching of the semiconductor film 155f is preferably used as the insulating layer 104. For example, an insulating film containing an inorganic material is preferably used as the insulating layer 104.

### [Removal of Mask Layer]

Next, the mask layer 177 is removed, so that the top surface of the mask layer 175 is exposed (FIG. 11C). At this time, the mask layer 145 remains.

[Formation of Insulating Film 125f]

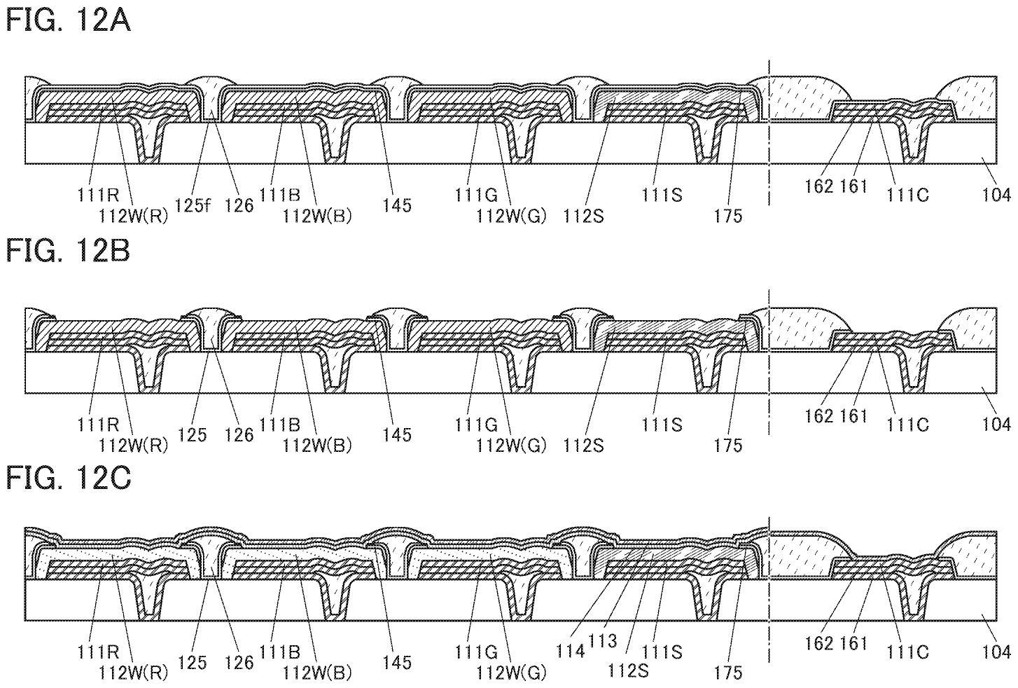

Then, an insulating film 125f is formed to cover the mask layer 145, the mask layer 175, and the connection electrode 111C (FIG. 12A).

The insulating film 125f functions as a barrier layer that prevents diffusion of impurities such as water into the organic compound layers 112W and the active layer 112S. The insulating film 125f is preferably formed by an ALD method with excellent step coverage because the side surfaces of the organic compound layers 112W and the active layer 112S can be suitably covered.

The insulating film 125f is preferably formed using the same film as the mask layer 145 and the mask layer 175 because the insulating film 125f can be easily removed in an etching treatment in a later step. For example, one or two or more of inorganic materials selected from aluminum oxide, hafnium oxide, silicon oxide, and the like which are formed by an ALD method are preferably used for the insulating film 125f, the mask layer 145, and the mask layer 175.

Note that materials that can be used for the insulating film 125f are not limited thereto. For example, the materials that can be used for the mask film 144 can be used as appropriate.

### [Formation of Insulating Layer 126]

Next, the insulating layer 126 is formed in the regions overlapping with the slit 118a, the slit 118b, and the slit 119 (FIG. 12A). The insulating layer 126 can be formed by a method similar to that of the resin layer 163. For example, the insulating layer 126 can be formed by performing light exposure and development after a photosensitive resin is formed. The insulating layer 126 may be formed by etching part of the resin by ashing or the like after a resin is formed on the entire surface.

Here, a structure where the insulating layer 126 has a larger width than the widths of the slit 118a, the slit 118b, and the slit 119 is illustrated. Note that the insulating layer 126 is provided so that part of the top surface of the connection electrode 111C is exposed.

### [Etching of Insulating Film 125f, Mask Layer 145, and Mask Layer 175]

Then, portions of the insulating film 125f, the mask layer 145, and the mask layer 175, which are not covered with the insulating layer 126, are removed by etching, so that part of the top surfaces of the organic compound layers 112W and part of the top surface of the active layer 112S are exposed. In this manner, the insulating layer 125, the mask layer 145, and the mask layer 175 remain in a region overlapping with the insulating layer 126 (FIG. 12B). It is preferable that the center portion of the insulating layer 126 be positioned above the end portion of the insulating layer 126 and the center portion thereof include a region which rises up more than the end portion thereof. The top surface of the insulating layer 126 is preferably positioned above the top surfaces of the organic compound layers 112W. Furthermore, the end portion of the insulating layer 126 preferably has a tapered shape.

Etching of the insulating film 125f, the mask layer 145, and the mask layer 175 is preferably performed in the same step. In particular, the etching of the mask layer 145 and the etching of the mask layer 175 are preferably performed by wet etching, which causes less etching damage to the organic compound layers 112W and the active layer 112S. For example, wet etching using a tetramethyl ammonium hydroxide (TMAH) aqueous solution, diluted hydrofluoric acid, oxalic acid, phosphoric acid, acetic acid, nitric acid, or a mixed solution thereof is preferably performed.

Alternatively, at least one of the insulating film 125f, the mask layer 145, and the mask layer 175 is preferably removed by being dissolved in a solvent such as water or alcohol. Here, as the alcohol in which the insulating film 125f, the mask layer 145, and the mask layer 175 can be dissolved, any of various alcohols such as ethyl alcohol, methyl alcohol, isopropyl alcohol (IPA), and glycerin can be used.

After part of the insulating film 125f, part of the mask layer 145, and part of the mask layer 175 are removed, drying treatment is preferably performed to remove water contained in the organic compound layers 112W, the active layer 112S, and the like and water adsorbed onto the surfaces thereof. For example, heat treatment is preferably performed in an inert gas atmosphere or a reduced-pressure atmosphere. The heat treatment can be performed with a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Employing a reduced-pressure atmosphere is preferable, in which case drying at a lower temperature is possible.

Part of the insulating film 125f is removed, so that part of the top surface of the connection electrode 111C is exposed.

### [Formation of Common Layer 114]

Next, the common layer 114 is formed to cover the organic compound layers 112W, the active layer 112S, the insulating layer 125, the mask layer 145, the mask layer 175, the insulating layer 126, and the like (FIG. 12C).

The above-described materials that can be used for the electron-injection layer can be used for the common layer 114, and for example, the alkali metal, the alkaline earth metal, or the compound thereof can be given. As the above-described materials, a composite material of an organic compound and the alkali metal or the alkaline earth metal can be given. Specifically, lithium fluoride (LiF) or a composite material containing NBPhen and Ag is preferably used, for example.

The common layer 114 can be formed by a method similar to that of the organic compound film 112f, for example. For obtaining the above-described composite material, a co-evaporation is preferably used for the formation. In the case where the common layer 114 is formed by an evaporation method, the common layer 114 is preferably formed using an area mask so as not to be formed over the connection electrode 111C.

### [Formation of Common Electrode 113]

Then, the common electrode 113 is formed to cover the common layer 114 (FIG. 12C).

The common electrode 113 can be formed by a deposition method such as an evaporation method or a sputtering method. Alternatively, a film formed by an evaporation method and a film formed by a sputtering method may be stacked.

The common electrode 113 is preferably formed to cover a region where the common layer 114 is formed.

The common electrode 113 can be formed using the same area mask as the area mask used for forming the common layer 114. In this case, a structure in which the end portion of the common layer 114 overlaps with the end portion of the common electrode 113 can be obtained.

In the connection portion 140, the common layer 114 may be positioned between the connection electrode 111C and the common electrode 113. In this case, for the common layer 114, a material with as low electric resistance as possible is preferably used. Alternatively, it is preferable to form the common layer 114 as thin as possible, in which case the electric resistance of the common layer 114 in the thickness direction can be reduced. For example, the common layer 114 can be formed using a material having an electron-injection property or a hole-injection property having a thickness greater than or equal to 1 nm and less than or equal to 5 nm, preferably greater than or equal to 1 nm and less than or equal to 3 nm, whereby the electric resistance between the connection electrode 111C and the common electrode 113 can be made negligible.

### [Formation of Auxiliary Wiring]

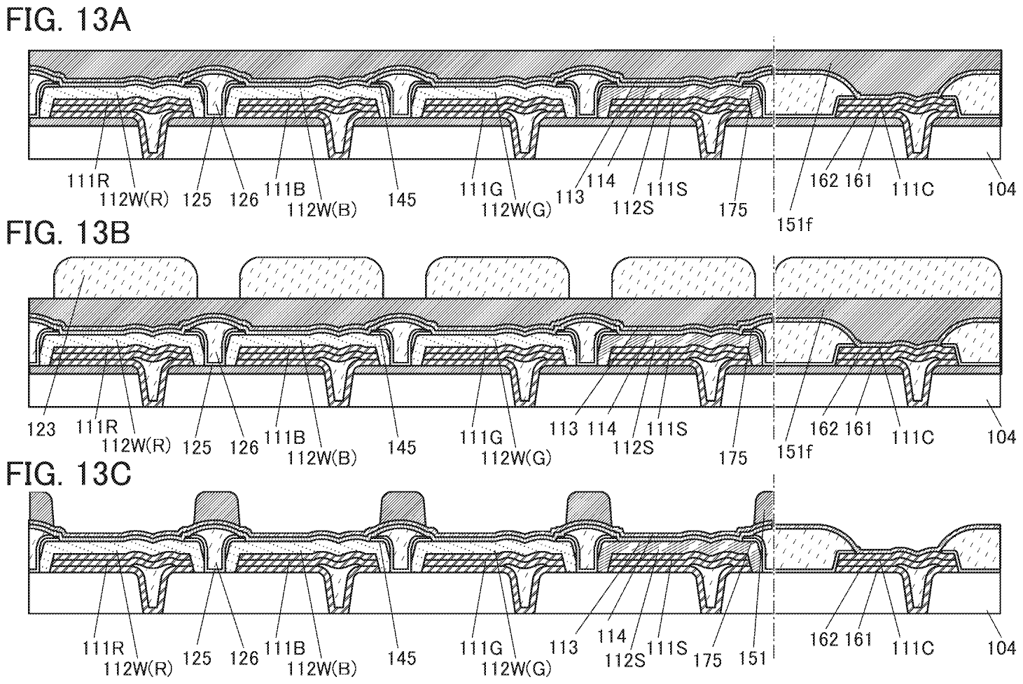

Next, an auxiliary wiring layer 151f is formed over the common electrode 113 (FIG. 13A). In the case where an organic material is used for the auxiliary wiring layer 151f, a wet process is preferably used for the formation of the auxiliary wiring layer containing the organic material. The auxiliary wiring 151 as illustrated in FIG. 1A to FIG. 1E can be formed of the auxiliary wiring layer containing the organic material.

In the case where an inorganic material is used for the auxiliary wiring layer 151f, a sputtering method, a CVD method, a vacuum evaporation method, or the like is preferably used. When a metal mask is used in the case of using a sputtering method, the auxiliary wiring 151 as illustrated in FIG. 1D or FIG. 1E can be selectively formed.

A resist mask 123 is formed in positions which are over the auxiliary wiring layer 151f and overlap with the lower electrode 111R, the lower electrode 111G, the lower electrode 111B, and the connection portion 140, and light exposure and development are performed (FIG. 13B).

For the resist mask 123, a resist material containing a photosensitive resin, such as a positive type resist material or a negative type resist material can be used.

After that, the auxiliary wiring layer 151f which is not covered with the resist mask 123 is removed by etching, so that the auxiliary wiring 151 is formed (FIG. 13C). The etching of the auxiliary wiring layer 151f can be performed by wet etching or dry etching.

The auxiliary wiring 151 is formed in a position overlapping with the insulating layer 126 in the pixel portion 103. The auxiliary wiring 151 formed in such a manner is preferable because the aperture ratio of the display apparatus is not reduced.

The auxiliary wiring 151 is formed to include a region in contact with the common electrode 113. The auxiliary wiring 151 can inhibit voltage drop and can have an effect of inhibiting stray light.

### [Formation of Counter Substrate]

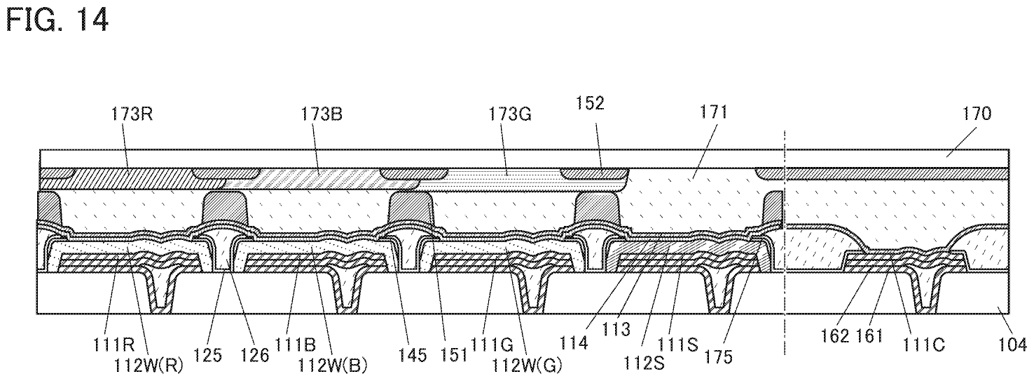

Then, using the adhesive layer 171, the substrate 170 is attached (FIG. 14). In the case where the display apparatus has a hollow sealing structure, the substrate 170 is preferably attached, using a sealant or the like. A space generated when the substrate is attached using the sealant is preferably filled with an inert gas (a gas containing nitrogen or argon).

For the adhesive layer 171, an organic material such as a reactive curable adhesive, a photocurable adhesive, a thermosetting adhesive, or/and an anaerobic adhesive can be used, for example.

Specifically, an adhesive containing an epoxy resin, an acrylic resin, a silicone resin, a phenol resin, a polyimide resin, an imide resin, a PVC (polyvinyl chloride) resin, a PVB (polyvinyl butyral) resin, an EVA (ethylene vinyl acetate) resin, or the like can be used for the adhesive layer 171 or the like.

The substrate 170 is provided with the light-blocking layer 152, the coloring layer 173R, the coloring layer 173G, and the coloring layer 173B. The light-blocking layer 152 is provided in a region overlapping with the insulating layer 126. The substrate 170 is preferably attached, such that the coloring layer 173R, the coloring layer 173G, and the coloring layer 173B overlap with the lower electrode 111R, the lower electrode 111G, and the lower electrode 111B, respectively.

Each of the coloring layer 173R, the coloring layer 173G, and the coloring layer 173B can be formed in a desired position through an ink-jet method, an etching treatment using a photolithography method, or the like. Specifically, a different coloring layer 173 (the coloring layer 173R, the coloring layer 173G, or the coloring layer 173B) can be formed for each pixel.

White light emitted toward the common electrode 113 side is colored when light in a predetermined wavelength range is absorbed by the coloring layer 173R, the coloring layer 173G, or the coloring layer 173B, then, the colored light is emitted to the outside through the substrate 170, whereby full-color display can be achieved.

The thickness of the auxiliary wiring 151 is preferably thick enough to be in contact with the coloring layer 173R, the coloring layer 173G, and the coloring layer 173B. With the auxiliary wiring 151, an effect of inhibiting stray light can be produced.

In this manner, the display apparatus described in Variation Example 1 can be manufactured.

Although the organic compound layers 112W and the active layer 112S are formed in this order as described above, the formation order is not limited thereto. The active layer 112S and the organic compound layers 112W may be formed in this order.

Note that the display apparatuses described in Specific Examples 1 to 7 and Variation Example 2 can also be manufactured in accordance with the above description.

The above is the description of the example of the method for manufacturing the display apparatus.

At least part of this embodiment can be implemented in combination with the other embodiments described in this specification as appropriate.

### Embodiment 2

In this embodiment, structure examples of a display apparatus of one embodiment of the present invention are described. In this embodiment, structure examples of the display apparatus are described using the pixel portion 103 in which a light-receiving portion is not included and subpixels are arranged in a stripe pattern.

### <Top Surface Structure Example of Auxiliary Wiring>

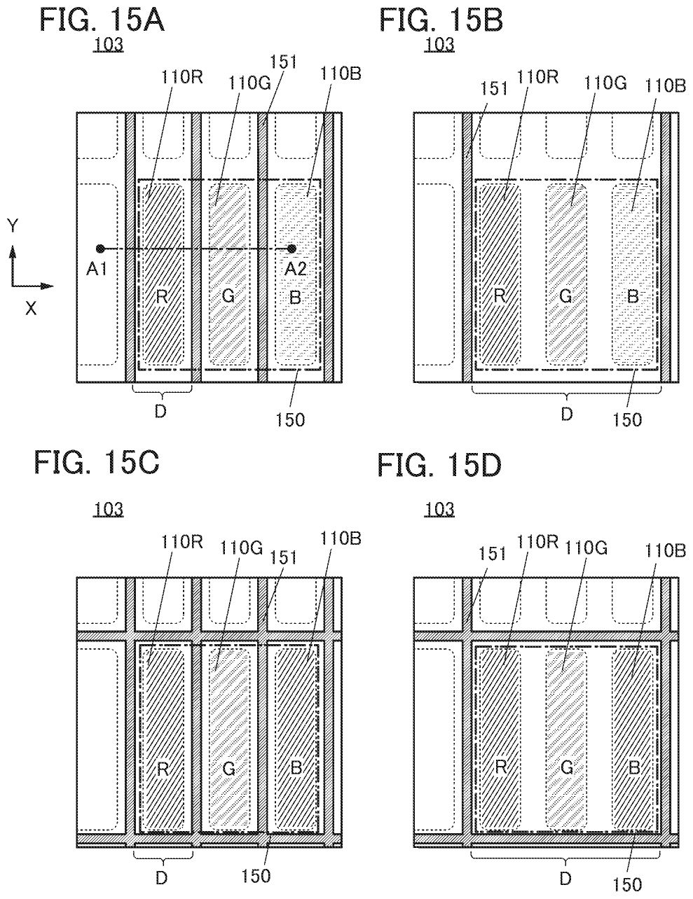

FIG. 15A to FIG. 15D each illustrates a top view of the pixel portion 103 of the display apparatus. In FIG. 15A to FIG. 15D, the X direction and the Y direction intersecting in the X direction are indicated and a structure arrangement and the like included in the pixel portion 103 are described using the directions.

The pixel portion 103 is positioned in a display region and includes the plurality of pixels 150. The pixel portion 103 sometimes includes a protection circuit besides the pixel 150. The pixel 150 includes at least the subpixel 110R, the subpixel 110G, and the subpixel 110B. The subpixel 110R, the subpixel 110G, and the subpixel 110B correspond to the light-emitting regions of the light-emitting devices, and for example, the subpixel 110R, the subpixel 110G, and the subpixel 110B correspond to the light-emitting region of the light-emitting device of red (sometimes referred to as R), the light-emitting region of the light-emitting device of green (sometimes referred to as G), and the light-emitting region of the light-emitting device of blue (sometimes referred to as B), respectively.

Note that the display apparatus of one embodiment of the present invention is not limited to the above emission colors, and the light-emitting region of white may be included in addition to the light-emitting regions of red, green, and blue, for example.

The subpixel 110R, the subpixel 110G, and the subpixel 110B are preferably arranged in a matrix (referred to as a matrix arrangement). The matrix arrangement is a regular arrangement, and the plurality of subpixels 110R, the plurality of subpixels 110G, and the plurality of subpixels 110B are arranged in the entire pixel portion 103 in accordance with the regular arrangement as shown in the pixel 150.

The structure at least including the subpixel 110R, the subpixel 110G, and the subpixel 110B enables full-color display. The pixel 150 can be given as an example of the minimum unit that enables full-color display.

When a common part of the subpixel 110R, the subpixel 110G, and the subpixel 110B is described, the term “subpixel 110” is used in some cases. The subpixel 110 includes a switching element for controlling the light-emitting device in addition to the light-emitting device exhibiting one emission color. The display apparatus can perform full-color display by light emitted from the light-emitting device which is controlled by the switching element. To perform full-color display, the subpixel 110R, the subpixel 110G, and the subpixel 110B may each include a coloring layer, and a color filter or a color conversion layer can be given as the coloring layer, for example.

The arrangement of the auxiliary wiring 151 and the like is described with reference to FIG. 15A. The pixel 150 illustrated in FIG. 15A includes the subpixel 110R, the subpixel 110G, and the subpixel 110B; the subpixels have a stripe arrangement, in which the subpixels of the same color are arranged in the Y direction.

The auxiliary wiring 151 illustrated in FIG. 15A is provided over a region not overlapping with the subpixel and has a band shape along the Y direction in a plan view. The auxiliary wiring 151 having a band shape includes a region positioned between the subpixel 110R and the subpixel 110G. Furthermore, the auxiliary wiring 151 having a band shape includes a region positioned between the subpixel 110G and the subpixel 110B. The distance (D) between the auxiliary wirings 151 each of which has a band shape is substantially the same as the width between the subpixels.

Although not illustrated in FIG. 15A, the common electrode is electrically connected to the auxiliary wiring 151 illustrated in FIG. 15A, whereby voltage drop due to the common electrode can be inhibited.

Next, an auxiliary wiring having an arrangement different from that in FIG. 15A is described with reference to FIG. 15B. FIG. 15B illustrates the pixel 150 in the same arrangement as that in FIG. 15A. The auxiliary wiring 151 illustrated in FIG. 15B has a band shape in a plan view, and includes a region positioned between the subpixel 110R and the subpixel 110B which belongs to the next subpixel. The distance (D) between the auxiliary wirings 151 each of which has a band shape is substantially the same as the width of three subpixels, that is, the width of the pixel 150.

Although not illustrated in FIG. 15B, the common electrode is electrically connected to the auxiliary wiring 151 illustrated in FIG. 15B, whereby voltage drop due to the common electrode can be inhibited.

Then, an auxiliary wiring having an arrangement different from that in FIG. 15A is described with reference to FIG. 15C. FIG. 15C illustrates the pixel 150 in the same arrangement as that in FIG. 15A. The auxiliary wiring 151 illustrated in FIG. 15C has a lattice pattern in a plan view. The auxiliary wiring 151 illustrated in FIG. 15C includes a region positioned between the subpixels 110R as a region extending along the X direction. The auxiliary wiring 151 illustrated in FIG. 15C includes a region positioned between the subpixel 110R and the subpixel 110G and a region positioned between the subpixel 110G and the subpixel 110B as regions extending along the Y direction. The distance (D) between the auxiliary wirings 151 each of which has a band shape is substantially the same as the width between the subpixels.

Although not illustrated in FIG. 15C, the common electrode is electrically connected to the auxiliary wiring 151 illustrated in FIG. 15C, whereby voltage drop due to the common electrode can be inhibited.

Next, an auxiliary wiring having an arrangement different from that in FIG. 15A is described with reference to FIG. 15D. FIG. 15D illustrates the pixel 150 in the same arrangement as that in FIG. 15A. The auxiliary wiring 151 illustrated in FIG. 15D has a lattice pattern in a plan view. The auxiliary wiring 151 illustrated in FIG. 15D includes a region positioned between the subpixels 110R as a region extending along the X direction. The auxiliary wiring 151 illustrated in FIG. 15C includes a region positioned between the subpixel 110R and the subpixel 110G and a region positioned between the subpixel 110G and the subpixel 110B as regions extending along the Y direction. The distance (D) between the auxiliary wirings 151 each of which has a band shape is substantially the same as the width of three subpixels, that is, the width of the pixel 150.

Although not illustrated in FIG. 15D, the common electrode is electrically connected to the auxiliary wiring 151 illustrated in FIG. 15D, whereby voltage drop due to the common electrode can be inhibited.

The arrangements of the auxiliary wiring 151 illustrated in FIG. 15A to FIG. 15D have a common arrangement in terms of not decreasing the aperture ratio or the like. The auxiliary wirings 151 illustrated in FIG. 15A to FIG. 15D can inhibit voltage drop.

In the case where a conductive material having a light-transmitting property is used for the auxiliary wiring 151, the aperture ratio or the like does not decrease even when the auxiliary wiring 151 overlaps with the subpixel; thus, the arrangement of the auxiliary wiring 151 is not limited to those illustrated in FIG. 15A to FIG. 15D. The conductive material having a light-transmitting property and the auxiliary wirings 151 illustrated in FIG. 15A to FIG. 15D are preferably used in combination as the auxiliary wiring having a stacked-layer structure.

### <Cross-Sectional Structure Example of Auxiliary Wiring>

For a cross-sectional structure of the auxiliary wiring 151 and the like, the cross-sectional structure examples illustrated in FIG. 2A to FIG. 2C can be used. Specifically, the auxiliary wiring 151 has a structure where the light-receiving device is omitted from any of FIG. 2A to FIG. 2C and the light-emitting device 11B is provided.

### SPECIFIC EXAMPLES

The display apparatus of one embodiment of the present invention is described using an SBS structure where the light-emitting devices emitting light of different colors are separately formed.

### Specific Example 8

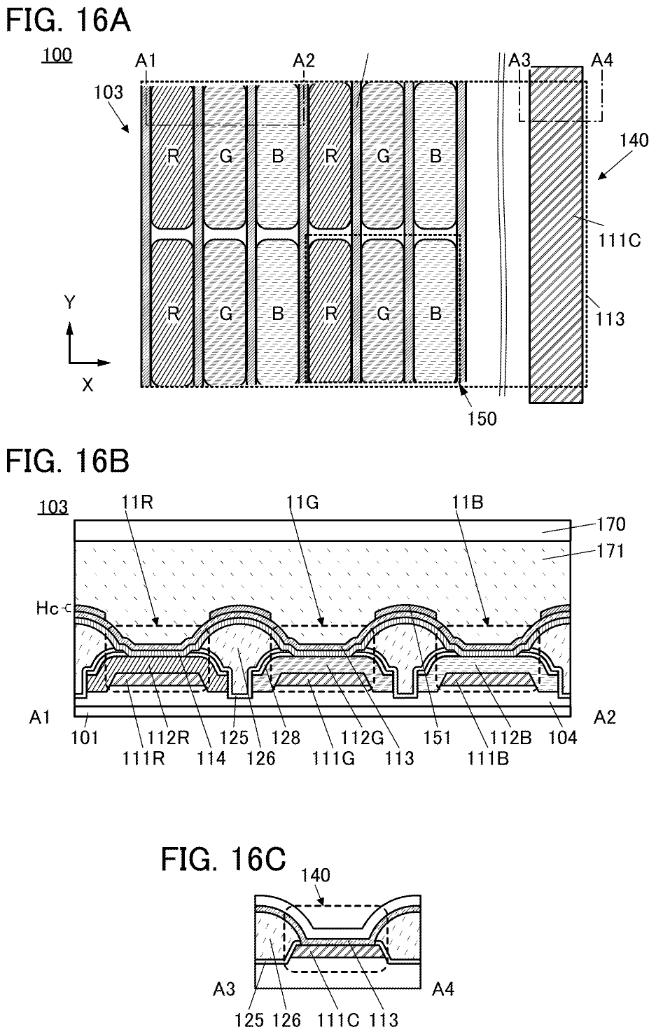

Specific Example 8 of the display apparatus of one embodiment of the present invention is described with reference to FIG. 16A to FIG. 16C. The display apparatus 100 includes the pixel portion 103 and the connection portion 140. The pixel portion 103 includes the plurality of pixels 150. The pixel 150 includes the plurality of subpixels 110, and for example, the subpixel 110R includes the light-emitting device 11R exhibiting red, the subpixel 110G includes the light-emitting device 11G exhibiting green, and the subpixel 110B includes the light-emitting device 11B exhibiting blue.

In FIG. 16A, a region corresponding to the light-emitting device 11R, the light-emitting device 11G, and the light-emitting device 11B are denoted by R, G, and B, respectively. The arrangement in FIG. 16A is similar to the arrangements illustrated in FIG. 15A and the like and is a regular arrangement.

As each of the light-emitting device 11R, the light-emitting device 11G, and the light-emitting device 11B, an element such as an OLED or a QLED is preferably used. Examples of a light-emitting substance contained in the light-emitting device include a substance that emits fluorescent light (a fluorescent material), a substance that emits phosphorescent light (a phosphorescent material), an inorganic compound (e.g., a quantum dot material), and a substance that exhibits thermally activated delayed fluorescence (a thermally activated delayed fluorescent material).

FIG. 16B and FIG. 16C are each a cross-sectional view taken along the dashed-dotted line A1-A2 and the dashed-dotted line A3-A4 in FIG. 16A. FIG. 16B illustrates a cross-sectional view of the light-emitting device 11R, the light-emitting device 11G, and the light-emitting device 11B, and FIG. 16C illustrates a cross-sectional view of the connection electrode 111C. The cross-sectional structure illustrated in FIG. 16C has a structure similar to the cross-sectional structure illustrated in FIG. 3C. The auxiliary wiring 151 can be provided in the connection portion 140 as well as the pixel portion 103.

FIG. 16A to FIG. 16C are different from FIG. 3A to FIG. 3C in the thickness of the auxiliary wiring 151 (the distance denoted by Hc in FIG. 16B). The thickness of the auxiliary wiring 151 is preferably greater than or equal to 50 nm and less than or equal to 500 nm, further preferably greater than or equal to 100 nm and less than or equal to 200 nm. The auxiliary wiring 151 can inhibit voltage drop. Since the light-receiving device is not included in the pixel portion, stray light does not need to be considered in this embodiment; thus, the thickness of the auxiliary wiring may be reduced.

Specific Example 8 is the same as Specific Example 1 shown in FIG. 3A to FIG. 3C and the like other than the thickness of the auxiliary wiring 151.

### Specific Example 9

Specific Example 9 of the display apparatus of one embodiment of the present invention is described. In Specific Example 9, the thickness of the auxiliary wiring 151 is the same as that in Specific Example 8, and the upper portion of the insulating layer 126 has a flat shape and the end portion thereof has a tapered shape as in Specific Example 2. The auxiliary wiring 151 can inhibit voltage drop.

### Specific Example 10

Specific Example 10 of the display apparatus of one embodiment of the present invention is described. In Specific Example 10, the thickness of the auxiliary wiring 151 is the same as that in Specific Example 8, and the auxiliary wiring 151 having a stacked-layer structure is included as in Specific Example 3. The auxiliary wiring 151 can inhibit voltage drop.

### Specific Example 11

Specific Example 11 of the display apparatus of one embodiment of the present invention is described. In Specific Example 11, the thickness of the auxiliary wiring 151 is the same as that in Specific Example 8, and the auxiliary wiring 151 having a stacked-layer structure is included as in Specific Example 4. The auxiliary wiring 151 can inhibit voltage drop.

### Specific Example 12

Specific Example 12 of the display apparatus of one embodiment of the present invention is described. In Specific Example 12, the thickness of the auxiliary wiring 151 is the same as that in Specific Example 8, and the light-blocking layer 152 is provided on the substrate 170 as in Specific Example 5. The auxiliary wiring 151 can inhibit voltage drop.

### Specific Example 13

Specific Example 13 of the display apparatus of one embodiment of the present invention is described. In Specific Example 13, the thickness of the auxiliary wiring 151 is the same as that in Specific Example 8, and the coloring layer 173R and the coloring layer 173G are provided on the substrate 170 as in Specific Example 6. In Specific Example 13, the coloring layer 173B which is not illustrated in the drawing in Specific Example 6 is also provided. The auxiliary wiring 151 can inhibit voltage drop.

### Specific Example 14

Specific Example 14 of the display apparatus of one embodiment of the present invention is described. In Specific Example 14, the thickness of the auxiliary wiring 151 is the same as that in Specific Example 8, the coloring layer 173R and the coloring layer 173G are provided on the substrate 170 as in Specific Example 7, and the light-blocking layer 152 is provided in a region where the coloring layer 173R and the coloring layer 173G overlap with each other. In Specific Example 10, the coloring layer 173B which is not illustrated in the drawing in Specific Example 7 is also provided. The auxiliary wiring 151 can inhibit voltage drop.

### Variation Example 3

Variation Example 3 of the display apparatus of one embodiment of the present invention is described. Variation Example 3 is different from the structure of Specific Example 8 mainly in including the light-emitting device emitting white light. The auxiliary wiring 151 can inhibit voltage drop.

### Variation Example 4

Variation Example 4 of the display apparatus of one embodiment of the present invention is described. Variation Example 4 is an example where the light-blocking layer 152 is applied to the structure of Variation Example 3. The auxiliary wiring 151 can inhibit voltage drop.

The above is the description of Variation Examples.

In the display apparatuses described above as examples, a crosstalk due to leakage current is inhibited and both a high aperture ratio and a high resolution can be achieved. Thus, the display apparatus can be suitably used for an extremely small display for a head-mounted display (a microdisplay). Note that without limited to this, the display apparatus of one embodiment of the present invention can be used for an extremely small display that is less than one inch in size to an ultra-large display that is more than 100 inches in size.

### [Light-Emitting Device]

Next, a material that can be used for the light-emitting device is similar to that in the above embodiment.

### [Layout]

Hereinafter, a pixel layout different from that in FIG. 15A is mainly described.

Examples of the top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

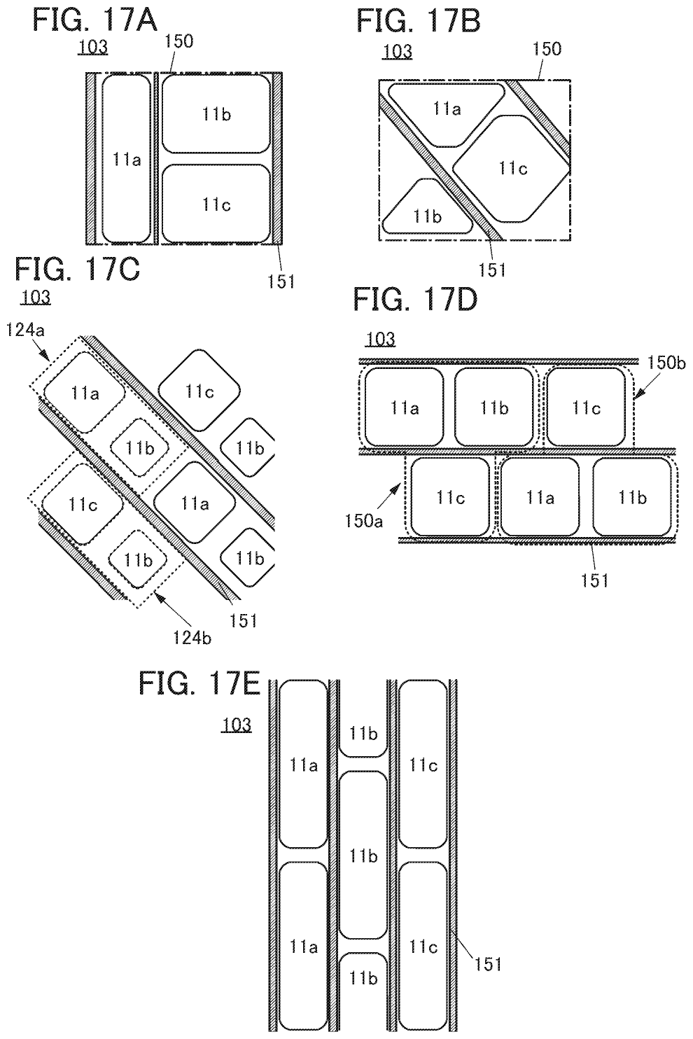

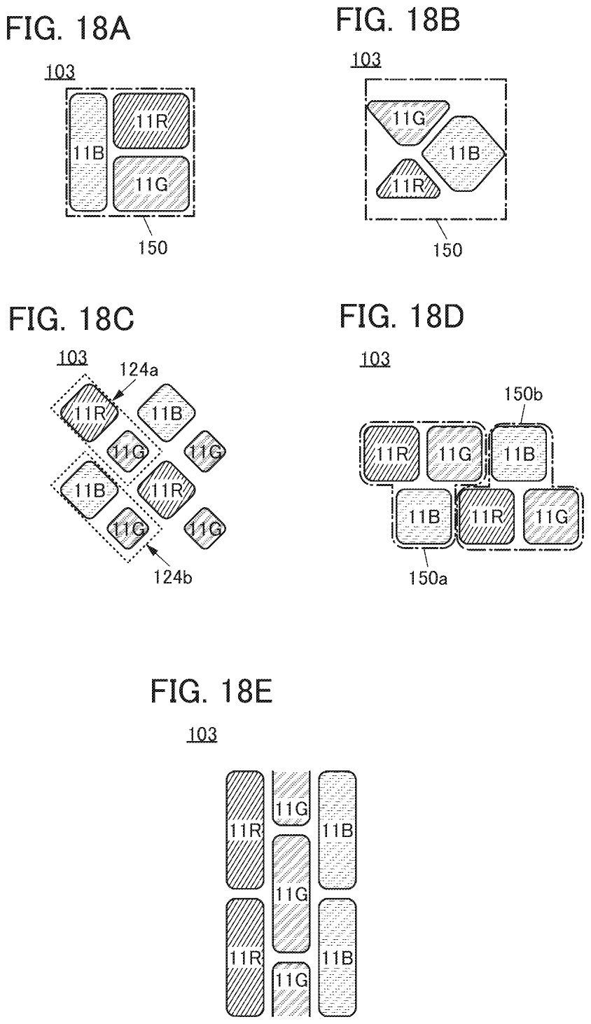

The pixel portion 103 illustrated in FIG. 17A includes the auxiliary wiring 151, and the pixel 150 includes three subpixels of a light-emitting device 11a, a light-emitting device 11b, and a light-emitting device 11c. The arrangement of the light-emitting device 11a, the light-emitting device 11b, and the light-emitting device 11c illustrated in FIG. 17A is sometimes referred to as an S-stripe arrangement. The auxiliary wiring 151 is positioned so as not to overlap with the light-emitting device 11a to the light-emitting device 11c, and includes a region positioned between the light-emitting device 11a and the light-emitting device 11b and a region positioned between the light-emitting device 11a and the light-emitting device 11c, for example. For example, as illustrated in FIG. 18A, the light-emitting device 11a may be the light-emitting device 11B exhibiting blue, the light-emitting device 11b may be the light-emitting device 11R exhibiting red, and the light-emitting device 11c may be the light-emitting device 11G exhibiting green.

The pixel portion 103 illustrated in FIG. 17B includes the auxiliary wiring 151, and the pixel 150 includes the light-emitting device 11a whose top surface has a rough trapezoidal shape with rounded corners, the light-emitting device 11b whose top surface has a rough triangle shape with rounded corners, and the light-emitting device 11c whose top surface has a rough tetragonal or rough hexagonal shape with rounded corners. The light-emitting device 11a has a larger light-emitting area than the light-emitting device 11b. In this manner, the shapes and sizes of the light-emitting devices can be determined independently. For example, the size of a light-emitting device with higher reliability can be smaller. The auxiliary wiring 151 is positioned so as not to overlap with the light-emitting device 11a to the light-emitting device 11c, and includes a region positioned between the light-emitting device 11b and the light-emitting device 11c, for example.

For example, as illustrated in FIG. 18B, the light-emitting device 11a may be the light-emitting device 11G exhibiting green, the light-emitting device 11b may be the light-emitting device 11R exhibiting red, and the light-emitting device 11c may be the light-emitting device 11B exhibiting blue.

The pixel portion 103 illustrated in FIG. 17C includes the auxiliary wiring 151, and the subpixels employ a PenTile arrangement. FIG. 17C illustrates an example in which a subpixel 124a including a pair of the light-emitting device 11a and the light-emitting device 11b and a subpixel 124b including a pair of the light-emitting device 11b and the light-emitting device 11c are alternately arranged. The auxiliary wiring 151 is positioned so as not to overlap with the light-emitting device 11a to the light-emitting device 11c, and includes a region positioned between the light-emitting device 11a and the light-emitting device 11b and a region positioned between the light-emitting device 11b and the light-emitting device 11c, for example.

For example, as illustrated in FIG. 18C, the light-emitting device 11a may be the light-emitting device 11R exhibiting red, the light-emitting device 11b may be the light-emitting device 11G exhibiting green, and the light-emitting device 11c may be the light-emitting device 11B exhibiting blue.

The pixel portion 103 illustrated in FIG. 17D includes the auxiliary wiring 151, and a delta arrangement is employed for a pixel 150a and a pixel 150b. The pixel 150a includes two light-emitting devices (the light-emitting device 11a and the light-emitting device 11b) in the upper row (first row) and one light-emitting device (the light-emitting device 11c) in the lower row (second row). The pixel 150b includes one light-emitting device (the light-emitting device 11c) in the upper row (first row) and two light-emitting devices (the light-emitting device 11a and the light-emitting device 11b) in the lower row (second row). The auxiliary wiring 151 is positioned so as not to overlap with the light-emitting device 11a to the light-emitting device 11c, and includes a region positioned between the light-emitting device 11a and the light-emitting device 11b and a region positioned between the light-emitting device 11b and the light-emitting device 11c, for example.

For example, as illustrated in FIG. 18D, the light-emitting device 11a may be the light-emitting device 11R exhibiting red, the light-emitting device 11b may be the light-emitting device 11G exhibiting green, and the light-emitting device 11c may be the light-emitting device 11B exhibiting blue.

The pixel portion 103 illustrated in FIG. 17E includes the auxiliary wiring 151, and the light-emitting devices of the respective colors are arranged in a zigzag manner. Specifically, the positions of the top sides of two light-emitting devices arranged in the column direction (e.g., the light-emitting device 11a and the light-emitting device 11b or the light-emitting device 11b and the light-emitting device 11c) are not aligned in a plan view. The auxiliary wiring 151 is positioned so as not to overlap with the light-emitting device 11a to the light-emitting device 11c, and includes a region positioned between the light-emitting device 11a and the light-emitting device 11b and a region positioned between the light-emitting device 11b and the light-emitting device 11c, for example.

For example, as illustrated in FIG. 18E, the light-emitting device 11a may be the light-emitting device 11R exhibiting red, the light-emitting device 11b may be the light-emitting device 11G exhibiting green, and the light-emitting device 11c may be the light-emitting device 11B exhibiting blue.

In a photolithography method, as a pattern to be processed becomes finer, the influence of light diffraction becomes more difficult to ignore; therefore, the fidelity in transferring a resist mask pattern by light exposure is degraded, and it becomes difficult to process a resist mask into a desired shape. Thus, a pattern with rounded corners is likely to be formed even with a rectangular resist mask pattern. Consequently, the top surface of a light-emitting device may have a polygonal shape with rounded corners, an elliptical shape, a circular shape, or the like.

Furthermore, in the method for manufacturing the display apparatus of one embodiment of the present invention, the organic compound layer is processed with a resist mask. A resist mask formed over the organic compound layer needs to be cured at a temperature lower than the upper temperature limit of the organic compound layer. Therefore, curing for forming a resist mask is insufficient in some cases depending on the upper temperature limit of the material of the organic compound layer and the curing temperature of the resist material. An insufficiently cured resist mask may have a shape different from a desired shape by processing. As a result, the top surface of the organic compound layer may have a polygonal shape with rounded corners, an elliptical shape, a circular shape, or the like. For example, when a resist mask with a square top surface is intended to be formed, a resist mask with a circular top surface may be formed, and the top surface of the organic compound layer may be circular.

To obtain a desired top surface shape of the organic compound layer, a technique of correcting a mask pattern in advance so that a design pattern agrees with a transferred pattern (an OPC (Optical Proximity Correction) technique) may be used. Specifically, with the OPC technique, a pattern for correction is added to a corner portion or the like of a figure on a mask pattern.

The above is the description of the pixel layouts.

### Manufacturing Method Example 2

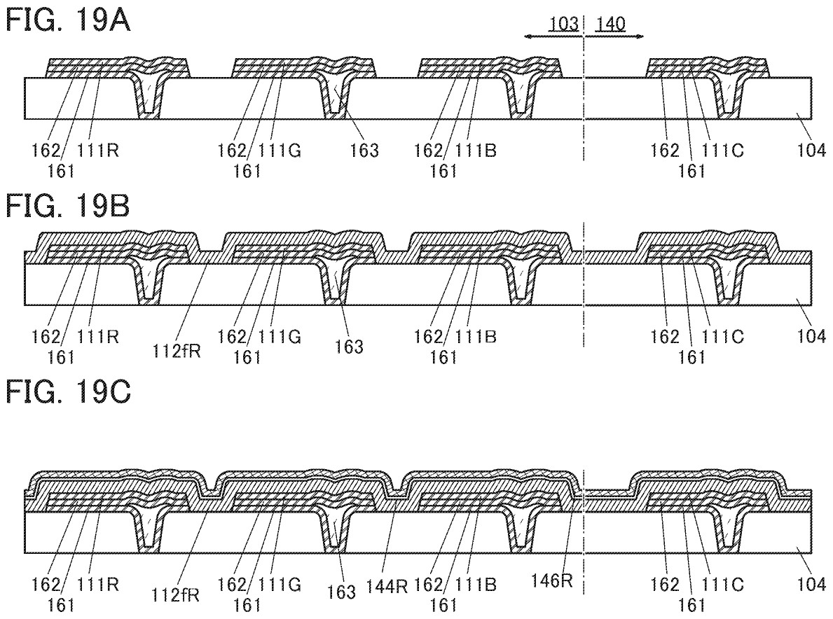

An example of a method for manufacturing the above-described display apparatus in Specific Example 8 is described with reference to FIG. 19A to FIG. 22B. In the drawing, the pixel portion 103 is illustrated on the left side and the connection portion 140 is illustrated on the right side.

### [Preparation for Substrate]

### [Formation of Conductive Layer 161, Resin Layer 163, Conductive Layer 162, and Lower Electrode 111]

As in Embodiment 1, a substrate is prepared, the insulating layer 104 is provided over the substrate, and then the conductive layer 161, the resin layer 163, the conductive layer 162, the lower electrode 111R, the lower electrode 111G, the lower electrode 111B, and the connection electrode 111C are formed (FIG. 19A).

### [Formation of Organic Compound Film]

An organic compound film 112fR which can emit red light is formed to cover the lower electrodes 111 and the connection electrode 111C (FIG. 19B). The organic compound film 112fR may have either a single structure or a tandem structure. The organic compound film 112fR is a stack of functional layers, and the functional layers can be formed by a vacuum evaporation method. Note that without limitation to this, the organic compound film 112fR can also be formed by a sputtering method, an inkjet method, or the like.

Note that although the organic compound film 112fR is formed to cover the connection electrode 111C in FIG. 19B, the present invention is not limited thereto. For example, by using an area mask for specifying a film formation area, the film formation area of the organic compound film 112fR may be inward from the connection portion 140 so that the organic compound film 112fR does not overlap with the connection electrode 111C. Accordingly, the connection electrode 111C can be prevented from being in contact with the organic compound film 112fR, which is preferable because a remover for removing the organic compound film 112fR is not in contact with the surface of the connection electrode 111C.

The organic compound film 112fR may be separately formed using a fine metal mask. In that case, the organic compound film 112fR is preferably formed to cover only the lower electrode 111R. Accordingly, the lower electrode 111G, the lower electrode 111B, and the connection electrode 111C can be prevented from being in contact with the organic compound film 112fR, which is preferable because the remover for removing the organic compound film 112fR is not in contact with the surfaces of the lower electrode 111G, the lower electrode 111B, and the connection electrode 111C.

It is preferable that the organic compound film 112fR include the functional layers and be a stack including at least a hole-injection layer, a hole-transport layer, a light-emitting layer, and an electron-transport layer sequentially from the lower electrode 111, for example.

Note that an electron-injection layer positioned over an electron-transport layer is an example of the functional layer. In this embodiment, the electron-injection layer is a common layer and thus formed later. Any of functional layers may be employed as long as the common layer is positioned between the light-emitting layer and the common electrode. Needless to say, all the functional layers may be divided for each subpixel without providing the common layer.

The electron-transport layer positioned on the uppermost layer of the organic compound film 112fR is exposed to a processing process using a photolithography method for obtaining the processed organic compound layer 112. Thus, a material having high heat resistance is preferably used for the electron-transport layer. As the material having high heat resistance, a material having the glass transition point higher than or equal to 110° C. and lower than or equal to 165° C., preferably higher than or equal to 120° C. and lower than or equal to 135° C. is used, for example.

Moreover, the electron-transport layer exposed to processing may have a stacked-layer structure. Examples of the stacked-layer structure include a structure where the second electron-transport layer is stacked over the first electron-transport layer. In the processing, a period when the first electron-transport layer is covered with the second electron-transport layer is included; thus, the heat resistance of the first electron-transport layer may be lower than that of the second electron-transport layer. For example, a material having the glass transition point higher than or equal to 110° C. and lower than or equal to 165° C., preferably higher than or equal to 120° C. and lower than or equal to 135° C. can be used for the second electron-transport layer, and a material having the glass transition point lower than the glass transition point of the second electron-transport layer, for example, higher than or equal to 100° C. and lower than or equal to 155° C., preferably higher than or equal to 110° C. and lower than or equal to 125° C. can be used for the first electron-transport layer.

Although the uppermost layer of the organic compound film 112fR is also considered to be the light-emitting layer, damage to the light-emitting layer by the processing might significantly degrade the reliability. In view of the above, in manufacturing the display apparatus of one embodiment of the present invention, the processing is preferably performed after the functional layer (e.g., an electron-transport layer) is formed above the light-emitting layer. A mask layer or the like can be further formed over the organic compound film so that the light-emitting layer can be inhibited from being damaged by the processing. Using such a method can provide a highly reliable display panel.

### [Formation of Mask Film 144R and Mask Film 146R]

Next, a mask film 144R is formed to cover the organic compound film 112fR and a mask film 146R is formed to cover the mask film 144R (FIG. 19C). The mask film 144R at least has a function of protecting the organic compound film 112fR at the time of the etching treatment of the organic compound film 112fR.

The mask film 144 and the mask film 146 described in Embodiment 1 can be used as the mask film 144R and the mask film 146R, respectively.

### [Formation of Resist Mask 143R]

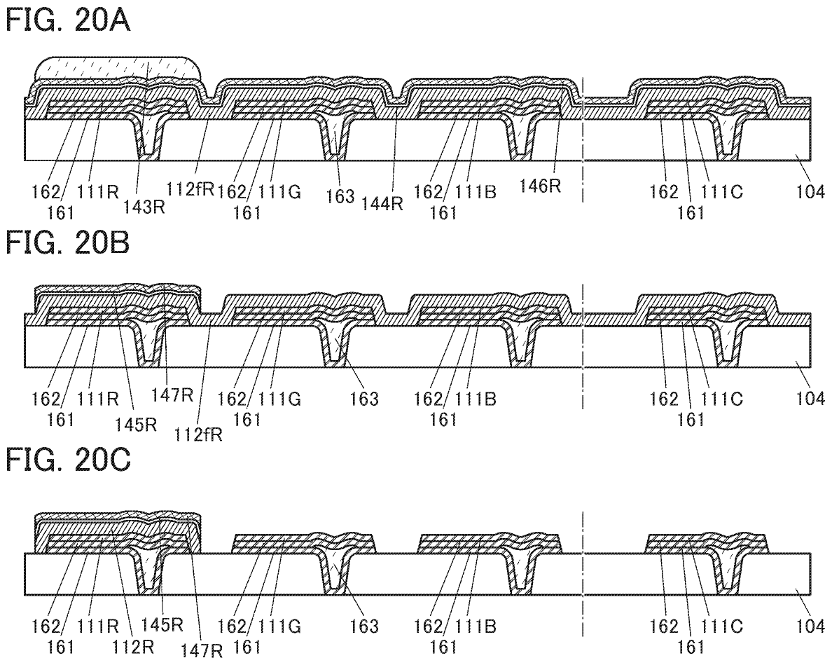

Then, a resist mask 143R is formed in a region that is over the mask film 146R and overlaps with the lower electrode 111R (FIG. 20A). As the resist mask 143R, the resist mask 143 described in Embodiment 1 can be used.

### [Etching of Mask Film 146R]

Next, part of the mask film 146R that is not covered with the resist mask 143R is removed by etching, so that a mask layer 147R is formed (FIG. 20B). For the etching of the mask film 146R, the etching condition and the like of the mask film 146 described in Embodiment 1 can be used.

### [Removal of Resist Mask 143R]

Then, the resist mask 143R is removed (FIG. 20B). For the removal of the resist mask 143R, the description of the removal of the resist mask 143 described in Embodiment 1 can be used.

### [Etching of Mask Film 144R]

Next, part of the mask film 144R is etched with use of the mask layer 147R as a hard mask, so that a mask layer 145R is formed (FIG. 20B).

For the etching condition of the mask film 144R, the etching condition and the like of the mask film 144 described in Embodiment 1 can be used.

[Etching of Organic Compound Film 112fR]

Then, part of the organic compound film 112fR that is not covered with the mask layer 145R is removed by etching, so that the independent organic compound layer 112R is formed (FIG. 20C). On the outermost surface of the organic compound layer 112R, at least a functional layer having high heat resistance, for example, an electron-transport layer, is preferably positioned.

For the etching of the organic compound film 112fR, the etching condition and the like of the organic compound film 112f described in Embodiment 1 can be used. At that time, the organic compound film 112fR over the lower electrode 111G, the lower electrode 111B, and the connection electrode 111C is removed, so that the lower electrode 111G, the lower electrode 111B, and the connection electrode 111C are exposed.

In this manner, the organic compound layer 112R can be formed from the organic compound film 112fR.

[Film Formation and Etching of Organic Compound Film 112fG]

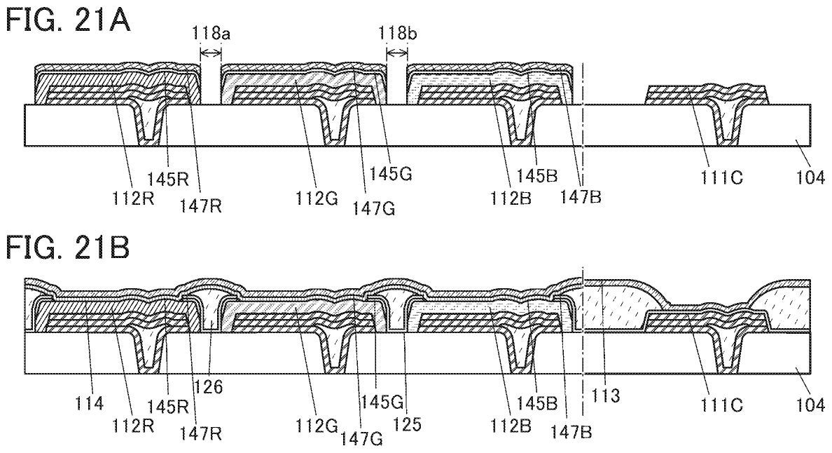

As in the case where the organic compound layer 112R is formed from the organic compound film 112fR, the organic compound layer 112G is formed in the following manner: an organic compound film 112fG is formed, a mask film 144G and a mask film 146G which are not illustrated are also formed, a mask layer 147G is formed by processing the mask film 146G, a mask layer 145G is formed by processing the mask film 144G using the mask layer 147G, and the organic compound film 112fG which is not illustrated is also processed using the mask layer 145G (FIG. 21A). On the outermost surface of the organic compound layer 112G, a functional layer having high heat resistance, for example, an electron-transport layer, is preferably positioned.

At that time, the top surface of the connection electrode 111C is exposed.

Note that before the organic compound film 112fG is formed, heat treatment is preferably performed at higher than or equal to 70° C. and lower than or equal to 90° C. for longer than or equal to 15 minutes and shorter than or equal to 60 minutes in a vacuum. Thus, water and the like adsorbed on the formation surface of the organic compound film 112fG can be removed.

In this manner, the organic compound layer 112G can be formed from the organic compound film 112fG.

[Film Formation and Etching of Organic Compound Film 112fB]

As in the case where the organic compound layer 112R is formed from the organic compound film 112fR, the organic compound layer 112B is formed in the following manner: an organic compound film 112fB is formed, a mask film 144B and a mask film 146B which are not illustrated are also formed, a mask layer 147B is formed by processing the mask film 146B, a mask layer 145B is formed by processing the mask film 144B using the mask layer 147B, and the organic compound film 112fB which is not illustrated is also processed using the mask layer 145B (FIG. 21A). On the outermost surface of the organic compound layer 112B, a functional layer having high heat resistance, for example, an electron-transport layer, is preferably positioned.

At that time, the top surface of the connection electrode 111C is exposed.

Note that before the organic compound film 112fB is formed, heat treatment is preferably performed at higher than or equal to 70° C. and lower than or equal to 90° C. for longer than or equal to 15 minutes and shorter than or equal to 60 minutes in a vacuum. Thus, water and the like adsorbed on the formation surface of the organic compound film 112fB can be removed.

In this manner, the organic compound layer 112B can be formed from the organic compound film 112fB.

Note that the insulating layer 104 is exposed when the organic compound film 112fR, the organic compound film 112fG, and the organic compound film 112fB are etched. Thus, depressed portions of the insulating layer 104 may be formed in regions which overlap with the slit 118a and the slit 118b. In the case where the depressed portions are not desired to be formed, a film highly resistant to the etching treatment of the organic compound film 112fR, the organic compound film 112fG, and the organic compound film 112fB is preferably used as the insulating layer 104. For example, an insulating film containing an inorganic material is preferably used as the insulating layer 104.

In addition, the slit 118a and the slit 118b are formed among the organic compound layer 112R, the organic compound layer 112G, and the organic compound layer 112B. The organic compound layers 112 obtained through the processing step using a photolithography method, the widths of the slit 118a and the slit 118b indicated by arrows in FIG. 21A can be less than or equal to 8 μm, less than or equal to 3 μm, less than or equal to 2 μm, or less than or equal to 1 μm. The widths of the slit 118a and the slit 118b correspond to the distance between the subpixels. When the distance between the subpixels is shortened, the display apparatus with high resolution and a high aperture ratio can be provided. Note that the widths of the slit 118a and the slit 118b are not necessarily constant. For example, the width of the slit 118a may be larger than the width of the slit 118b. The width of the slit 118b may be larger than the width of the slit 118a.

As illustrated by the slit 118a and the slit 118b, the organic compound layers 112 adjacent to each other are separated and a current leakage path (a leakage path) is divided; thus, leakage current (also referred to as side leakage and side leakage current) can be inhibited. In this manner, in the light-emitting device, it is possible to increase luminance, contrast, display quality, and power efficiency or to reduce power consumption, for example.

### [Removal of Mask Layers]

Next, the mask layer 147R, the mask layer 147G, and the mask layer 147B are removed, so that the top surfaces of the mask layer 145R, the mask layer 145G, and the mask layer 145B are exposed.

[Formation of Insulating Film 125f]

Then, the insulating film 125f is formed to cover the mask layer 145R, the mask layer 145G, the mask layer 145B, and the connection electrode 111C. The insulating film 125f can be formed in a manner similar to that of the insulating film 125f described in Embodiment 1 (see FIG. 12A described in Embodiment 1).

### [Formation of Insulating Layer 126]

Next, the insulating layer 126 is formed in the regions overlapping with the slit 118a and the slit 118b. The insulating layer 126 can be formed in a manner similar to that of the insulating layer 126 described in Embodiment 1 (see FIG. 12A described in Embodiment 1).

### [Etching of Insulating Film 125f, Mask Layer 145R, Mask Layer 145G, and Mask Layer 145B]

Then, the insulating layer 125 is formed in the following manner: portions of the insulating film 125f, the mask layer 145R, the mask layer 145G, and the mask layer 145B, which are not covered with the insulating layer 126, are removed by etching, so that part of the top surfaces of the organic compound layers 112 is exposed. For the etching conditions of the insulating film 125f, the mask layer 145R, the mask layer 145G, and the mask layer 145B, the etching conditions and the like of the insulating film 125f, the mask layers 145, and the like described in Embodiment 1 can be used.

Part of the insulating film 125f is removed, so that part of the top surface of the connection electrode 111C is exposed.

### [Formation of Common Layer 114]

Next, the common layer 114 is formed in a manner similar to that in Embodiment 1 to cover the organic compound layer 112R, the organic compound layer 112G, the organic compound layer 112B, the insulating layer 126, and the like (FIG. 21B).

### [Formation of Common Electrode 113]

Then, the common electrode 113 is formed in a manner similar to that in Embodiment 1 to cover the common layer 114 (FIG. 21B).

### [Formation of Auxiliary Wiring]

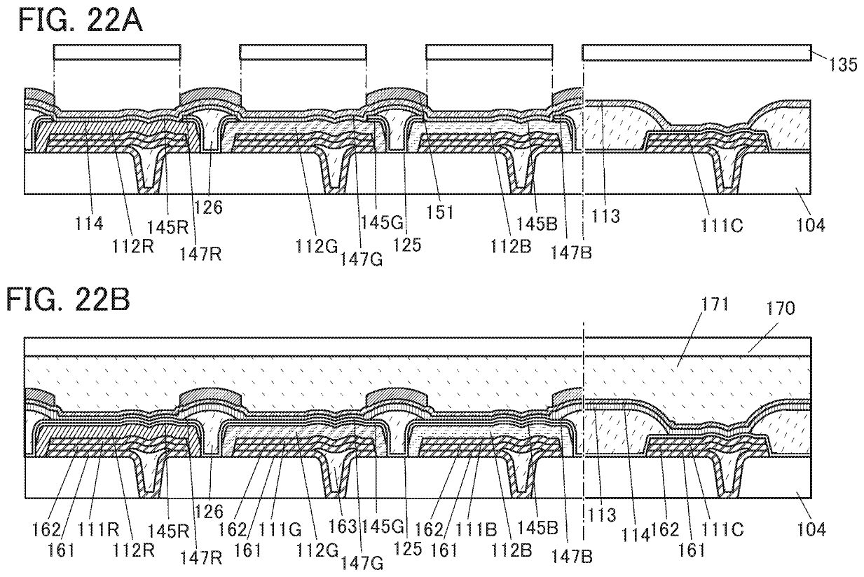

Next, the auxiliary wiring 151 is formed over the common electrode 113 (FIG. 22A). In this embodiment, the auxiliary wiring 151 is selectively formed over the common electrode 113 using a mask 135. For example, the auxiliary wiring 151 can be formed by a sputtering method. When a metal mask is used in the case of using a sputtering method, the auxiliary wiring 151 as illustrated in FIG. 1D or FIG. 1E can be selectively formed.

The auxiliary wiring 151 is formed in a position overlapping with the insulating layer 126 in the pixel portion 103. The auxiliary wiring 151 formed in such a manner is preferable because the aperture ratio of the display apparatus is not reduced.

The auxiliary wiring 151 is formed to include the region in contact with the common electrode 113. Thus, voltage drop due to the common electrode 113 can be inhibited.

### [Formation of Counter Substrate]

As in Embodiment 1, using the adhesive layer 171, the substrate 170 is attached (FIG. 22B).

Although not illustrated, the substrate 170 may be provided with the light-blocking layer 152, the coloring layer 173R, the coloring layer 173G, and the coloring layer 173B as in Embodiment 1.

In the above manner, the display apparatus can be manufactured.

Note that the display apparatuses described in Specific Examples 9 to 14 and Variation Examples 3 and 4 can also be manufactured in accordance with the above description.

At least part of this embodiment can be implemented in combination with the other embodiments described in this specification as appropriate.

### Embodiment 3

In this embodiment, a display apparatus of one embodiment of the present invention is described with reference to the drawings.

### [Specific Example of Display Apparatus]

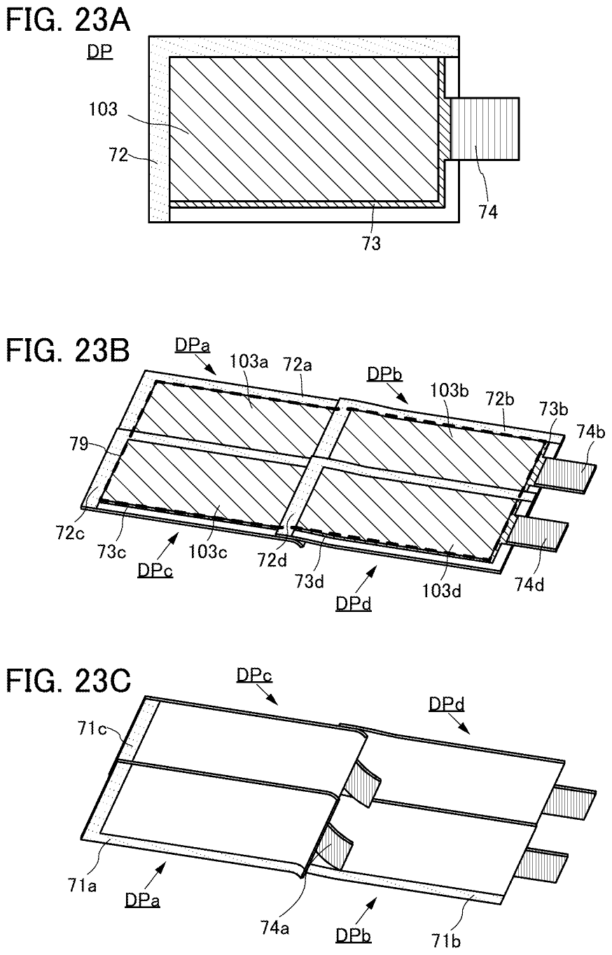

A large display apparatus using a plurality of display modules DP each of which includes the display apparatus described in the above embodiment and an FPC 74 is described with reference to FIG. 23A to FIG. 23C.

FIG. 23A illustrates a top view of the display module DP. The display module DP includes a visible-light-transmitting region 72 and a visible-light-blocking region 73 which are adjacent to the pixel portion 103.

FIG. 23B and FIG. 23C each illustrate a perspective view of the display apparatus including four display modules DP. When the plurality of display modules DP are arranged in one or more directions (e.g., in one column or in a matrix), a large display apparatus with a large display region can be manufactured.

In the case where the large display apparatus is manufactured using the plurality of display modules DP, each of the display modules DP is not required to be large. Thus, an apparatus for manufacturing the display module DP does not need to be increased in size, whereby space-saving can be achieved. Furthermore, since an apparatus for manufacturing a small- and medium-sized display panel can be used and a novel apparatus does not need to be utilized for larger display apparatus, manufacturing cost can be reduced. In addition, a decrease in yield caused by an increase in the size of the display module DP can be inhibited.

In the outer periphery of the pixel portion 103, a non-display region where a wiring and the like are routed might be positioned. The non-display region corresponds to the visible-light-blocking region 73. When the plurality of display modules DP overlap with each other, one image is sometimes perceived as separated images by the non-display region and the like.

In view of this, in one embodiment of the present invention, the visible-light-transmitting region 72 is provided in the display module DP, and in two display modules overlapping with each other, the pixel portion 103 of the display module DP positioned on the lower side and the visible-light-transmitting region 72 of the display module DP positioned on the upper side overlap with each other.

The visible-light-transmitting region 72 is provided in such a manner, the non-display region does not need to be reduced actively in the display module DP. Note that two display modules DP in an overlapped state is preferable because the non-display region is reduced. In this manner, a large display apparatus in which a seam between the display modules DP is hardly recognized by the user can be obtained.

In the display module DP positioned on the upper side, the visible-light-transmitting region 72 may be provided in at least part of the non-display region. The visible-light-transmitting region 72 can overlap with the pixel portion 103 of the display module DP positioned on the lower side.

Furthermore, the pixel portion 103 of the display module DP positioned on the upper side or the visible-light-blocking region 73 overlaps with at least part of the non-display region of the display module DP positioned on the lower side.

A large non-display region of the display module DP is preferable because the distance between the end portion of the display module DP and an element in the display module DP is increased, in which case the deterioration of the element due to entry of impurities from the outside of the display module DP can be inhibited.

As described above, in the case where the plurality of display modules DP are provided in the display apparatus, the pixel portions 103 are continuous in the display modules DP adjacent to each other; thus, a display region with large area can be provided.

The pixel portion 103 includes a plurality of pixels.

In the visible-light-transmitting region 72, a pair of substrates that constitutes the display module DP, a resin material for sealing a display element interposed between the pair of substrates, and the like may be provided. At this time, for members provided in the visible-light-transmitting region 72, a material having a visible-light-transmitting property is used.

In the visible-light-blocking region 73, a wiring electrically connected to the pixel included in the pixel portion 103 may be provided. Moreover, one or both of a scan line driver circuit and a signal line driver circuit may be provided in the visible-light-blocking region 73. Furthermore, a terminal connected to the FPC 74, a wiring connected to the terminal, and the like may be provided in the visible-light-blocking region 73.

FIG. 23B and FIG. 23C illustrate an example in which the display modules DP illustrated in FIG. 23A are arranged in a 2×2 matrix (two display modules DP are arranged in each of the longitudinal direction and the lateral direction). FIG. 23B is a perspective view of the display surface side of the display module DP, and FIG. 23C is a perspective view of the side opposite to the display surface side of the display module DP.

Four display modules DP (display modules DPa, DPb, DPc, and DPd) are arranged so as to include regions overlapping with each other. Specifically, the display modules DPa, DPb, DPc, and DPd are arranged such that the visible-light-transmitting region 72 that is included in one display module DP includes a region overlapping with the pixel portion 103 (on the display surface side) included in another display module DP. In addition, the display modules DPa, DPb, DPc, and DPd are arranged such that the visible-light-blocking region 73 that is included in one display module DP does not overlap with the pixel portion 103 of another display module DP. In a portion where the four display modules DP overlap with each other, the display module DPb overlaps with the display module DPa, the display module DPc overlaps with the display module DPb, and the display module DPd overlaps with the display module DPc.

The short sides of the display modules DPa and DPb overlap with each other, and part of a pixel portion 103a and part of a visible-light-transmitting region 72b overlap with each other. Furthermore, the long sides of the display modules DPa and DPc overlap with each other, and part of the pixel portion 103a and part of a visible-light-transmitting region 72c overlap with each other.

Part of the visible-light-transmitting region 72c and part of a visible-light-transmitting region 72d overlap with part of a pixel portion 103b. In addition, part of a pixel portion 103c and part of the visible-light-transmitting region 72d overlap with each other.

Therefore, a region where the pixel portion 103a to the pixel portion 103d are placed almost seamlessly can be a display region 79.

Here, it is preferable that the display module DP have flexibility. For example, the pair of substrates included in the display module DP preferably have flexibility.

Thus, as illustrated in FIG. 23B and FIG. 23C, a vicinity of an FPC 74a of the display module DPa can be bent so that part of the display module DPa and part of the FPC 74a can be placed under the pixel portion 103b of the display module DPb adjacent to the FPC 74a, for example. As a result, the FPC 74a can be placed without physical interference with the rear surface of the display module DPb. Furthermore, when the display module DPa and the display module DPb overlap with each other and are fixed, it is not necessary to consider the thickness of the FPC 74a; thus, a difference of the heights between the top surface of the visible-light-transmitting region 72b and the top surface of the display module DPa can be reduced. As a result, the end portion of the display module DPb positioned over the pixel portion 103a can be less noticeable.

Moreover, each display module DP is made flexible, in which case the display module DPb can be curved gently so that the height of the top surface of the pixel portion 103b of the display module DPb is the same as the height of the top surface of the pixel portion 103a of the display module DPa. Thus, the heights of the display regions can be the same as each other except in the vicinity of a region where the display module DPa and the display module DPb overlap with each other, and display quality of an image displayed on the display region 79 can be improved.

Although the relation between the display module DPa and the display module DPb is taken as an example in the above description, the same can apply to the relation between any other two adjacent display modules DP.

Note that to reduce the step between two adjacent display modules DP, the thicknesses of the display modules DP are preferably small. For example, the thickness of the display module DP is preferably less than or equal to 1 mm, further preferably less than or equal to 300 μm, still further preferably less than or equal to 100 μm.

The display module DP preferably incorporates both a scan line driver circuit and a signal line driver circuit. In the case where a driver circuit is provided separately from the display panel, a printed circuit board including a driver circuit and a large number of wirings, terminals, and the like are provided on the back side (the side opposite to the display surface side) of the display panel. Thus, the number of components of the whole display apparatus becomes enormous, which leads to an increase in weight of the display apparatus in some cases. When the display module DP includes both a scan line driver circuit and a signal line driver circuit, the number of components of the display apparatus can be reduced and the weight of the display apparatus can be reduced. This leads to higher portability of the display apparatus.

Here, the scan line driver circuit and the signal line driver circuit are required to operate at a high driving frequency in accordance with the frame frequency of an image to be displayed. In particular, the signal line driver circuit is required to operate at a higher driving frequency than the scan line driver circuit. Therefore, some transistors used for the signal line driver circuit require large current supply capability in some cases. Meanwhile, some transistors provided in the pixel portion require adequate withstand voltage for driving the display element in some cases.

In view of the above, the transistor included in the driver circuit and the transistor included in the pixel portion are preferably formed to have different structures. For example, one or a plurality of transistors provided in the pixel portion are transistors with high withstand voltage, and one or a plurality of transistors provided in the driver circuit are transistors with high driving frequency.

Specifically, one or a plurality of transistors used for the signal line driver circuit are transistors each including a thinner gate insulating layer than the transistor used for the pixel portion. By forming two kinds of transistors separately as described above, the signal line driver circuit can be formed over the substrate over which the pixel portion is provided. As each transistor used for the scan line driver circuit, the signal line driver circuit, and the pixel portion, a transistor in which a metal oxide is used for a semiconductor where a channel is formed is preferably used.

As each transistor used for the scan line driver circuit, the signal line driver circuit, and the pixel portion, a transistor in which silicon is used for a semiconductor where a channel is formed is preferably used.

As each transistor used for the scan line driver circuit, the signal line driver circuit, and the pixel portion, a transistor in which a metal oxide is used for a semiconductor where a channel is formed and a transistor in which silicon is used for a semiconductor where a channel is formed are preferably used in combination.

At least part of this embodiment can be implemented in combination with the other embodiments described in this specification as appropriate.

### Embodiment 4

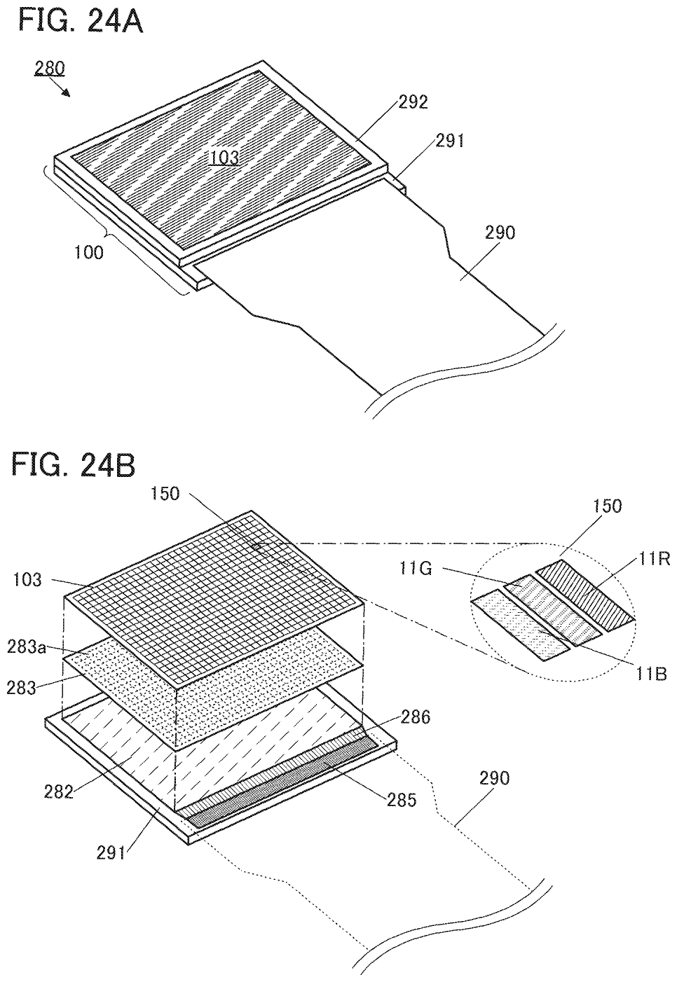

In this embodiment, a display apparatus of one embodiment of the present invention is described with reference to FIG. 24 to FIG. 30.

The display apparatus of this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on the head, such as a VR (Virtual Reality) device like a head mounted display and a glasses-type AR (Augmented Reality) device.

### [Display Module]

FIG. 24A illustrates a perspective view of a display module 280. The display module 280 includes the display apparatus 100 and an FPC 290.

The display module 280 includes a substrate 291 and a substrate 292. The display module 280 includes the pixel portion 103. The pixel portion 103 is a region of the display module 280 where an image is displayed and is a region where light from pixels provided in the pixel portion 103 described later can be perceived.

FIG. 24B illustrates a perspective view schematically illustrating a structure on the substrate 291 side. Over the substrate 291, a circuit portion 282, a pixel circuit portion 283 over the circuit portion 282, and the pixel portion 103 over the pixel circuit portion 283 are stacked.

In addition, a terminal portion 285 for connection to the FPC 290 (also referred to as an FPC terminal portion) is provided in a portion over the substrate 291 that does not overlap with the pixel portion 103. The terminal portion 285 and the circuit portion 282 are electrically connected to each other through a wiring portion 286 formed of a plurality of wirings.

The pixel portion 103 includes the plurality of pixels 150 arranged periodically. An enlarged view of one pixel 150 is illustrated on the right side of FIG. 24B. The pixel 150 includes the light-emitting device 11R, the light-emitting device 11G, and the light-emitting device 11B with different emission colors. The pixel 150 may further include the light-receiving device 11S. The plurality of light-emitting devices can be arranged in a stripe pattern as illustrated in FIG. 24B. Alternatively, a variety of arrangement methods for light-emitting devices, such as a delta arrangement or a PenTile arrangement, can be employed.

The pixel circuit portion 283 includes a pixel circuit 283a including a plurality of transistors and the like arranged periodically.

One pixel circuit 283a is a circuit that controls light emission of light-emitting devices included in one pixel 150. One pixel circuit 283a may be provided with three circuits for controlling light emission of one light-emitting device. For example, the pixel circuit 283a for one light-emitting device can include at least one selection transistor, one current control transistor (driving transistor), and a capacitor. In this case, a gate signal is input to a gate of the selection transistor and a source signal is input to one of a source and a drain thereof. With such a structure, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. In addition, an IC may be mounted on the FPC 290.

The display module 280 can have a structure in which one or both of the pixel circuit portion 283 and the circuit portion 282 are stacked below the pixel portion 103; hence, the aperture ratio (effective display area ratio) of the pixel portion 103 can be significantly high. For example, the aperture ratio of the pixel portion 103 can be greater than or equal to 40% and less than 100%, preferably greater than or equal to 50% and less than or equal to 95%, further preferably greater than or equal to 60% and less than or equal to 95%. Furthermore, the pixels 150 can be arranged extremely densely, and thus the resolution of the pixel portion 103 can be extremely high. For example, the pixels 150 are preferably arranged in the pixel portion 103 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 280 has extremely high resolution, and thus can be suitably used for a VR device such as a head-mounted display or a glasses-type AR device. For example, even in the case of a structure in which the display portion of the display module 280 is perceived through a lens, pixels of the extremely minute pixel portion 103 included in the display module 280 are not perceived when the display portion is enlarged by the lens, so that display providing a high sense of immersion can be performed. Without limitation to the above, the display module 280 can also be suitably used for an electronic device having a relatively small display portion. For example, the display module 280 can be suitably used in a display portion of a wearable electronic device such as a wrist watch.

### [Structure Example of Display Apparatus]

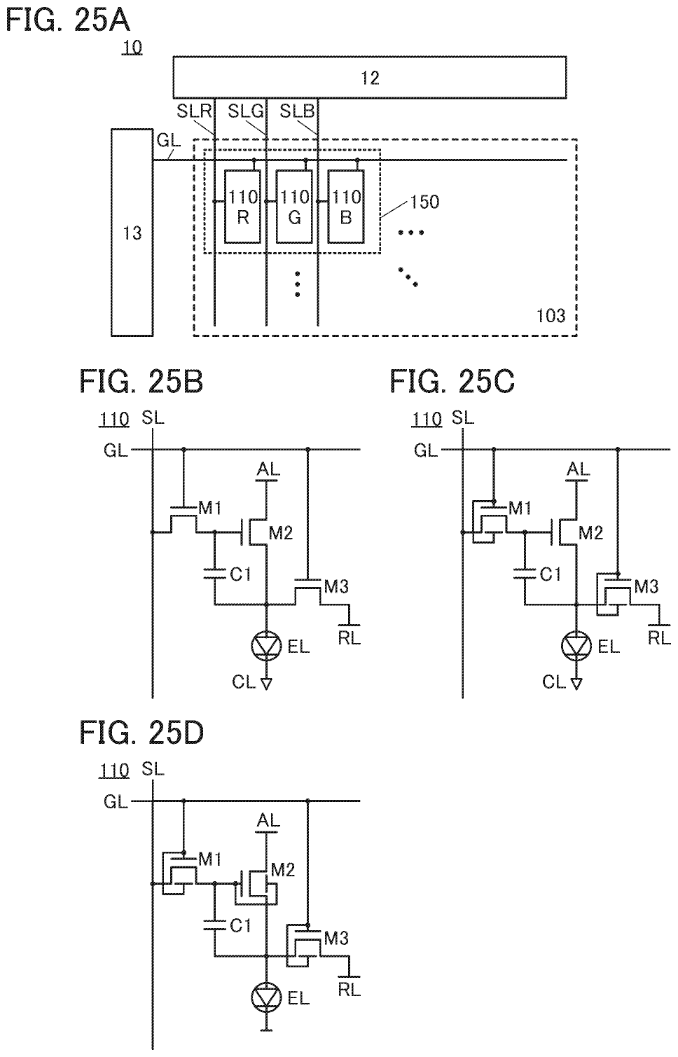

FIG. 25A illustrates a block diagram of a display apparatus 10. The display apparatus 10 includes the pixel portion 103, a driver circuit portion 12, a driver circuit portion 13, and the like.

The pixel portion 103 includes the plurality of pixels 150 arranged in a matrix. The pixel 150 includes the subpixel 110R, the subpixel 110G, and the subpixel 110B. The subpixel 110R, the subpixel 110G, and the subpixel 110B each include a light-emitting device functioning as a display device.

The pixel 150 is electrically connected to a wiring GL, a wiring SLR, a wiring SLG, and a wiring SLB. The wiring SLR, the wiring SLG, and the wiring SLB are electrically connected to the driver circuit portion 12. The wiring GL is electrically connected to the driver circuit portion 13. The driver circuit portion 12 functions as a source line driver circuit (also referred to as a source driver), and the driver circuit portion 13 functions as a gate line driver circuit (also referred to as a gate driver). The wiring GL functions as a gate line, and the wiring SLR, the wiring SLG, and the wiring SLB function as source lines.

The subpixel 110R includes a light-emitting device that emits red light. The subpixel 110G includes a light-emitting device that emits green light. The subpixel 110B includes a light-emitting device that emits blue light. Thus, the display apparatus 10 can perform full-color display. Note that the pixel 150 may include a subpixel including a light-emitting device that emits light of another color. For example, the pixel 150 may include, in addition to the three subpixels, a subpixel including a light-emitting device that emits white light, a subpixel including a light-emitting device that emits yellow light, or the like.

The wiring GL is electrically connected to the subpixel 110R, the subpixel 110G, and the subpixel 110B arranged in a row direction (an extending direction of the wiring GL). The wiring SLR, the wiring SLG, and the wiring SLB are electrically connected to the subpixels 110R, the subpixels 110G, and the subpixels 110B (not illustrated) arranged in a column direction (an extending direction of the wiring SLR and the like), respectively.

### [Structure Example of Pixel Circuit]

FIG. 25B illustrates an example of a circuit diagram of the pixel 150 that can be used as the subpixel 110R, the subpixel 110G, and the subpixel 110B. The pixel 150 includes a transistor M1, a transistor M2, a transistor M3, a capacitor C1, and a light-emitting device EL. The wiring GL and a wiring SL are electrically connected to the pixel 150. The wiring SL corresponds to any of the wiring SLR, the wiring SLG, and the wiring SLB illustrated in FIG. 25A.

A gate of the transistor M1 is electrically connected to the wiring GL, one of a source and a drain of the transistor M1 is electrically connected to the wiring SL, and the other of the source and the drain of the transistor M1 is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential is supplied to the wiring SL. A selection signal is supplied to the wiring GL. The selection signal includes a potential for turning on a transistor and a potential for turning off a transistor.

A reset potential is supplied to the wiring RL. An anode potential is supplied to the wiring AL. A cathode potential is supplied to the wiring CL. In the pixel 150, the anode potential is a potential higher than the cathode potential. The reset potential supplied to the wiring RL can be a potential such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. The transistor M2 functions as a transistor that controls current flowing through the light-emitting device EL. For example, it can be regarded that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In that case, an LTPS transistor can be used as at least one of a plurality of transistors included in the driver circuit portion 12 and a plurality of transistors included in the driver circuit portion 13, and OS transistors can be used as the other transistors. For example, OS transistors can be used as the transistors provided in the pixel portion 103, and LTPS transistors can be used as the transistors provided in the driver circuit portion 12 and the driver circuit portion 13.

As the OS transistor, a transistor including an oxide semiconductor in a semiconductor layer in which a channel is formed can be used. The semiconductor layer preferably includes indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Alternatively, it is preferable to use an oxide containing indium, gallium, tin, and zinc.

A transistor using an oxide semiconductor having a wider band gap and a lower carrier density than silicon can achieve extremely low off-state current. Thus, such low off-state current enables long-term retention of charge accumulated in a capacitor that is connected in series with the transistor. Therefore, it is particularly preferable to use a transistor including an oxide semiconductor as the transistor M1 and the transistor M3 each of which is connected to the capacitor C1 in series. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 150.

Although n-channel transistors are illustrated as the transistors in FIG. 25B, p-channel transistors can be used.

The transistors included in the pixel 150 are preferably arranged over the same substrate.

Transistors each including a pair of gates overlapping with each other with a semiconductor layer therebetween can be used as the transistors included in the pixel 150.

In the transistor including the pair of gates, the same potential is supplied to the pair of gates electrically connected to each other, which brings advantage that the transistor can have higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 150 illustrated in FIG. 25C is an example of a case where a transistor including a pair of gates is used as each of the transistor M1 and the transistor M3. In each of the transistor M1 and the transistor M3, the pair of gates are electrically connected to each other. Such a structure can shorten the period in which data is written to the pixel 150.

The pixel 150 illustrated in FIG. 25D is an example of a case where a transistor including a pair of gates is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device EL can be controlled easily and display quality can be increased.

### [Structure Example of Transistor]

Cross-sectional structure examples of a transistor that can be used in the display apparatus are described below.

### Structure Example 1

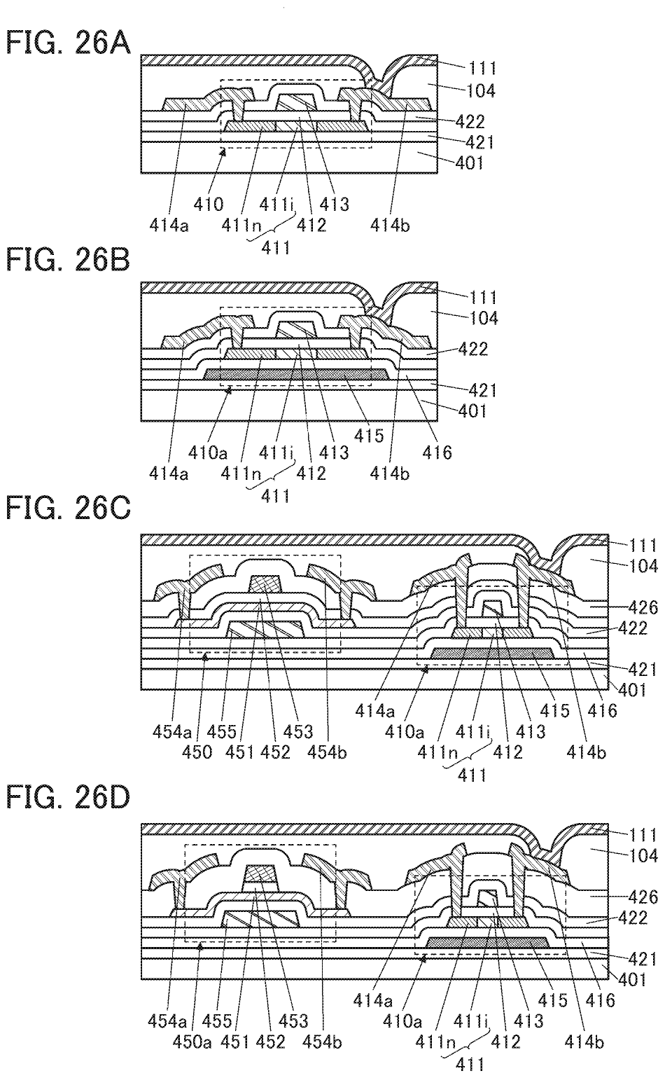

FIG. 26A is a cross-sectional view including a transistor 410.

The transistor 410 is a transistor provided over a substrate 401 and containing polycrystalline silicon in its semiconductor layer. For example, the transistor 410 corresponds to the transistor M2 in the pixel 150. In other words, FIG. 26A is an example in which one of a source and a drain of the transistor 410 is electrically connected to the lower electrode 111 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can contain a metal oxide exhibiting semiconductor characteristics (also referred to as an oxide semiconductor). In this case, the transistor 410 can be referred to as an OS transistor.

The low-resistance regions 411n are regions containing an impurity element. For example, in the case where the transistor 410 is an n-channel transistor, phosphorus, arsenic, or the like is added to the low-resistance regions 411n. Meanwhile, in the case where the transistor 410 is a p-channel transistor, boron, aluminum, or the like is added to the low-resistance regions 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are electrically connected to the low-resistance regions 411n in opening portions provided in the insulating layer 422 and the insulating layer 412. Part of the conductive layer 414a functions as one of a source electrode and a drain electrode and part of the conductive layer 414b functions as the other of the source electrode and the drain electrode. The insulating layer 104 is provided to cover the conductive layer 414a, the conductive layer 414b, and the insulating layer 422.

The lower electrode 111 functioning as a pixel electrode is provided over the insulating layer 104. The lower electrode 111 is provided over the insulating layer 104 and is electrically connected to the conductive layer 414b through an opening provided in the insulating layer 104. Although not illustrated here, an EL layer and a common electrode can be stacked over the lower electrode 111.

### Structure Example 2

FIG. 26B illustrates a transistor 410a including a pair of gate electrodes. The transistor 410a illustrated in FIG. 26B is different from FIG. 26A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 26B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through opening portions provided in the insulating layer 412 and the insulating layer 416 in a region not illustrated. To electrically connect the second gate electrode to a source or a drain, the conductive layer 415 is electrically connected to the conductive layer 414a or the conductive layer 414b through opening portions provided in the insulating layer 422, the insulating layer 412, and the insulating layer 416 in a region not illustrated.

In the case where all of the transistors included in the pixel 150 are LTPS transistors, the transistor 410 illustrated in FIG. 26A or the transistor 410a illustrated in FIG. 26B can be used. In this case, the transistors 410a may be used as all of the transistors included in the pixel 150, the transistors 410 may be used as all of the transistors, or a combination of the transistors 410a and the transistors 410 may be used.

### Structure Example 3

Described below is an example of a structure including both a transistor containing silicon in its semiconductor layer and a transistor including a metal oxide in its semiconductor layer.

FIG. 26C illustrates a cross-sectional view including the transistor 410a and a transistor 450.

Structure Example 1 described above can be referred to for the transistor 410a. Although the example using the transistor 410a is described here, a structure including the transistor 410 and the transistor 450 may be employed or a structure including all of the transistor 410, the transistor 410a, and the transistor 450 may be employed.

The transistor 450 is a transistor including a metal oxide in its semiconductor layer. The structure illustrated in FIG. 26C is an example where the transistor 450 and the transistor 410a corresponds to the transistor M1 and the transistor M2, respectively, in the pixel 150. That is, FIG. 26C is an example in which one of a source and a drain of the transistor 410a is electrically connected to the lower electrode 111.

Moreover, FIG. 26C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode and part of the conductive layer 454b functions as the other of the source electrode and the drain electrode. The insulating layer 104 is provided to cover the conductive layer 454a, the conductive layer 454b, and the insulating layer 426.

Here, the conductive layer 414a and the conductive layer 414b that are electrically connected to the transistor 410a are preferably formed by processing the same conductive film as the conductive layer 454a and the conductive layer 454b. FIG. 26C illustrates a structure where the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the manufacturing step can be simplified.

Moreover, the conductive layer 413 functioning as a first gate electrode of the transistor 410a and the conductive layer 455 functioning as a second gate electrode of the transistor 450 are preferably formed by processing the same conductive film. FIG. 26C illustrates a structure where the conductive layer 413 and the conductive layer 455 are formed on the same plane (i.e., in contact with the top surface of the insulating layer 412) and contain the same metal element. This is preferable because the manufacturing step can be simplified.

Although the insulating layer 452 functioning as the first gate insulating layer of the transistor 450 covers the end portion of the semiconductor layer 451 in the structure in FIG. 26C, the insulating layer 452 may be processed such that the top surface shape of the insulating layer 452 is the same or substantially the same as the top surface shape of the conductive layer 453 as in a transistor 450a illustrated in FIG. 26D.

Note that in this specification and the like, the expression “top surface shapes are substantially the same” means that at least outlines of stacked layers partly overlap with each other. For example, the case of processing or partly processing an upper layer and a lower layer with the use of the same mask pattern is included. However, in some cases, the outlines do not completely overlap with each other and the upper layer is positioned on an inner side of the lower layer or the upper layer is positioned on an outer side of the lower layer; such a case is also represented by the expression “top surface shapes are substantially the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

When the display apparatus has the pixel circuit and the light-emitting device structure of the above embodiment, the display apparatus can have any one or more of the image crispness, the image sharpness, a high chroma, and a high contrast ratio. This structure is preferable because leakage current which might flow through the transistor of the pixel circuit is extremely low and lateral leakage current between the light-emitting devices of the above embodiment is extremely low; and light leakage or the like which might occur at the time of black display can be reduced as much as possible in the display apparatus.

This embodiment can be combined with the other embodiments as appropriate. In the case where a plurality of structure examples are described in one embodiment in this specification, the structure examples can be combined as appropriate.

### Embodiment 5

Described in this embodiment is a metal oxide (also referred to as an oxide semiconductor) that can be used in the OS transistor described in the above embodiment.

A metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a CVD method such as an MOCVD method, an ALD method, or the like.

### <Classification of Crystal Structure>

Examples of a crystal structure of an oxide semiconductor include amorphous (including completely amorphous), CAAC (c-axis-aligned crystalline), nc (nanocrystalline), CAC (cloud-aligned composite), single crystal, and polycrystalline structures.

A crystal structure of a film or a substrate can be analyzed with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method.

For example, the peak of the XRD spectrum of a quartz glass substrate has a substantially bilaterally symmetrical shape. On the other hand, the peak of the XRD spectrum of an IGZO film having a crystal structure has a bilaterally asymmetrical shape. The bilaterally asymmetrical peak of the XRD spectrum shows the existence of crystal in the film or the substrate. In other words, the crystal structure of the film or the substrate cannot be regarded as “amorphous” unless it has a bilaterally symmetrical peak in the XRD spectrum.

The crystal structure of the film or the substrate can be evaluated with a diffraction pattern obtained by a nanobeam electron diffraction (NBED) method (such a pattern is also referred to as a nanobeam electron diffraction pattern). For example, a halo pattern is observed in the diffraction pattern of a quartz glass substrate, which indicates that the quartz glass substrate is in an amorphous state. Furthermore, not a halo pattern but a spot-like pattern is observed in the diffraction pattern of an IGZO film formed at room temperature. Thus, it is presumed that the IGZO film formed at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC and nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, nc-OS, and a-like OS is described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. Furthermore, the CAAC-OS includes a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a plurality of fine crystals, the size of the crystal region may be approximately several tens of nanometers.

In the case of In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ=31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called a polycrystal structure. It is highly probable that the grain boundary becomes a recombination center and traps carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, In—Zn oxide and In—Ga—Zn oxide are suitable because they can inhibit generation of a grain boundary as compared with In oxide.

The CAAC-OS is an oxide semiconductor with high crystallinity in which no clear grain boundary is observed. Thus, in the CAAC-OS, a reduction in electron mobility due to the grain boundary is less likely to occur. Entry of impurities, formation of defects, or the like might decrease the crystallinity of an oxide semiconductor. This means that the CAAC-OS can be referred to as an oxide semiconductor having small amounts of impurities and defects (e.g., oxygen vacancies). Therefore, an oxide semiconductor including the CAAC-OS is physically stable. Accordingly, the oxide semiconductor including the CAAC-OS is resistant to heat and has high reliability. In addition, the CAAC-OS is stable with respect to high temperatures in the manufacturing process (i.e., thermal budget). Accordingly, the use of the CAAC-OS for the OS transistor can extend a degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. There is no regularity of crystal orientation between different nanocrystals in the nc-OS. Hence, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

### [A-Like OS]

The a-like OS is an oxide semiconductor having a structure between those of the nc-OS and the amorphous oxide semiconductor. The a-like OS has a void or a low-density region.

That is, the a-like OS has lower crystallinity than the nc-OS and the CAAC-OS. Moreover, the a-like OS has higher hydrogen concentration in the film than the nc-OS and the CAAC-OS.

### <<Composition of Oxide Semiconductor>>

Next, the CAC-OS is described in detail. Note that the CAC-OS relates to a material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to a metal element included in a CAC-OS in In—Ga—Zn oxide are expressed as [In], [Ga], and [Zn], respectively. For example, the first region of the CAC-OS in the In—Ga—Zn oxide has [In] higher than that in the composition of the CAC-OS film. Moreover, the second region of the CAC-OS in the In—Ga—Zn oxide has [Ga] higher than that in the composition of the CAC-OS film. Alternatively, for example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under conditions where a substrate is not heated, for example. In the case of forming the CAC-OS by a sputtering method, one or more selected from an inert gas (typically, argon), an oxygen gas, and a nitrogen gas can be used as a deposition gas. The ratio of the flow rate of an oxygen gas to the total flow rate of the deposition gas at the time of film formation is preferably as low as possible, and for example, the ratio of the flow rate of an oxygen gas to the total flow rate of the deposition gas at the time of film formation is preferably higher than or equal to 0% and less than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the regions containing In as a main component (the first regions) and the regions containing Ga as a main component (the second regions) are unevenly distributed and mixed.

Here, the first region has a higher conductivity than the second region. In other words, when carriers flow through the first region, the conductivity of a metal oxide is exhibited. Accordingly, when the first regions are distributed in a metal oxide as a cloud, high field-effect mobility (μ) can be achieved.

Meanwhile, the second region has a higher insulating property than the first region. In other words, when the second regions are distributed in a metal oxide, leakage current can be inhibited.

Thus, in the case where the CAC-OS is used for a transistor, a switching function (On/Off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), high field-effect mobility (u), and favorable switching operation can be achieved.

A transistor including the CAC-OS is highly reliable. Thus, the CAC-OS is most suitable for a variety of semiconductor devices such as a display apparatus.

An oxide semiconductor can have any of various structures that show various different properties. Two or more kinds of the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, a case where the oxide semiconductor is used for a transistor is described.

When the oxide semiconductor is used for a transistor, the transistor can have high field-effect mobility. In addition, the transistor can have high reliability.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charges trapped by the trap states in an oxide semiconductor take a long time to disappear and might behave like fixed charges. A transistor whose channel formation region is formed in an oxide semiconductor having a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, the impurity concentration in a film that is adjacent to the oxide semiconductor is preferably reduced. Examples of impurities include hydrogen, nitrogen, an alkali metal, an alkaline earth metal, iron, nickel, and silicon.

### <Impurities>

Here, the influence of impurities in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by Secondary Ion Mass Spectrometry (SIMS)) are lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor using an oxide semiconductor that contains an alkali metal or an alkaline earth metal is likely to become normally-on. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

An oxide semiconductor containing nitrogen easily becomes n-type by generation of electrons serving as carriers and an increase in carrier concentration. As a result, a transistor using the oxide semiconductor containing nitrogen as a semiconductor is likely to become normally-on. When nitrogen is contained in the oxide semiconductor, a trap state is sometimes formed. This might make the electrical characteristics of the transistor unstable. Thus, the concentration of nitrogen in the oxide semiconductor, which is obtained by SIMS, is lower than 5× 10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, some hydrogen may bond with oxygen bonded to a metal atom and generate an electron serving as a carrier. Thus, a transistor including the oxide semiconductor that contains hydrogen is likely to become normally-on. For this reason, hydrogen in the oxide semiconductor is preferably reduced as much as possible. Specifically, the hydrogen concentration in the oxide semiconductor, which is obtained by SIMS, is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, the transistor can have stable electrical characteristics.

This embodiment can be combined with any of the other embodiments as appropriate. In this specification, in the case where a plurality of structure examples are described in one embodiment, the structure examples can be combined as appropriate.

### Embodiment 6

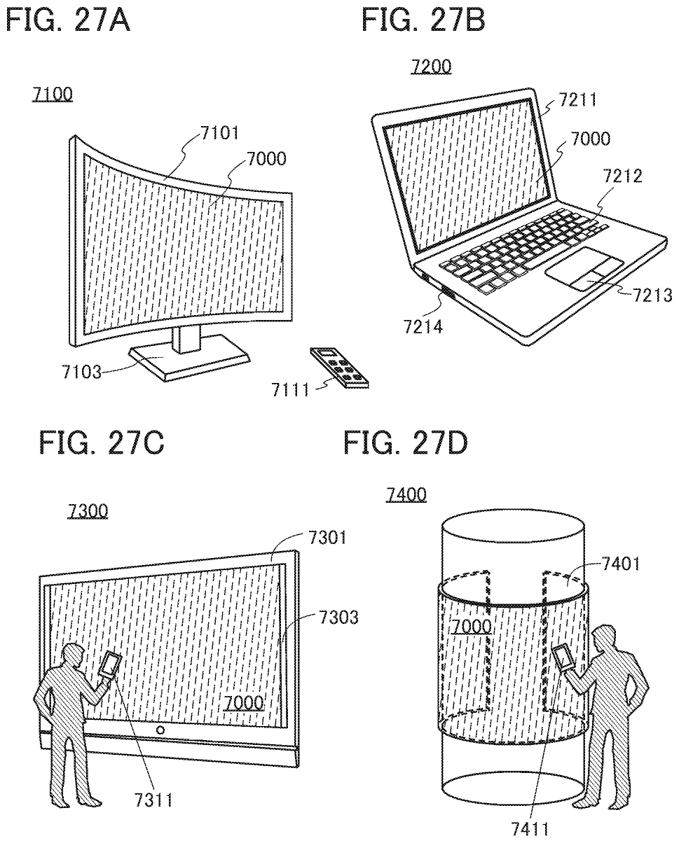

In this embodiment, electronic devices of one embodiment of the present invention are described with reference to FIG. 27 to FIG. 30.

Electronic devices of this embodiment are each provided with the display apparatus of one embodiment of the present invention in a display portion. The resolution and the definition of the display apparatus of one embodiment of the present invention can be easily increased. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display apparatus of one embodiment of the present invention can have a high resolution, and thus can be suitably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR (Mixed Reality) device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display apparatus having one or both of such high definition and high resolution can further increase realistic sensation, sense of depth, and the like in personal use such as portable use or home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays).

The electronic device in this embodiment can have a variety of functions. For example, the electronic device in this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

FIG. 27A illustrates an example of a television device. In a television device 7100, a pixel portion 7000 is incorporated in a housing 7101. Here, the housing 7101 is supported by a stand 7103.

The pixel portion 103 of one embodiment of the present invention can be used in the pixel portion 7000.

Operation of the television device 7100 illustrated in FIG. 27A can be performed with an operation switch provided in the housing 7101 and a separate remote controller 7111. Alternatively, the pixel portion 7000 may include a touch sensor, and the television device 7100 may be operated by touch on the pixel portion 7000 with a finger or the like. The remote controller 7111 may be provided with a display portion for displaying information output from the remote controller 7111. With operation keys or a touch panel provided in the remote controller 7111, channels and volume can be controlled and videos displayed on the pixel portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 27B illustrates an example of a laptop personal computer. A laptop personal computer 7200 includes a housing 7211, a keyboard 7212, a pointing device 7213, an external connection port 7214, and the like. The pixel portion 7000 is incorporated in the housing 7211.

The pixel portion 103 of one embodiment of the present invention can be used in the pixel portion 7000.

FIG. 27C and FIG. 27D illustrate examples of digital signage.

Digital signage 7300 illustrated in FIG. 27C includes a housing 7301, the pixel portion 7000, a speaker 7303, and the like. The digital signage 7300 can also include an LED lamp, an operation key (including a power switch or an operation switch), a connection terminal, a variety of sensors, a microphone, and the like.

FIG. 27D illustrates digital signage 7400 attached to a cylindrical pillar 7401. The digital signage 7400 includes the pixel portion 7000 provided along a curved surface of the pillar 7401.

In FIG. 27C and FIG. 27D, the pixel portion 103 of one embodiment of the present invention can be used in the pixel portion 7000.

A larger area of the pixel portion 7000 can increase the amount of data that can be provided at a time. The larger pixel portion 7000 attracts more attention, so that the effectiveness of the advertisement can be increased, for example.

The use of a touch panel in the pixel portion 7000 is preferable because in addition to display of an image or a moving image on the pixel portion 7000, intuitive operation by a user is possible. Moreover, for an application for providing information such as route information or traffic information, usability can be enhanced by intuitive operation.

As illustrated in FIG. 27C and FIG. 27D, it is preferable that the digital signage 7300 or the digital signage 7400 can work with an information terminal 7311 or an information terminal 7411, such as a smartphone that a user has, through wireless communication. For example, information of an advertisement displayed on the pixel portion 7000 can be displayed on a screen of the information terminal 7311 or the information terminal 7411. By operation of the information terminal 7311 or the information terminal 7411, display on the pixel portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

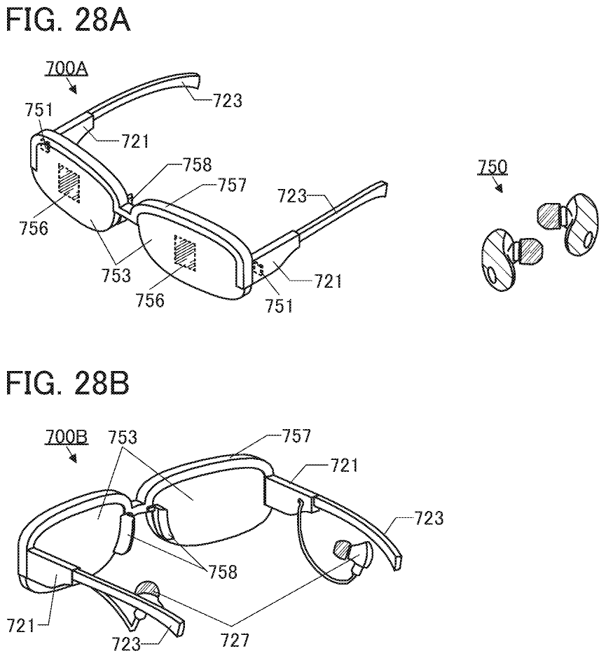

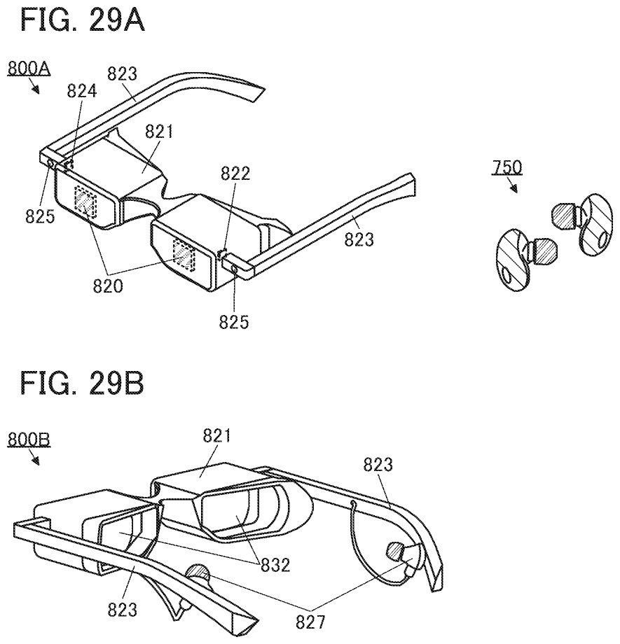

Examples of head-mounted wearable devices are described with reference to FIG. 28A, FIG. 28B, FIG. 29A, and FIG. 29B. These wearable devices have one or both of a function of displaying AR contents and a function of displaying VR contents. Note that these wearable devices may have a function of displaying SR (Substitutional Reality) or MR contents, in addition to AR and VR contents. The electronic device having a function of displaying contents of AR, VR, SR, MR, or the like enables the user to reach a higher level of immersion.

An electronic device 700A illustrated in FIG. 28A and an electronic device 700B illustrated in FIG. 28B each include a pair of pixel portions 751, a pair of housings 721, a communication portion (not illustrated), a pair of mounting portions 723, a control portion (not illustrated), an image capturing portion (not illustrated), a pair of optical members 753, a frame 757, and a pair of nose pads 758.

The pixel portion 103 of one embodiment of the present invention can be used in the pixel portion 751.

The electronic device 700A and the electronic device 700B can each project images displayed on the pixel portions 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 29A and an electronic device 800B illustrated in FIG. 29B each include a pair of display portions 820, a housing 821, a communication portion 822, a pair of mounting portions 823, a control portion 824, a pair of image capturing portions 825, and a pair of lenses 832.

The pixel portion 103 of one embodiment of the present invention can be used in the display portion 820.

The display portions 820 are provided at a position inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the mounting portions 823. FIG. 29A and the like illustrate examples where the mounting portion 823 has a shape like a temple (also referred to as a joint or the like) of glasses; however, one embodiment of the present invention is not limited thereto. The mounting portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portions 825 are provided is shown here, a range sensor capable of measuring the distance between the user and an object (hereinafter also referred to as a sensing portion) just needs to be provided. In other words, the image capturing portion 825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, any one or more of the display portion 820, the housing 821, and the mounting portion 823 can include the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A illustrated in FIG. 28A has a function of transmitting information to the earphones 750 with the wireless communication function. As another example, the electronic device 800A illustrated in FIG. 29A has a function of transmitting information to the earphones 750 with the wireless communication function.

The electronic device may include an earphone portion. The electronic device 700B illustrated in FIG. 28B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic device 800B illustrated in FIG. 29B includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferred because the earphone portions 827 can be fixed to the mounting portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

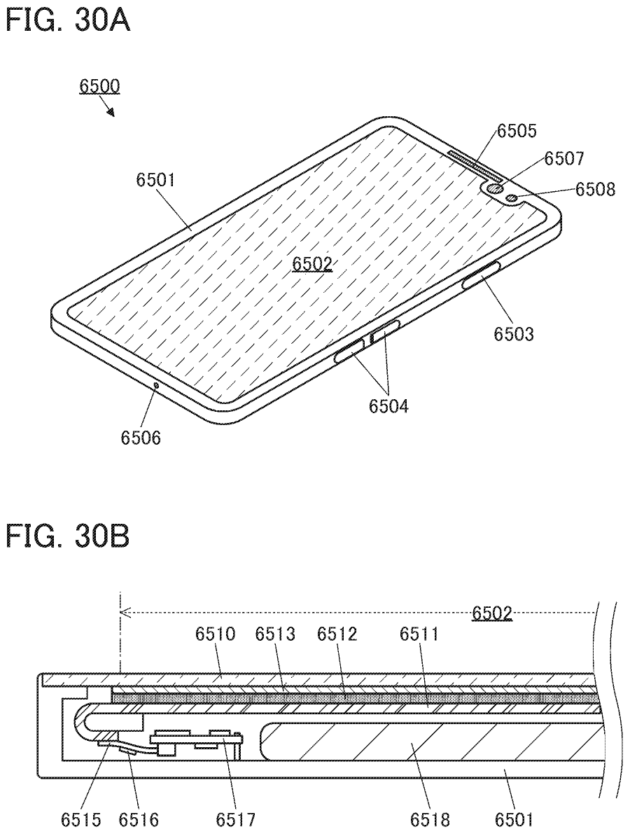

An electronic device 6500 illustrated in FIG. 30A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The pixel portion 103 of one embodiment of the present invention can be used in the display portion 6502.

FIG. 30B is a cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

This embodiment can be combined with any of the other embodiments as appropriate. In this specification, in the case where a plurality of structure examples are described in one embodiment, the structure examples can be combined as appropriate.

### REFERENCE NUMERALS

AL: wiring, CL: wiring, DP: display module, DPa: display module, DPb: display module, DPc: display module, DPd: display module, GL: wiring, M11: transistor, M12: transistor, M13: transistor, M14: transistor, PD: light-receiving device, RES: wiring, RL: wiring, SE: wiring, SL: wiring, SLB: wiring, SLG: wiring, SLR: wiring, TX: wiring, 10: display apparatus, 11a: light-emitting device, 11B: light-emitting device, 11b: light-emitting device, 11c: light-emitting device, 11G: light-emitting device, 11R: light-emitting device, 11S: light-receiving device, 11W: light-emitting device, 11: light-emitting device, 12: driver circuit portion, 13: driver circuit portion, 72b: region, 72c: region, 72d: region, 72: region, 73: region, 74a: FPC, 74: FPC, 79: display region, 100: display apparatus, 101: substrate, 103a: pixel portion, 103b: pixel portion, 103c: pixel portion, 103d: pixel portion, 103: pixel portion, 104: insulating layer, 110B: subpixel, 110G: subpixel, 110R: subpixel, 110S: light-receiving portion, 110: subpixel, 111B: lower electrode, 111C: connection electrode, 111G: lower electrode, 111R: lower electrode, 111S: lower electrode, 111: lower electrode, 112B: organic compound layer, 112f: organic compound film, 112fB: organic compound film, 112fG: organic compound film, 112fR: organic compound film, 112G: organic compound layer, 112R: organic compound layer, 112S: active layer, 112W: organic compound layer, 112: organic compound layer, 113: common electrode, 114: common layer, 118a: slit, 118b: slit, 119: slit, 123: resist mask, 124a: pair, 124b: pair, 125f: insulating film, 125: insulating layer, 126: insulating layer, 128: insulating layer, 135: mask, 140: connection portion, 143R: resist mask, 143: resist mask, 144B: mask film, 144G: mask film, 144R: mask film, 144: mask film, 145B: mask layer, 145G: mask layer, 145R: mask layer, 145: mask layer, 146B: mask film, 146G: mask film, 146R: mask film, 146: mask film, 147B: mask layer, 147G: mask layer, 147R: mask layer, 147: mask layer, 150a: pixel, 150b: pixel, 150: pixel, 151a: first auxiliary wiring, 151b: second auxiliary wiring, 151f: auxiliary wiring layer, 151: auxiliary wiring, 152: light-blocking layer, 155f: semiconductor film, 161: conductive layer, 162: conductive layer, 163: resin layer, 170: substrate, 171: adhesive layer, 172: resist mask, 173B: coloring layer, 173G: coloring layer, 173R: coloring layer, 173: coloring layer, 174: mask film, 175: mask layer, 176: mask film, 177: mask layer, 280: display module, 282: circuit portion, 283a: pixel circuit, 283: pixel circuit portion, 285: terminal portion, 286: wiring portion, 290: FPC, 291: substrate, 292: substrate, 401: substrate, 410a: transistor, 410: transistor, 411i: channel formation region, 411n: low-resistance region, 411: semiconductor layer, 412: insulating layer, 413: conductive layer, 414a: conductive layer, 414b: conductive layer, 415: conductive layer, 416: insulating layer, 421: insulating layer, 422: insulating layer, 426: insulating layer, 450a: transistor, 450: transistor, 451: semiconductor layer, 452: insulating layer, 453: conductive layer, 454a: conductive layer, 454b: conductive layer, 455: conductive layer, 700A: electronic device, 700B: electronic device, 721: housing, 723: mounting portion, 727: earphone portion, 750: earphone, 751: pixel portion, 753: optical member, 756: display region, 757: frame, 758: nose pad, 800A: electronic device, 800B: electronic device, 820: display portion, 821: housing, 822: communication portion, 823: mounting portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: pixel portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal

1. A display apparatus comprising:
a first light-emitting device comprising:
a first lower electrode whose end portion has a first tapered shape; and
a first organic compound layer over the first lower electrode, the first organic compound layer having a shape along the first tapered shape;
a second light-emitting device comprising:
a second lower electrode whose end portion has a second tapered shape; and
a second organic compound layer over the second lower electrode, the second organic compound layer having a shape along the second tapered shape;
a common electrode included in the first light-emitting device and the second light-emitting device;
an insulating layer between the first light-emitting device and the second light-emitting device; and
an auxiliary wiring electrically connected to the common electrode,
wherein the auxiliary wiring is over the common electrode, and
wherein the auxiliary wiring comprises a region overlapping with the insulating layer.

2. (canceled)

3. A display apparatus comprising:
a light-receiving device;
a first light-emitting device comprising:
a first lower electrode whose end portion has a first tapered shape; and
a first organic compound layer over the first lower electrode, the first organic compound layer having a shape along the first tapered shape;
a second light-emitting device comprising:
a second lower electrode whose end portion has a second tapered shape; and
a second organic compound layer over the second lower electrode, the second organic compound layer having a shape along the second tapered shape;
a common electrode included in the first light-emitting device and the second light-emitting device;
an insulating layer between the first light-emitting device and the second light-emitting device and between the second light-emitting device and the light-receiving device; and
an auxiliary wiring electrically connected to the common electrode,
wherein the auxiliary wiring is over the common electrode, and
wherein the auxiliary wiring comprises a region surrounding the light-receiving device.

4. A display apparatus comprising:
a light-receiving device;
a first light-emitting device comprising a first lower electrode whose end portion has a first tapered shape and a first organic compound layer having a shape along the first tapered shape;
a second light-emitting device comprising a second lower electrode whose end portion has a second tapered shape and a second organic compound layer having a shape along the second tapered shape;
a common electrode included in the first light-emitting device and the second light-emitting device;
an insulating layer positioned between the first light-emitting device and the second light-emitting device and between the second light-emitting device and the light-receiving device; and
an auxiliary wiring electrically connected to the common electrode,
wherein the auxiliary wiring is over the common electrode, and
wherein the auxiliary wiring comprises a region positioned between the first light-emitting device and the light-receiving device.

5. The display apparatus according to claim 1, wherein the insulating layer has a shape where a center portion thereof rises up more than an end portion.

6. The display apparatus according to claim 1, wherein the insulating layer comprises an upper portion with a flat shape.

7. The display apparatus according to claim 1, further comprising a light-receiving device,
wherein the insulating layer is positioned between the second light-emitting device and the light-receiving device.

8. The display apparatus according to claim 1,
wherein the first light-emitting device further comprises a first light-emitting layer, and
wherein a part of the insulating layer is interposed between the first light-emitting layer and the common electrode.

9. The display apparatus according to claim 1, wherein the auxiliary wiring comprises an organic material.

10. The display apparatus according to claim 3, wherein the insulating layer has a shape where a center portion thereof rises up more than an end portion.

11. The display apparatus according to claim 3, wherein the insulating layer comprises an upper portion with a flat shape.

12. The display apparatus according to claim 3,
wherein the first light-emitting device further comprises a first light-emitting layer, and
wherein the insulating layer comprises a region interposed between the first light-emitting layer and the common electrode.

13. The display apparatus according to claim 3, wherein the auxiliary wiring comprises an organic material.

14. The display apparatus according to claim 4, wherein the insulating layer has a shape where a center portion thereof rises up more than an end portion.

15. The display apparatus according to claim 4, wherein the insulating layer comprises an upper portion with a flat shape.

16. The display apparatus according to claim 4,
wherein the first light-emitting device further comprises a first light-emitting layer, and
wherein the insulating layer comprises a region interposed between the first light-emitting layer and the common electrode.

17. The display apparatus according to claim 4, wherein the auxiliary wiring comprises an organic material.
